(19) United States
(12) Patent Application Publication
(10) Pub. No.: US 2023/0299726 A1
(43) Pub. Date: Sep. 21, 2023

(54) SEMICONDUCTOR DEVICE

(71) Applicant: Murata Manufacturing Co., Ltd., Kyoto-fu (JP)

(72) Inventors: Satoshi Goto, Nagaokakyo-shi (JP); Masayuki Aoike, Nagaokakyo-shi (JP); Takayuki Tsutsui, Nagaokakyo-shi (JP); Kenji Sasaki, Nagaokakyo-shi (JP)

(73) Assignee: Murata Manufacturing Co., Ltd., Kyoto-fu (JP)

(21) Appl. No.: 18/166,369

(22) Filed: Feb. 8, 2023

(30) Foreign Application Priority Data
Feb. 9, 2022 (JP) 2022-018886
Nov. 9, 2022 (JP) 2022-179677

(51) Int. Cl. H03F 3/195; H01L 23/66; H03F 3/24; H03F 1/02; H03F 1/56

(52) U.S. Cl. CPC H03F 3/195; H01L 23/66; H03F 1/0288; H03F 1/565; H03F 3/245; H01L 2223/6611; H01L 2223/6655; H03F 2200/451

(57) ABSTRACT

A semiconductor device includes first and second members. A second surface of the second member is opposite to a first surface of the first member. A radio-frequency amplifier circuit is included in the second member. The first and second members are bonded to each other by an electrically conductive bonding member between the first and second surfaces. The radio-frequency amplifier circuit includes at least one power stage transistor, an input wire that is connected to the power stage transistor and supplies an input signal to the power stage transistor, and an input-side circuit element that is connected to the input wire and that includes at least one of a passive element, an active element, and an external connection terminal. The bonding member includes a first conductor pattern covering the power stage transistor in plan view. The input-side circuit element is disposed outside the first conductor pattern in plan view.

### CROSS-REFERENCE TO RELATED APPLICATIONS

This application claims benefit of priority to Japanese Patent Application No. 2022-179677, filed Nov. 9, 2022, and to Japanese Patent Application No. 2022-018886, filed Feb. 9, 2022, the entire content of each is incorporated herein by reference.

### BACKGROUND

### Technical Field

The present disclosure relates to a semiconductor device.

### Background Art

A semiconductor device having a board formed by bonding two substrates having different thermal conductivities, for example, a GaAs substrate and an Si substrate, to each other is described in Japanese Unexamined Patent Application Publication No. 2021-002644. The two substrates are, for example, bonded to each other with a bonding layer made of metal provided all over a bonding interface and interposed therebetween. A radio-frequency amplifier circuit is formed on or in one of the substrates. Heat dissipation is ensured when heat generated in a transistor of the radio-frequency amplifier circuit is conducted to the other one of the substrates through the bonding layer.

A parasitic capacitance is generated between the bonding layer made of metal and a wire or a circuit element in the radio-frequency amplifier circuit formed on or in the one of the substrates. Interference occurs in the radio-frequency amplifier circuit via the parasitic capacitance and the bonding layer, so characteristics can degrade or oscillation can occur.

### SUMMARY

The present disclosure provides a semiconductor device that is less likely to cause the characteristics degradation or oscillation of a radio-frequency amplifier circuit while ensuring heat dissipation in a structure in which different members are bonded to each other.

According to an aspect of the present disclosure, a semiconductor device includes a first member having a first surface; a second member having a second surface opposite to the first surface and including a radio-frequency amplifier circuit; and an electrically conductive bonding member disposed between the first surface and the second surface and bonding the first member and the second member to each other. The radio-frequency amplifier circuit includes at least one power stage transistor, an input wire that is connected to the power stage transistor and that supplies an input signal to the power stage transistor, and an input-side circuit element connected to the input wire and including at least one of a passive element, an active element, and an external connection terminal, the bonding member includes a first conductor pattern covering the power stage transistor in plan view, and the input-side circuit element is disposed outside the first conductor pattern in plan view.

According to another aspect of the present disclosure, a semiconductor device includes a semiconductor member containing a compound semiconductor; a radio-frequency amplifier circuit formed on or in the semiconductor member; and a conductor member disposed on one surface of the semiconductor member. The radio-frequency amplifier circuit includes at least one power stage transistor, an input wire that supplies an input signal to the power stage transistor, and an input-side circuit element connected to the input wire and including at least one of a passive element, an active element, and an external connection terminal. The conductor member includes at least one conductor pattern, and when a surface on which the conductor member is disposed is viewed in plan. The power stage transistor is covered with at least one conductor pattern of the conductor member, and the input-side circuit element is disposed outside the conductor pattern covering the power stage transistor.

### BRIEF DESCRIPTION OF THE DRAWINGS

FIG. 1 is a schematic plan view of a semiconductor device according to a first embodiment;

FIG. 2A is a cross-sectional view of the semiconductor device according to the first embodiment, and FIG. 2B is a cross-sectional view of a first member and a second member that show an example in which a natural oxide film is formed on a second surface of the second member;

FIG. 3 is an enlarged cross-sectional view of one of power stage transistors included in the second member;

FIG. 4 is a plan view of one of the power stage transistors included in the second member and an input-side circuit element disposed for each power stage transistor;

FIG. 5 is an equivalent circuit diagram of a radio-frequency amplifier circuit;

FIG. 6 is a block diagram of the radio-frequency amplifier circuit of the semiconductor device according to the first embodiment;

FIG. 7 is a schematic plan view of a semiconductor device according to a second embodiment;

FIG. 8 is a schematic plan view of a semiconductor device according to a third embodiment;

FIG. 9 is a schematic plan view of a semiconductor device according to a fourth embodiment;

FIG. 10 is a schematic plan view of a semiconductor device according to a fifth embodiment;

FIG. 11 is a schematic plan view of a semiconductor device according to a sixth embodiment;

FIG. 12 is a schematic plan view of a semiconductor device according to a seventh embodiment;

FIG. 13 is a schematic plan view of a semiconductor device according to an eighth embodiment;

FIG. 14 is a schematic plan view of a semiconductor device according to a ninth embodiment;

FIG. 15 is a schematic plan view of a semiconductor device according to a tenth embodiment;

FIG. 16 is a schematic plan view of a semiconductor device according to an eleventh embodiment;

FIG. 17 is a schematic plan view of a semiconductor device according to a twelfth embodiment;

FIG. 18 is a schematic plan view of a second member of a semiconductor device according to a thirteenth embodiment;

FIG. 19 is a block diagram of the semiconductor device according to the thirteenth embodiment;

FIG. 20 is a schematic plan view of a second member of a semiconductor device according to a fourteenth embodiment;

FIG. 21 is a schematic plan view of a second member of a semiconductor device according to a fifteenth embodiment;

FIG. 22 is a schematic plan view of a second member of a semiconductor device according to a sixteenth embodiment;

FIG. 23 is a schematic plan view of a second member of a semiconductor device according to a seventeenth embodiment;

FIG. 24 is a schematic plan view of a second member of a semiconductor device according to an eighteenth embodiment;

FIG. 25 is a schematic plan view of a second member of a semiconductor device according to a nineteenth embodiment;

FIG. 26 is a schematic plan view of a semiconductor device according to a twentieth embodiment;

FIG. 27 is a block diagram of the semiconductor device according to the twentieth embodiment;

FIG. 28 is a schematic plan view of a semiconductor device according to a twenty-first embodiment;

FIG. 29 is a block diagram of the semiconductor device according to the twenty-first embodiment;

FIG. 30 is a schematic plan view of a second member of a semiconductor device according to a twenty-second embodiment;

FIG. 31 is a schematic plan view of a second member of a semiconductor device according to a twenty-third embodiment;

FIG. 32 is a schematic plan view of a second member of a semiconductor device according to a twenty-fourth embodiment;

FIG. 33 is a schematic plan view of a second member of a semiconductor device according to a twenty-fifth embodiment;

FIG. 34 is a schematic plan view of a second member of a semiconductor device according to a twenty-sixth embodiment;

FIG. 35 is a schematic plan view of a second member of a semiconductor device according to a twenty-seventh embodiment;

FIG. 36 is a schematic plan view of a second member of a semiconductor device according to a twenty-eighth embodiment;

FIG. 37 is a schematic plan view of a semiconductor device according to a twenty-ninth embodiment;

FIG. 38 is a schematic plan view of a semiconductor device according to a thirtieth embodiment;

FIG. 39 is a schematic plan view of a semiconductor device according to a thirty-first embodiment;

FIG. 40 is an enlarged plan view of one of power stage transistors of the semiconductor device according to the thirty-first embodiment;

FIG. 41 is a schematic plan view of a semiconductor device according to a thirty-second embodiment;

FIG. 42 is a schematic plan view of a semiconductor device according to a thirty-third embodiment;

FIG. 43A is a schematic plan view of a semiconductor device according to a thirty-fourth embodiment, FIG. 43B is a schematic cross-sectional view taken along the alternate long and short dashed line 43B-43B in FIG. 43A, and FIG. 43C is a schematic cross-sectional view taken along the alternate long and short dashed line 43C-43C in FIG. 43A;

FIG. 44A is a schematic plan view of a semiconductor device according to a thirty-fifth embodiment, FIG. 44B is a schematic cross-sectional view taken along the alternate long and short dashed line 44B-44B in FIG. 44A, and FIG. 44C is a schematic cross-sectional view taken along the alternate long and short dashed line 44C-44C in FIG. 44A;

FIG. 45 is a schematic plan view of a semiconductor device according to a thirty-sixth embodiment;

FIG. 46 is a cross-sectional view of part of the semiconductor device shown in FIG. 45;

FIG. 47 is a schematic plan view of a semiconductor device according to a thirty-seventh embodiment;

FIG. 48 is a cross-sectional view of part of the semiconductor device shown in FIG. 47;

FIG. 49 is a schematic plan view of a semiconductor device according to a thirty-eighth embodiment;

FIG. 50 is a schematic plan view of a semiconductor device according to a modification of the thirty-eighth embodiment;

FIG. 51 is a schematic plan view of a semiconductor device according to another modification of the thirty-eighth embodiment;

FIG. 52 is a schematic plan view of a semiconductor device according to further another modification of the thirty-eighth embodiment;

FIG. 53 is a schematic plan view of a semiconductor device according to further another modification of the thirty-eighth embodiment;

FIG. 54 is a schematic plan view of a semiconductor device according to further another modification of the thirty-eighth embodiment;

FIG. 55 is a schematic plan view of a semiconductor device according to a thirty-ninth embodiment;

FIG. 56 is a schematic plan view of a semiconductor device according to a modification of the thirty-ninth embodiment;

FIG. 57 is a schematic plan view of a semiconductor device according to a fortieth embodiment;

FIG. 58 is a schematic plan view of a semiconductor device according to a forty-first embodiment;

FIG. 59 is a schematic plan view of a semiconductor device according to a forty-second embodiment;

FIG. 60 is a schematic plan view of a semiconductor device according to a forty-third embodiment;

FIG. 61 is a schematic plan view of a semiconductor device according to a modification of the forty-third embodiment;

FIG. 62 is a schematic plan view of a semiconductor device according to another modification of the forty-third embodiment;

FIG. 63 is a schematic plan view of a semiconductor device according to further another modification of the forty-third embodiment;

FIG. 64 is a schematic plan view of a semiconductor device according to further another modification of the forty-third embodiment;

FIG. 65 is a schematic plan view of a semiconductor device according to further another modification of the forty-third embodiment;

FIG. 66 is a schematic plan view of a semiconductor device according to further another modification of the forty-third embodiment;

FIG. 67 is a schematic plan view of a semiconductor device according to further another modification of the forty-third embodiment;

FIG. 68 is a schematic plan view of a semiconductor device according to a forty-fourth embodiment;

FIG. 69 is a schematic plan view of a semiconductor device according to a forty-fifth embodiment;

FIG. 70 is a schematic plan view of a semiconductor device according to a modification of the forty-fifth embodiment;

FIG. 71 is a schematic plan view of a semiconductor device according to another modification of the forty-fifth embodiment;

FIG. 72 is a schematic plan view of a semiconductor device according to a forty-sixth embodiment;

FIG. 73 is a schematic plan view of a semiconductor device according to a modification of the forty-sixth embodiment;

FIG. 74 is a schematic plan view of a semiconductor device according to another modification of the forty-sixth embodiment;

FIG. 75 is a schematic plan view of a semiconductor device according to a forty-seventh embodiment;

FIG. 76 is a schematic plan view of a semiconductor device according to a modification of the forty-seventh embodiment;

FIG. 77 is a schematic plan view of a semiconductor device according to another modification of the forty-seventh embodiment;

FIG. 78 is a schematic plan view of a semiconductor device according to a forty-eighth embodiment; and

FIG. 79 is a schematic plan view of a semiconductor device according to a modification of the forty-eighth embodiment.

### DETAILED DESCRIPTION

### First Embodiment

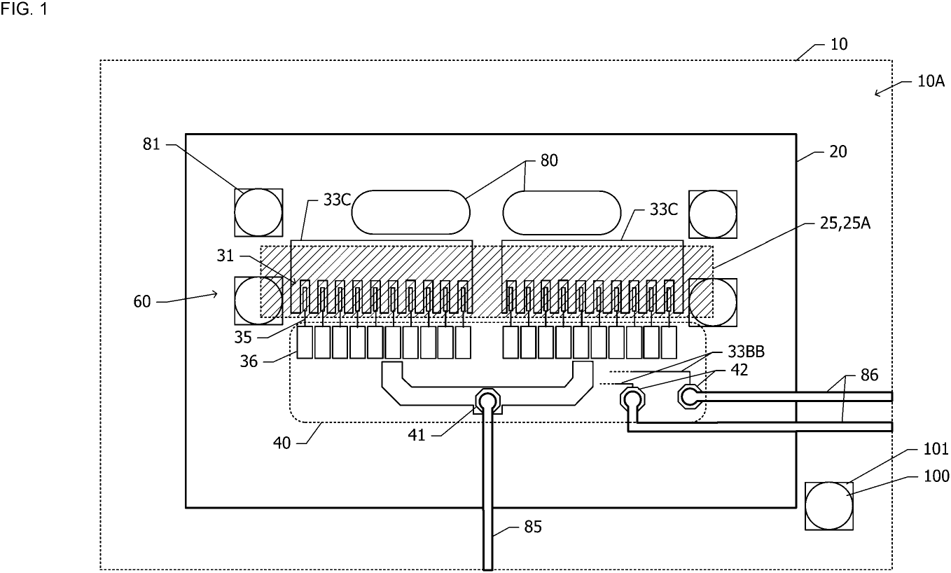

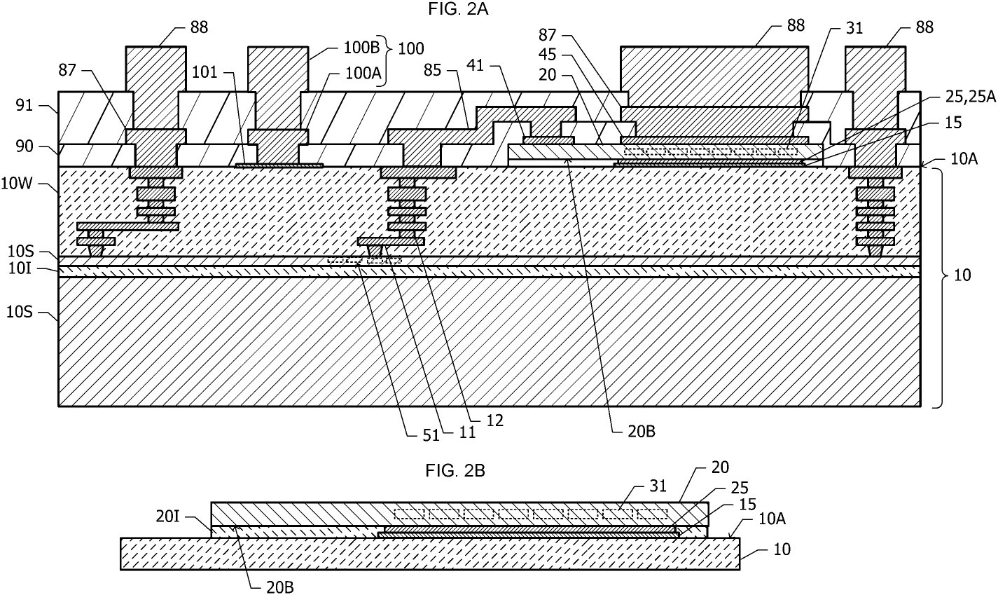

A semiconductor device according to a first embodiment will be described with reference to FIGS. 1 to 6. FIG. 1 is a schematic plan view of the semiconductor device according to the first embodiment. The semiconductor device according to the first embodiment includes a first member 10 and a second member 20. The first member 10 is a substrate including an elemental semiconductor layer, for example, an SOI substrate. The second member 20 is a filmy member including a compound semiconductor film, for example, a GaAs film. As will be described with reference to FIG. 2A, the second member 20 is bonded to a first surface 10A of the first member 10. FIG. 1 shows only part of the first member 10. The dashed line representing the first member 10 in FIG. 1 does not represent the outer shape of the first member 10. When the first surface 10A is viewed in plan (hereinafter, which may be simply referred to as “in plan view”), the shape of the second member 20 is a square or a rectangle.

The second member 20 includes a power stage radio-frequency amplifier circuit 60. The power stage radio-frequency amplifier circuit 60 includes a plurality of power stage transistors 31, a plurality of input wires 35 each connected to the base of a corresponding one of the power stage transistors 31, a plurality of input capacitors 36 each connected to a corresponding one of the input wires 35, an input terminal 41, bias terminals 42, and the like. Passive elements connected to the input wires 35, external connection terminals, and wires connecting the passive elements and the external connection terminals are referred to as an input-side circuit element 40.

The plurality of power stage transistors 31 is disposed so as to be arranged in a line and is disposed symmetrically with respect to the center in an array direction. The plurality of power stage transistors 31 is divided into two blocks at the center of the transistor array. For example, the power stage transistors 31 of both blocks are operated for high-power operation, and only the power stage transistors 31 of one of the blocks are operated for low-power operation. The input-side circuit element 40 is disposed on one side (lower side in FIG. 1) of a straight line parallel to the array direction of the plurality of power stage transistors 31 (hereinafter, which may be simply referred to as “array direction”) and passing through the plurality of power stage transistors 31 in plan view.

For example, the array direction of the plurality of power stage transistors 31 is parallel to one edge of the second member 20. The input-side circuit element 40 is disposed between the transistor array of the power stage transistors 31 and one edge of the second member 20, disposed with a space in a direction orthogonal to the array direction from the transistor array. The input-side circuit element 40 is not disposed between the transistor array and the other edge parallel to the array direction. In addition, the input-side circuit element 40 may be disposed between the transistor array and an edge of the second member 20, which intersects with a straight line extended from the transistor array in the array direction. A positional relationship between the input-side circuit element 40 and the transistor array is similar in embodiments (described later). Here, the phrase “orthogonal to the array direction” does not need to be geometrically strictly orthogonal and may deviate from an orthogonal relationship. In the specification, an orthogonal relationship that allows such a deviation is referred to as “substantially orthogonal”. The phrase “parallel to the array direction” does not need to be geometrically strictly parallel and may deviate from a parallel relationship. A parallel relationship that allows such a deviation is called “substantially parallel”.

For example, a protective element, a diode-connected transistor that makes up a bias circuit, a wire for feedback from an output side to an input side, and the like can be disposed in the space between the two blocks. No wire, circuit component, or the like can be disposed in the space between the two blocks.

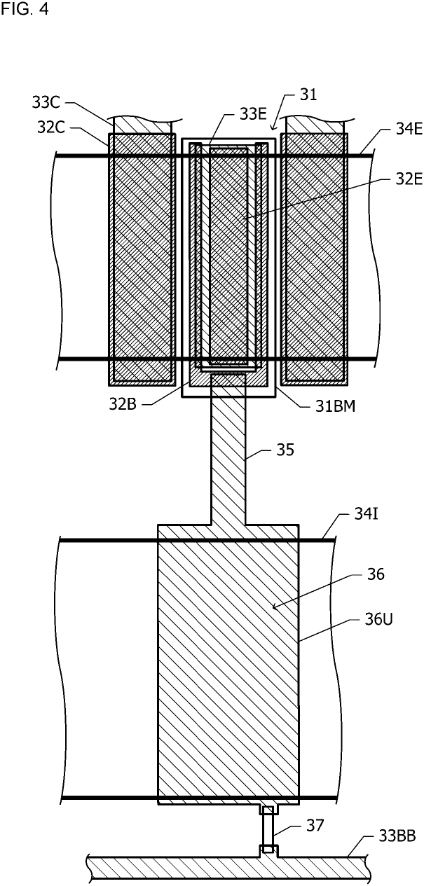

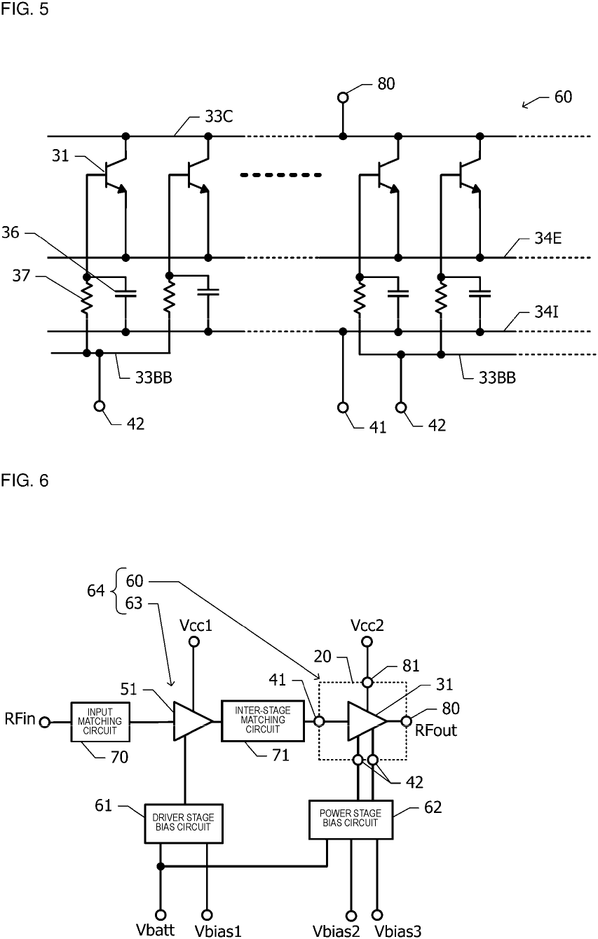

Base biases are respectively supplied from the two bias terminals 42 to the power stage transistors 31 of the two blocks via bias wires 33BB (ballast resistive elements that will be described with reference to FIGS. 4 and 5 are not shown in FIG. 1). A radio-frequency signal is input from the input terminal 41 to the bases of the power stage transistors 31 respectively via the plurality of input capacitors 36 and the input wires 35. Base bias control may be current control or voltage control.

A collector wire 33C is connected to the collector of each of the plurality of power stage transistors 31. The collector wire 33C has a combtooth shape in plan view. A plurality of combtooth parts each is disposed between any two of the plurality of power stage transistors 31. A common part that connects the plurality of combtooth parts is disposed on an opposite side to the input-side circuit element 40 when viewed from the power stage transistors 31. The collector wire 33C may be divided according to the blocks of the power stage transistors 31 or may be common to the two blocks.

Output terminals 80 each made up of a conductive protrusion, such as a bump, are connected to the collector wires 33C. An output signal amplified by the plurality of power stage transistors 31 is output from each of the output terminals 80. For example, a collector voltage is applied to the plurality of power stage transistors 31 via a choke coil, the output terminal 80, the collector wire 33C. The output terminals 80 each are connected to, for example, an external impedance matching circuit. Other than the output terminals 80, a plurality of external connection terminals 81 made up of conductive protrusions, such as bumps, is disposed. The plurality of external connection terminals 81 includes, for example, a terminal for connection with an external circuit, a dummy terminal for ensuring flatness and parallelism at the time of flip-chip mounting on a module substrate or the like, and other terminals.

In plan view, a radio-frequency signal passes through the plurality of power stage transistors 31 and is input from the input-side circuit element 40, disposed on one side of the straight line parallel to the array direction, to the plurality of power stage transistors 31, and is output from the output terminals 80 via the collector wires 33C disposed on the opposite side. In this way, a radio-frequency signal is transferred mainly in one direction from the input-side circuit element 40 toward the output terminals 80.

Inter-member connection wires 85, 86 are disposed. The inter-member connection wires 85, 86 each connect a terminal provided on the second member 20 with a terminal provided on the first member 10. An input signal is supplied to the input terminal 41 through the inter-member connection wire 85. A bias is supplied to the two bias terminals 42 respectively through the other two inter-member connection wires 86.

An electrically conductive bonding member 25 is disposed between the first surface 10A of the first member 10 and the second member 20. The first member 10 and the second member 20 are bonded to each other with the bonding member 25 interposed therebetween. In plan view, a conductor pattern 25A of the bonding member 25 is disposed so as to cover the plurality of power stage transistors 31. In the first embodiment, the bonding member 25 includes the single continuous conductor pattern 25A. In the specification, a plurality of conductor patterns separated from each other may be collectively referred to as “conductor pattern”.

In FIG. 1, the conductor pattern 25A is hatched. The conductor pattern 25A has a line-symmetric shape with respect to a symmetric axis passing through the center of the plurality of power stage transistors 31 in the array direction and orthogonal to the array direction in plan view. A conductor pattern of a first member 10-side bonding member 15 is disposed so as to substantially overlap the conductor pattern 25A. In the specification and the other drawings, the conductor pattern of the first member 10-side bonding member 15 can be not explicitly shown, and the first member 10-side conductor pattern is disposed so as to overlap a conductor pattern of the second member 20-side bonding member 25. In the direction orthogonal to the array direction of the plurality of power stage transistors 31, the conductor pattern of the first member 10-side bonding member 15 expands more widely on the side where the collector wires 33C and the output terminals 80 are disposed than on the side of the input-side circuit element 40 when viewed from the plurality of power stage transistors 31.

The conductor pattern 25A does not overlap the input-side circuit element 40 in plan view. In other words, the input-side circuit element 40 is disposed outside the conductor pattern 25A that contains the plurality of power stage transistors 31 in plan view. For example, the conductor pattern 25A partially overlaps the collector wires 33C disposed on an opposite side to the input-side circuit element 40 when viewed from the plurality of power stage transistors 31. In the specification, the phrase “outside a portion” means a region outside an outer peripheral line of the portion in plan view, and the phrase “inside a portion” means a region inside an outer peripheral line of the portion in plan view.

In plan view, a conductive protrusion base pattern 101 is disposed on the first surface 10A of the first member 10 outside the second member 20. In plan view, a first member conductive protrusion 100 is disposed inside the conductive protrusion base pattern 101.

FIG. 2A is a cross-sectional view of the semiconductor device according to the first embodiment. FIG. 2A does not show a specific cross-sectional structure of the semiconductor device according to the first embodiment and shows the cross-sectional structure of each of a plurality of component elements of the semiconductor device by focusing on each of the component elements. Initially, the configuration of the first member 10 will be described.

The first member 10 includes a silicon-on-insulator (SOI) substrate and a multilayer wiring layer 10W disposed on the SOI substrate. The SOI substrate includes a support substrate 10B, an electrically insulating layer 101, and a semiconductor layer 10S. Instead of the SOI substrate, an ordinary elementary silicon substrate or the like may be used. A plurality of driver stage transistors 51 is formed in the semiconductor layer 10S. In FIG. 2A, the driver stage transistors 51 are represented by the dashed line. The driver stage transistors 51 are, for example, CMOS transistors.

The second member 20 is bonded to a region that is part of the first surface 10A that is the top surface of the multilayer wiring layer 10W. The second surface 20B of the second member 20 is opposite to the first surface 10A of the first member 10. The bonding member 15 is disposed in a region that is part of the first surface 10A of the first member 10. The conductor pattern 25A of the bonding member 25 is disposed in a region that is part of the second surface 20B of the second member 20. When the second member 20-side bonding member 25 of the second member 20 closely contacts with the bonding member 15 of the first member 10, the second member 20 is bonded to the first member 10.

The second member 20-side bonding member 25 and the first member 10-side bonding member 15 have substantially the same shape in plan view and substantially overlap each other. Although FIG. 1 does not explicitly show the bonding member 15, the bonding member 15 is disposed so as to substantially overlap the second member 20-side bonding member 25. The second member 20-side bonding member 25 and the first member 10-side bonding member 15 may have different shapes, and one may be larger than the other. However, the first member 10-side bonding member 15 bonded to the bonding member 25 has a shape and size that do not overlap the input-side circuit element 40 (FIG. 1) in plan view. The difference in shape and size therebetween is preferably set to an extent that an alignment error during bonding is absorbed.

The bonding member 15 and the bonding member 25 may be made of, for example, Au. When both are brought into close contact with each other and applied with pressure, the second member 20 is bonded to the first member 10. Other than the above, van der Waals bond, hydrogen bond, electrostatic force, covalent bond, eutectic alloy bond, or the like may be used to bond the second member 20 with the first member 10. A gap corresponding to the total thickness of the first member 10-side bonding member 15 and the second member 20-side bonding member 25 is formed between the first surface 10A and the second surface 20B.

The plurality of power stage transistors 31 formed in the second member 20 is represented by the dashed line. The input terminal 41 and a ground terminal 45 are disposed on a surface of the second member 20 on an opposite side to the second surface (hereinafter, which may be referred to as “top surface”). The input terminal 41 and the ground terminal 45 are made up of a topmost layer metal film of the second member 20. The ground terminal 45 is disposed at a location that overlaps the plurality of power stage transistors 31 in plan view. In FIG. 1, the ground terminal 45 is not shown.

A rewiring layer is disposed on the first surface 10A of the first member 10 and on the top surface of the second member 20 with an electrically insulating film 90 interposed therebetween. The rewiring layer includes a plurality of pads 87, the inter-member connection wire 85, and a first member conductive protrusion lower part 100A, each of which is made up of a metal pattern. The conductive protrusion base pattern 101 is disposed between the first member conductive protrusion lower part 100A and the multilayer wiring layer 10W. The conductive protrusion base pattern 101 is formed in the same process with the first member 10-side bonding member 15. Although not shown in FIG. 2A, the inter-member connection wires 86 (FIG. 1) connected to the bias terminals 42 are also included in the rewiring layer. The input terminal 41 is connected to the driver stage transistors 51 with the inter-member connection wire 85, and wires 11 and vias 12 of the multilayer wiring layer 10W, interposed therebetween. An interstage impedance matching circuit including a capacitor, an inductor, and the like may be disposed between the input terminal 41 and the driver stage transistors 51. Alternatively, an interstage impedance matching circuit may be disposed between the input terminal 41 and the power stage transistors 31.

One of the plurality of pads 87 is connected to the ground terminal 45 provided on the second member 20. The plurality of pads 87, the inter-member connection wire 85, and the first member conductive protrusion lower part 100A are covered with an electrically insulating film 91. The electrically insulating film 91 has openings that respectively reach the top surfaces of the plurality of pads 87 and the first member conductive protrusion lower part 100A in the cross section shown in FIG. 2A. These openings are respectively covered with the plurality of pads 87 and the first member conductive protrusion lower part 100A in plan view. Conductive protrusions 88 connected to the pads 87 and a first member conductive protrusion upper part 100B connected to the first member conductive protrusion lower part 100A are disposed in the openings and on the electrically insulating film 91. The conductive protrusions 88 are used as connection terminals when mounted on a module substrate or the like in a face-down position. The output terminals 80 (FIG. 1) and the external connection terminal 81 (FIG. 1) are made up of these conductive protrusions 88. The first member conductive protrusion lower part 100A and the first member conductive protrusion upper part 100B are referred to as a first member conductive protrusion 100. In order to distinguish the conductive protrusion 88 from the first member conductive protrusion 100, the conductive protrusion 88 used as the external connection terminal 81 is referred to as a terminal conductive protrusion.

FIG. 2B is a cross-sectional view of the first member 10 and the second member 20, showing an example in which a natural oxide film 20I is formed on the second surface 20B of the second member 20. After the bonding member 25 is formed on the second surface 20B of the second member 20, the natural oxide film 20I can be formed on the second surface 20B of the second member 20 before the second member 20 is bonded to the first member 10. When the thickness of the natural oxide film 20I is substantially equal to the total thickness of the first member 10-side bonding member 15 and the second member 20-side bonding member 25, almost no gap is formed between the first member 10 and the second member 20.

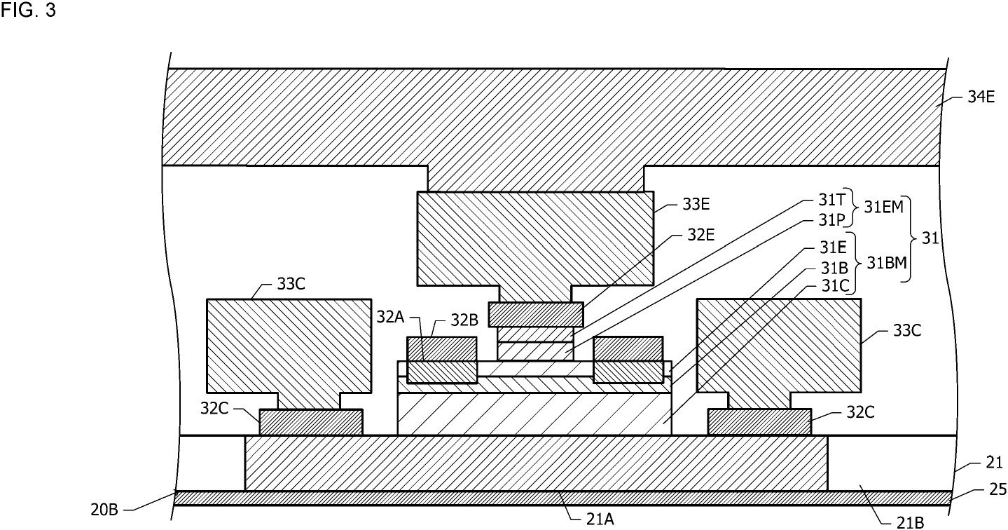

FIG. 3 is an enlarged cross-sectional view of one of the power stage transistors 31 included in the second member 20. The second member 20 includes a semiconductor thin film 21. One of the surfaces of the semiconductor thin film 21 corresponds to the second surface 20B opposite to the first member 10. The bonding member 25 is formed on the second surface 20B. The semiconductor thin film 21 is made of a compound semiconductor, such as GaAs, and is divided into an N-type electrically conductive sub-collector layer 21A and an electrically insulating element isolation region 21B. The power stage transistor 31 is formed on the sub-collector layer 21A.

The power stage transistor 31 includes a base mesa 31BM formed on the sub-collector layer 21A and an emitter mesa 31EM formed in a region that is part of the top surface of the base mesa 31BM. The base mesa 31BM includes a collector layer 31C, a base layer 31B, and an emitter layer 31E laminated in order from the sub-collector layer 21A. In other words, the collector layer 31C, the base layer 31B, and the emitter layer 31E are laminated in this order from a side close to the first member 10 (FIG. 2A). The emitter mesa 31EM includes a cap layer 31P and a contact layer 31T disposed on the cap layer 31P.

For example, the collector layer 31C is made from N-type GaAs, the base layer 31B is made from P-type GaAs, and the emitter layer 31E is made from N-type InGaP. The cap layer 31P is made from N-type GaAs, and the contact layer 31T is made from N-type InGaAs. The power stage transistor 31 made up of the base mesa 31BM and the emitter mesa 31EM is a heterojunction bipolar transistor (HBT). During operation of the power stage transistor 31, heat is generated mainly in the collector layer 31C just below the emitter mesa 31EM.

Collector electrodes 32C are disposed above a region in which the base mesa 31BM is not disposed within the sub-collector layer 21A. For example, in the cross section of FIG. 3, the collector electrodes 32C are respectively disposed on both sides of the base mesa 31BM. First-layer collector wires 33C are respectively disposed on the collector electrodes 32C. In FIG. 3, a specific structure of an interlayer electrically insulating film between wiring layers is not shown. The collector wires 33C are electrically connected to the collector layer 31C with the collector electrodes 32C and the sub-collector layer 21A interposed therebetween. The collector wires 33C in the cross section shown in FIG. 3 correspond to combtooth parts of the collector wire 33C shown in FIG. 1. The plurality of power stage transistors 31 may be disposed on the single continuous sub-collector layer 21A, and the single collector electrode 32C may be shared between mutually adjacent two of the power stage transistors 31.

A base electrode 32B is disposed on a region of the emitter layer 31E on which the emitter mesa 31EM is not disposed. The base electrode 32B includes portions disposed on both sides of the emitter mesa 31EM in the cross section of FIG. 3. The base electrode 32B is electrically connected to the base layer 31B with an alloyed region 32A extending through the emitter layer 31E in a thickness direction and interposed therebetween and reaches the base layer 31B.

An emitter electrode 32E is disposed on the emitter mesa 31EM. The emitter electrode 32E is electrically connected to the emitter layer 31E with the contact layer 31T and the cap layer 31P interposed therebetween. The emitter layer 31E located just below the emitter mesa 31EM substantially functions as an emitter region.

A first-layer emitter wire 33E is disposed on the emitter electrode 32E, and a second-layer emitter wire 34E is disposed on the emitter wire 33E. The second-layer emitter wire 34E is electrically connected to the emitter electrode 32E with the first-layer emitter wire 33E interposed therebetween. At least one ground terminal 45 (FIG. 2A) is disposed on the second-layer emitter wire 34E. The ground terminal 45 is electrically connected to the emitter layer 31E of the power stage transistor 31.

FIG. 4 is a plan view of one of the power stage transistors 31 included in the second member 20 and the input capacitor 36 disposed for each power stage transistor 31. In FIG. 4, relatively dark positive-slope hatching is applied to the emitter electrode 32E, the base electrode 32B, and the collector electrodes 32C, and relatively light negative-slope hatching is applied to the emitter wire 33E, the collector wires 33C, the input wire 35, and the bias wire 33BB.

The emitter electrode 32E and the base electrode 32B are disposed inside the base mesa 31BM having a shape long in one direction (for example, a rectangular shape) in plan view. The shape of the emitter electrode 32E in plan view is also a rectangular shape that is long in one direction. The base electrode 32B has a U-shape made up of portions respectively disposed so as to be spaced apart from the two long sides and one short side of the emitter electrode 32E. The two collector electrodes 32C are disposed so as to be spaced apart from the base mesa 31BM in the short-side direction (width direction). The plurality of power stage transistors 31 (FIG. 1) is disposed so as to be arranged in the width direction of the emitter electrode 32E. One collector electrode 32C may be shared between adjacent two power stage transistors 31.

The first-layer emitter wire 33E is disposed so as to overlap the emitter electrode 32E in plan view. The first-layer collector wires 33C are respectively disposed so as to overlap the collector electrodes 32C in plan view. Each of the first-layer collector wires 33C extends from a portion, at which the first-layer collector wires 33C overlap the collector electrode 32C, in one direction substantially orthogonal to the array direction of the power stage transistors 31. The direction in which the collector wires 33C extend and the array direction of the power stage transistors 31 do not need to be geometrically strictly orthogonal and may deviate from an orthogonal relationship.

The second-layer emitter wire 34E is disposed so as to overlap the plurality of first-layer emitter wires 33E in plan view. The second-layer emitter wire 34E extends in a direction substantially parallel to the array direction of the power stage transistors 31 and is connected to the plurality of first-layer emitter wires 33E.

One end portion of the input wire 35 overlaps the base electrode 32B and is connected to the base electrode 32B. The input wire 35 extends from a portion, at which the input wire 35 overlaps the base electrode 32B, in one direction substantially orthogonal to the array direction of the power stage transistors 31. The direction in which the input wire 35 extends in a direction opposite to the direction in which the collector wires 33C extend.

A lower electrode 36U of the input capacitor 36 is connected to the distal end of the input wire 35. A signal input wire 34I is disposed so as to overlap the lower electrode 36U of the input capacitor 36 in plan view. The signal input wire 34I in a region that overlaps the lower electrode 36U functions as an upper electrode of the input capacitor 36. The signal input wire 34I extends in a direction substantially parallel to the array direction of the power stage transistors 31 and overlaps the plurality of lower electrodes 36U respectively connected to the plurality of power stage transistors 31.

The input wire 35 is connected to one end portion of a ballast resistive element 37 with the lower electrode 36U of the input capacitor 36 interposed therebetween. The other end portion of the ballast resistive element 37 is connected to the bias wire 33BB. In FIG. 1, the second-layer emitter wire 34E, the signal input wire 34I, the ballast resistive elements 37, and the like are not shown. The state “the conductor pattern 25A of the bonding member 25 covers the power stage transistors 31 in plan view” described with reference to FIG. 1 specifically means that the conductor pattern 25A overlaps the base mesas 31BM in plan view.

The one of the power stage transistors 31, shown in FIGS. 3 and 4, has a single emitter structure including one emitter mesa 31EM. As another example, a multi-emitter structure in which a plurality of emitter mesas 31EM is disposed on one base mesa 31BM so as to be arranged in the short-side direction of the base mesa 31BM may be adopted. In the single emitter structure, the base electrode 32B may be disposed only on one side of the emitter mesa 31EM in the short-side direction to form the base electrode 32B in an L-shape in plan view.

In FIG. 4, the ballast resistive element 37 is disposed at a location farther from the input capacitor 36 when viewed from the power stage transistor 31. Alternatively, the ballast resistive element 37 may be disposed between the power stage transistor 31 and the input capacitor 36.

FIG. 5 is an equivalent circuit diagram of the power stage radio-frequency amplifier circuit 60. The power stage radio-frequency amplifier circuit 60 includes the plurality of power stage transistors 31. The collectors of the plurality of power stage transistors 31 are connected to the common collector wire 33C. The common collector wire 33C is connected to the output terminals 80. The emitters of the plurality of power stage transistors 31 are connected to the common emitter wire 34E. Each of the bases of the plurality of power stage transistors 31 is connected to the common signal input wire 34I with a corresponding one of the input capacitors 36 interposed therebetween. The signal input wire 34I is connected to the input terminal 41.

The plurality of power stage transistors 31 is divided into two blocks. Each of the bases of the plurality of power stage transistors 31 is connected block by block to the common bias wire 33BB with a corresponding one of the ballast resistive elements 37 interposed therebetween. Each of the bias wires 33BB provided block by block is connected to the bias terminal 42.

FIG. 6 is a block diagram of a two-stage radio-frequency amplifier circuit 64 including the power stage radio-frequency amplifier circuit 60 of the semiconductor device according to the first embodiment. The radio-frequency amplifier circuit 64 shown in FIG. 6 includes a driver stage radio-frequency amplifier circuit 63 and the power stage radio-frequency amplifier circuit 60. The driver stage radio-frequency amplifier circuit 63 includes the driver stage transistors 51. The power stage radio-frequency amplifier circuit 60 includes the power stage transistors 31. A radio-frequency signal RFin is input to the driver stage transistor 51 via an input matching circuit 70. The radio-frequency signal amplified by the driver stage transistors 51 is input to the power stage transistors 31 via an inter-stage matching circuit 71 and the input terminal 41. The radio-frequency signal amplified by the power stage transistors 31 is output from the output terminal 80 as an output signal RFout. The output terminal 80 is, for example, connected to a load with an impedance matching circuit mounted on or in a module substrate and interposed therebetween.

For example, a power supply voltage Vcc1 is supplied to the driver stage transistor 51 via an external connection terminal. A power supply voltage Vcc2 is supplied to the power stage transistors 31 via the external connection terminal 81. The output terminal 80 (FIG. 5) may be used as a terminal for supplying a power supply voltage Vcc2. A battery voltage Vbatt is supplied to a driver stage bias circuit 61 and a power stage bias circuit 62. The driver stage bias circuit 61 supplies a base bias to the driver stage transistor 51 in accordance with a driver stage bias control signal Vbias1. The power stage bias circuit 62 supplies a base bias to the power stage transistors 31 (FIG. 5) of each of the two blocks in accordance with power stage bias control signals Vbias2, Vbias3 via a corresponding one of the bias terminals 42.

Next, advantageous effects of the first embodiment will be described. In the first embodiment, heat generated in the power stage transistors 31 is transferred to the first member 10 through the bonding member 25 (FIG. 2A) and the first member 10-side bonding member 15 and is also transferred to the module substrate or the like through the emitter wires 33E, 34E (FIG. 3), the pads 87, and the conductive protrusions 88 (FIG. 2A). In plan view, since the bonding member 25 covers the power stage transistors 31, heat dissipation from the power stage transistors 31 to the first member 10 are not impaired as compared to the configuration that the bonding member 25 is disposed all over the region of the second surface 20B.

To further increase heat dissipation from the power stage transistors 31, vias and wires that extend from the bonding member 15 to the semiconductor layer 10S can be formed in the multilayer wiring layer 10W of the first member 10. These vias and wires function as a heat path and reduce thermal resistance from the bonding member 15 to the semiconductor layer 10S.

In addition, in the first embodiment, as shown in FIG. 1, the bonding member 25 does not overlap the input-side circuit element 40 in plan view. In comparison with the configuration that both overlap each other, a parasitic capacitance between the input-side circuit element 40 and the conductor pattern 25A of the bonding member 25 is small. For this reason, the strength of coupling between the power stage transistors 31 and the input-side circuit element 40 with the bonding member 25 interposed therebetween reduces. As a result, the deterioration of the characteristics of the power stage radio-frequency amplifier circuit 60 is suppressed. Particularly, a decrease in the gain of the power stage radio-frequency amplifier circuit 60 is suppressed. As a result, a decrease in output and a decrease in efficiency of the power stage radio-frequency amplifier circuit 60 are suppressed. In addition, since the coupling strength from the output-side circuit of the power stage transistors 31 to the input-side circuit element 40 is low, oscillation due to positive feedback from the output-side circuit to the input-side circuit element 40 is suppressed.

### Second Embodiment

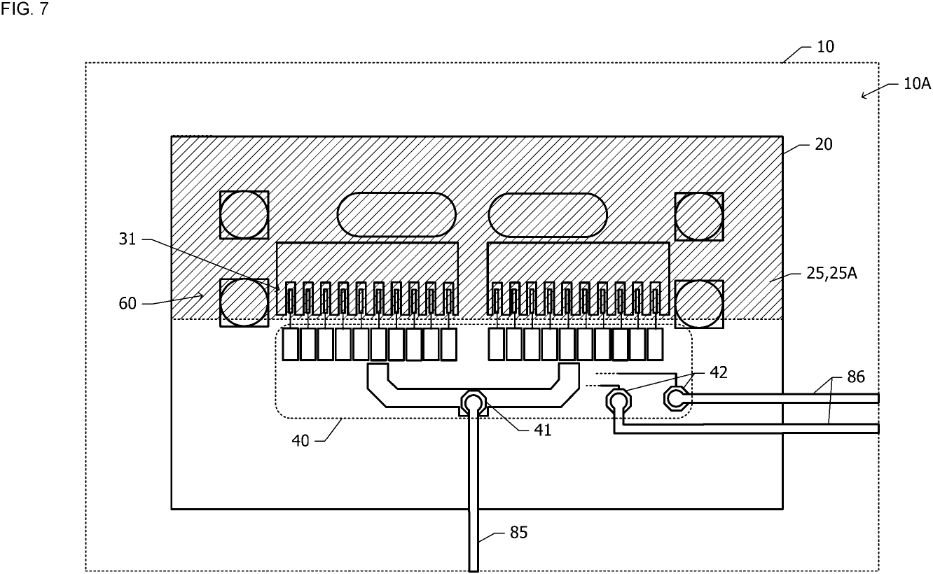

Next, a semiconductor device according to a second embodiment will be described with reference to FIG. 7. Hereinafter, the description of components common to those of the semiconductor device according to the first embodiment described with reference to FIGS. 1 to 6 will not be repeated.

FIG. 7 is a schematic plan view of the semiconductor device according to the second embodiment. In the first embodiment (FIG. 1), the conductor pattern 25A that covers the plurality of power stage transistors 31 in plan view is disposed in an internal region apart from the edge of the second member 20. In contrast, in the second embodiment, the conductor pattern 25A expands from a region overlapping the plurality of power stage transistors 31 in a direction other than a direction toward the region in which the input-side circuit element 40 is disposed, and reaches the edge of the second member 20. In the second embodiment as well, the input-side circuit element 40 is disposed outside the conductor pattern 25A in plan view.

Next, advantageous effects of the second embodiment will be described. In the second embodiment, the area of the conductor pattern 25A is wider than that in the first embodiment. Therefore, the bonding strength of the second member 20 with the first member 10 is increased. Even when the conductor pattern 25A is expanded, the conductor pattern 25A does not overlap the input-side circuit element 40 in plan view. Therefore, as in the case of the first embodiment, the oscillation and characteristics deterioration, such as a decrease in the gain, of the power stage radio-frequency amplifier circuit 60 are suppressed.

### Third Embodiment

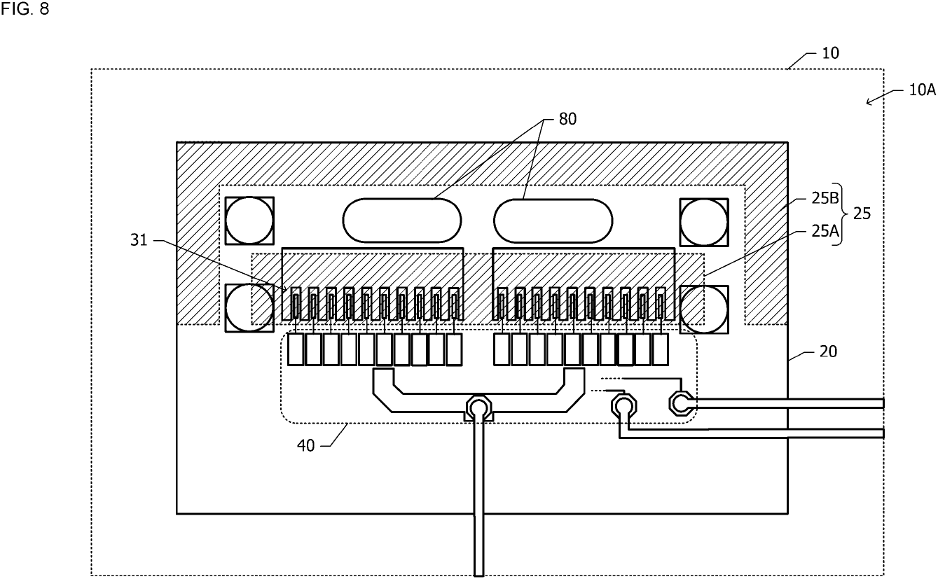

Next, a semiconductor device according to a third embodiment will be described with reference to FIG. 8. Hereinafter, the description of components common to those of the semiconductor device according to the first embodiment described with reference to FIGS. 1 to 6 will not be repeated.

FIG. 8 is a schematic plan view of the semiconductor device according to the third embodiment. In the first embodiment (FIG. 1), the bonding member 25 is made up of only one conductor pattern 25A. In contrast, in the third embodiment, the bonding member 25 includes another one conductor pattern 25B in addition to the conductor pattern 25A. The conductor pattern 25B is disposed along part of the edge of the second member 20. Here, the state “the conductor pattern 25B is provided along the edge of the second member 20” includes both the configuration that an outer peripheral-side outline of the conductor pattern 25B coincides with the edge of the second member 20 in plan view and the configuration that the outer peripheral-side outline of the conductor pattern 25B is disposed inside the edge of the second member 20 and a space is formed therebetween in plan view.

With respect to a transmission direction (up and down direction in FIG. 8) of a radio-frequency signal to be transmitted from the input-side circuit element 40 toward the output terminals 80, the conductor pattern 25B is disposed along the edge of the second member 20 in a range in which the input-side circuit element 40 is not disposed. For example, the conductor pattern 25B has a U-shape that is open from the power stage transistors 31 toward the input-side circuit element 40 in plan view.

The first member 10-side bonding member 15 (FIG. 2) also includes a conductor pattern that substantially overlaps the conductor pattern 25B in plan view. The conductor pattern of the first member 10-side bonding member 15 and the second member 20-side conductor pattern 25B are brought into contact with each other and bonded. As in the case of other embodiments that will be described later as well, the first member 10-side bonding member 15 is disposed in a region that overlaps a region in which the bonding member 25 of the second member 20 is disposed.

Next, advantageous effects of the third embodiment will be described. In the third embodiment, since the bonding member 25 includes the conductor pattern 25B provided along the edge of the second member 20 in addition to the conductor pattern 25A that covers the plurality of power stage transistors 31 in plan view, the bonding strength between the first member 10 and the second member 20 is increased as compared to the first embodiment (FIG. 1). In addition, none of the conductor patterns 25A, 25B of the bonding member 25 overlaps the input-side circuit element 40 in plan view, the oscillation and characteristics deterioration, such as a decrease in the gain, of the power stage radio-frequency amplifier circuit 60 are suppressed as in the case of the first embodiment.

### Fourth Embodiment

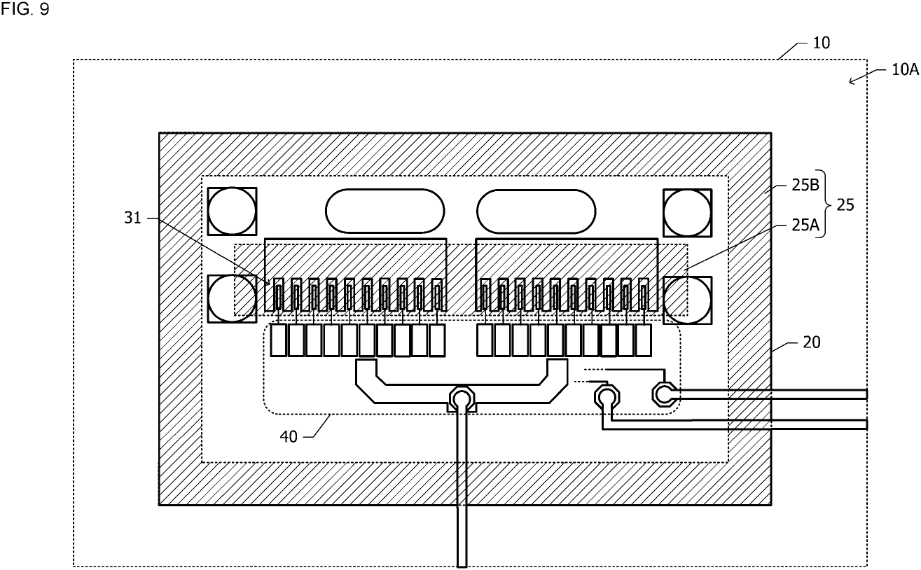

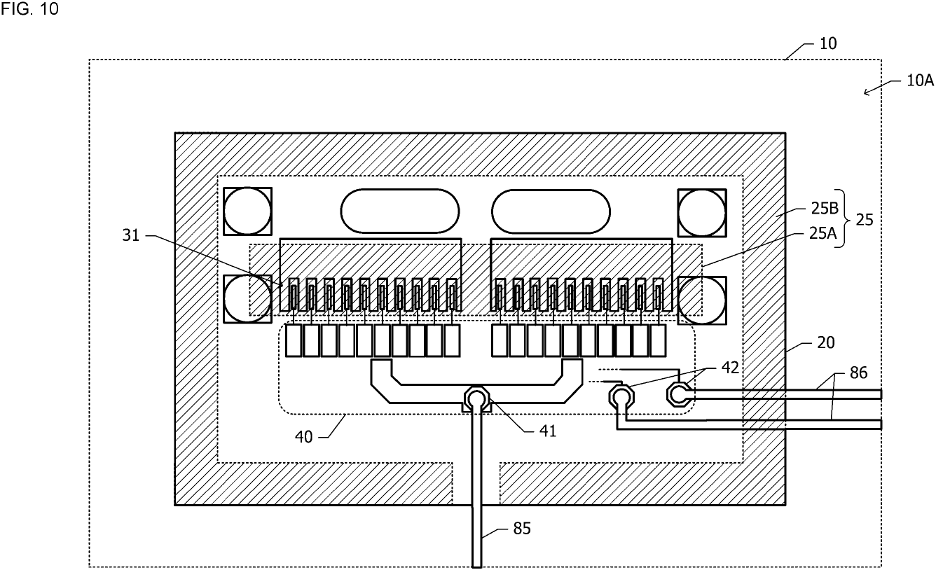

Next, a semiconductor device according to a fourth embodiment will be described with reference to FIG. 9. Hereinafter, the description of components common to the semiconductor device (FIG. 8) according to the third embodiment will not be repeated.

FIG. 9 is a schematic plan view of the semiconductor device according to the fourth embodiment. In the third embodiment (FIG. 8), the conductor pattern 25B of the bonding member 25 is disposed along part of the edge of the second member 20, while, in the fourth embodiment, the conductor pattern 25B is continuously disposed along all over the edge of the second member 20 in plan view. None of the conductor patterns 25A, 25B of the bonding member 25 overlaps the input-side circuit element 40 in plan view.

Next, advantageous effects of the fourth embodiment will be described. In the fourth embodiment, the area of one conductor pattern 25B of the bonding member 25 is wider than that in the third embodiment (FIG. 8). Therefore, the bonding strength between the second member 20 and the first member 10 is further increased. Since one conductor pattern 25B of the bonding member 25 is disposed along all over the edge of the second member 20 in plan view, the second member 20 is stably supported.

In addition, in the fourth embodiment as well, none of the two conductor patterns 25A, 25B of the bonding member 25 overlaps the input-side circuit element 40 in plan view. Therefore, the oscillation and characteristics deterioration, such as a decrease in gain, due to coupling between the output-side circuit of the power stage transistors 31 and the input-side circuit element 40 are suppressed.

### Fifth Embodiment

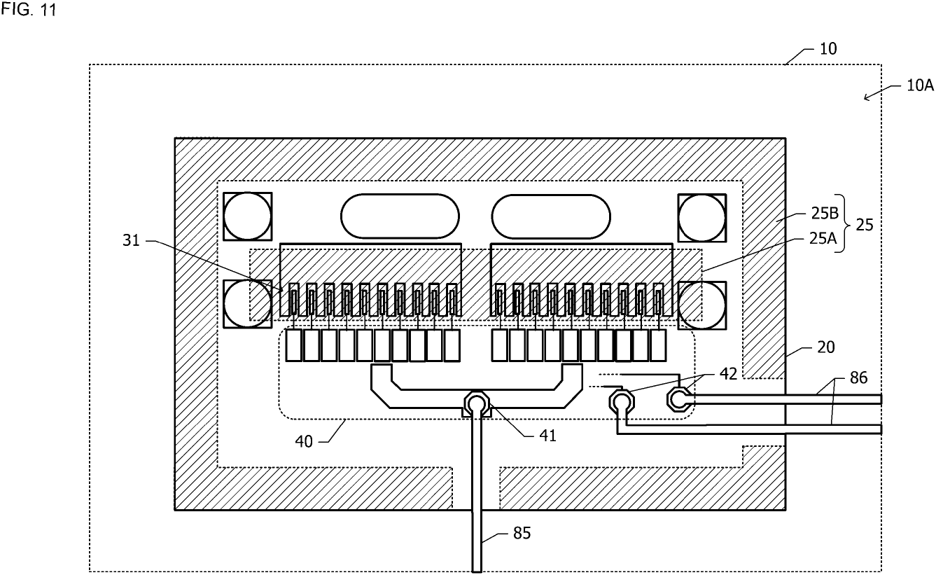

Next, a semiconductor device according to a fifth embodiment will be described with reference to FIG. 10. Hereinafter, the description of components common to the semiconductor device (FIG. 9) according to the fourth embodiment will not be repeated.

FIG. 10 is a schematic plan view of the semiconductor device according to the fifth embodiment. In the fourth embodiment (FIG. 9), one conductor pattern 25B of the bonding member 25 is continuously disposed along all over the edge of the second member 20 in plan view. In contrast, in the fifth embodiment, a gap of the conductor pattern 25B is provided at a portion at which the conductor pattern 25B intersects with the inter-member connection wire 85 connected to the input terminal 41, and the inter-member connection wire 85 does not overlap the conductor pattern 25B. Similarly, a gap is also provided at the same portion in the first member 10-side bonding member 15 (FIG. 2A).

Next, advantageous effects of the fifth embodiment will be described. In the fourth embodiment (FIG. 9), since the inter-member connection wire 85 connected to the input terminal 41 overlaps the conductor pattern 25B in plan view, a parasitic capacitance is generated therebetween. Since the conductor pattern 25B that overlaps the inter-member connection wire 85 is separated from the conductor pattern 25A that covers the power stage transistors 31, coupling between the output-side circuit of the power stage transistors 31 and the input-side circuit element 40 is sufficiently reduced. In the fifth embodiment, since almost no parasitic capacitance is generated between the inter-member connection wire 85 and the conductor pattern 25B, coupling between the output-side circuit of the power stage transistors 31 and the input-side circuit element 40 is further reduced.

### Sixth Embodiment

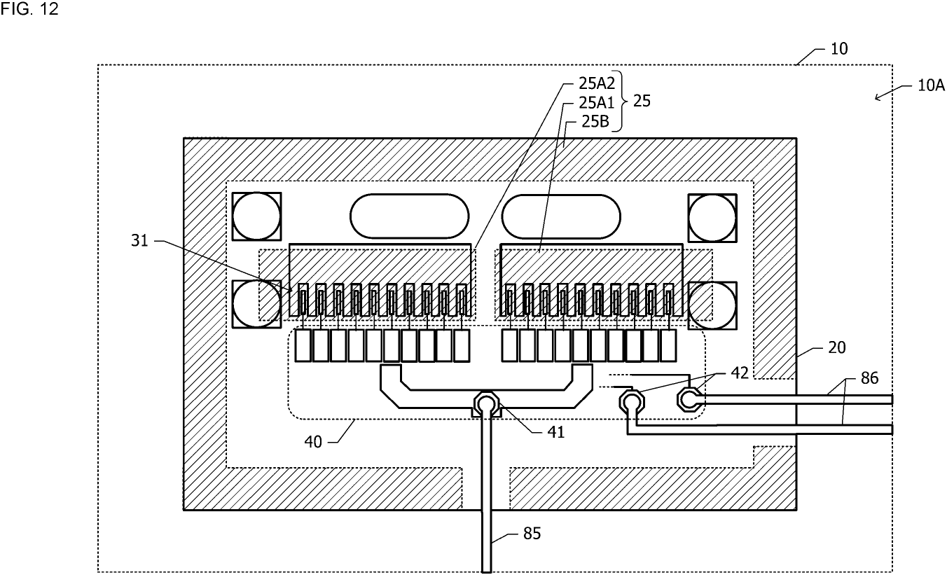

Next, a semiconductor device according to a sixth embodiment will be described with reference to FIG. 11. Hereinafter, the description of components common to the semiconductor device (FIG. 10) according to the fifth embodiment will not be repeated.

FIG. 11 is a schematic plan view of the semiconductor device according to the sixth embodiment. In the fifth embodiment (FIG. 10), the inter-member connection wires 86 respectively connected to the bias terminals 42 and the conductor pattern 25B of the bonding member 25 overlap in plan view. In contrast, in the sixth embodiment, a gap of the conductor pattern 25B is provided at a portion at which the conductor pattern 25B intersects with the inter-member connection wires 86, and the conductor pattern 25B is divided into two conductor patterns. Therefore, the conductor pattern 25B does not overlap the bias terminals 42 in plan view.

Next, advantageous effects of the sixth embodiment will be described. In the sixth embodiment, almost no parasitic capacitance is generated between the conductor pattern 25B and each of the inter-member connection wires 86 respectively connected to the bias terminals 42. Therefore, the influence of output signals of the power stage transistors 31 on the bias circuits is further reduced.

Next, a modification of an sixth embodiment will be described. In the sixth embodiment, one gap is provided in the conductor pattern 25B for the two inter-member connection wires 86. Alternatively, two breaks that respectively overlap the two inter-member connection wires 86 may be provided. In other words, with the inter-member connection wire 85 and the two inter-member connection wires 86, the conductor pattern 25B is divided into three conductor patterns. When, for example, a space between the two inter-member connection wires 86 is wide at an intersecting portion with the edge of the second member 20, the configuration of the present modification in which the conductor pattern 25B is divided into three conductor patterns can be adopted.

### Seventh Embodiment

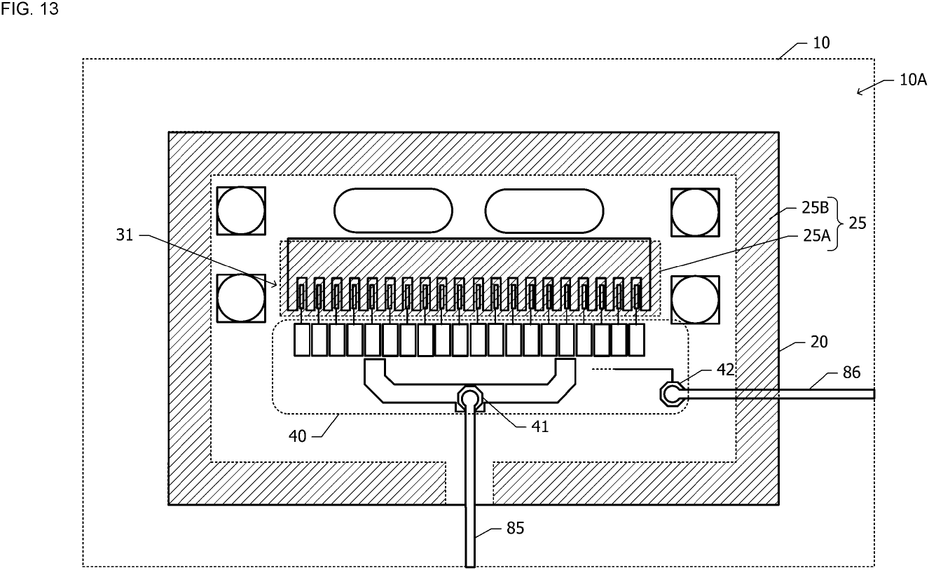

Next, a semiconductor device according to the seventh embodiment will be described with reference to FIG. 12. Hereinafter, the description of components common to the semiconductor device (FIG. 11) according to the sixth embodiment will not be repeated.

FIG. 12 is a schematic plan view of the semiconductor device according to a seventh embodiment. In the sixth embodiment (FIG. 11), one conductor pattern 25A covers the plurality of power stage transistors 31 of two blocks. In contrast, in the seventh embodiment, the conductor pattern 25A is divided into two conductor patterns 25A1, 25A2, and the conductor patterns 25A1, 25A2 are respectively disposed for the two blocks. The plurality of power stage transistors 31 of one of the blocks is covered with one conductor pattern 25A1 in plan view, and the plurality of power stage transistors 31 of the other one of the blocks is covered with the other conductor pattern 25A2 in plan view.

Next, advantageous effects of the seventh embodiment will be described. In the sixth embodiment (FIG. 11), the conductor pattern 25A functions as a heat path between the plurality of power stage transistors 31 of one of the blocks and the plurality of power stage transistors 31 of the other one of the blocks. Therefore, one of the blocks is susceptible to heat from the other one of the blocks. In the seventh embodiment, since the conductor pattern 25A1 that covers the plurality of power stage transistors 31 of one of the blocks in plan view and the conductor pattern 25A2 that covers the plurality of power stage transistors 31 of the other one of the blocks in plan view are separated from each other, thermal coupling strength between the blocks reduces. Therefore, thermal influence between the blocks reduces.

When, for example, the plurality of power stage transistors 31 of one of the blocks makes up a carrier amplifier of a Doherty power amplifier and the plurality of power stage transistors 31 of the other one of the blocks makes up a peak amplifier of the Doherty power amplifier, the amount of heat generated from the plurality of power stage transistors 31 that make up the carrier amplifier is relatively large.

When the continuous one conductor pattern 25A (FIG. 11) is disposed over the two blocks, there occurs an imbalance in thermal influence between the power stage transistors 31 at both ends, which are components of the carrier amplifier. When the conductor pattern 25A1 and the conductor pattern 25A2 are separated as in the case of the seventh embodiment, an imbalance in thermal influence among the plurality of power stage transistors 31 that make up the carrier amplifier is reduced. Thus, high-efficiency operation of the Doherty power amplifier is implemented.

### Eighth Embodiment

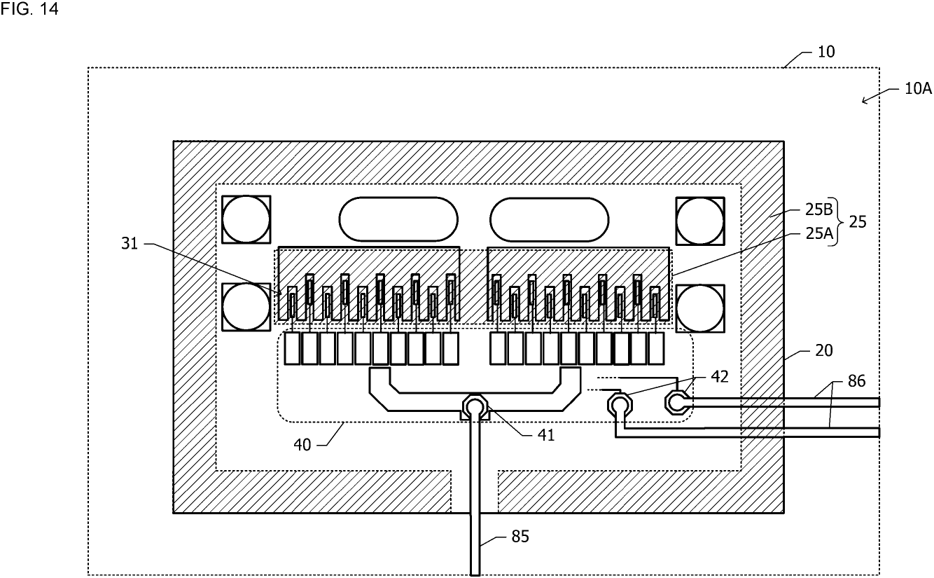

Next, a semiconductor device according to an eighth embodiment will be described with reference to FIG. 13. Hereinafter, the description of components common to the semiconductor device (FIG. 10) according to the fifth embodiment will not be repeated.

FIG. 13 is a schematic plan view of the semiconductor device according to the eighth embodiment. In the fifth embodiment (FIG. 10), the plurality of power stage transistors 31 is divided into two blocks, and a space is ensured between the blocks. In contrast, in the eighth embodiment, the plurality of power stage transistors 31 is not divided into blocks, and all the power stage transistors 31 are arranged at equal intervals. All the power stage transistors 31 are covered with one conductor pattern 25A of the bonding member 25 in plan view.

In the fifth embodiment (FIG. 10), the two bias terminals 42 are disposed in correspondence with the number of blocks of the plurality of power stage transistors 31; whereas, in the eighth embodiment, one bias terminal 42 is disposed. A base bias is supplied from the one bias terminal 42 to all the power stage transistors 31.

Next, advantageous effects of the eighth embodiment will be described. As in the case of the eighth embodiment, the configuration that the plurality of power stage transistors 31 is equally arranged from one end portion to the other end portion may be adopted. With this configuration as well, as in the case of the fifth embodiment (FIG. 10), heat dissipation from the plurality of power stage transistors 31 to the first member 10 is not impaired, and the strength of coupling between the input-side circuit element 40 and the plurality of power stage transistors 31 is reduced.

Next, a modification of the eighth embodiment will be described. In the eighth embodiment, one bias terminal 42 is provided for the plurality of power stage transistors 31. Alternatively, as in the case of the semiconductor device (FIG. 10) according to the fifth embodiment, two bias terminals 42 may be provided.

### Ninth Embodiment

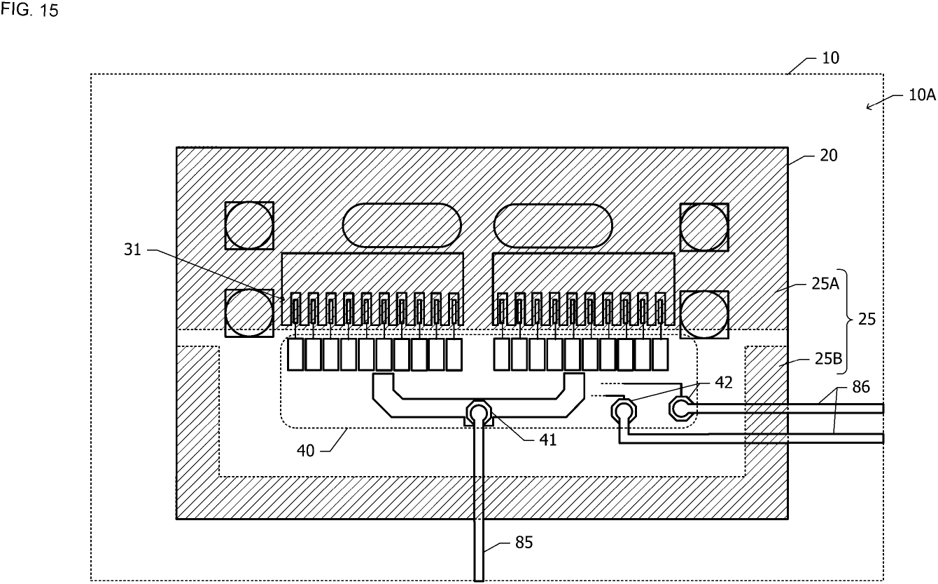

Next, a semiconductor device according to a ninth embodiment will be described with reference to FIG. 14. Hereinafter, the description of components common to the semiconductor device (FIG. 10) according to the fifth embodiment will not be repeated.

FIG. 14 is a schematic plan view of the semiconductor device according to the ninth embodiment. In the fifth embodiment (FIG. 10), the plurality of power stage transistors 31 is disposed along a straight line. In contrast, in the ninth embodiment, the plurality of power stage transistors 31 is disposed in a staggered manner. Specifically, when a serial number is assigned to each of the plurality of power stage transistors 31 in one block in the array direction, the odd-numbered power stage transistors 31 are disposed along a straight line, the even-numbered power stage transistors 31 are also disposed along a straight line, and the plurality of even-numbered power stage transistors 31 are shifted in a direction substantially orthogonal to the array direction from the odd-numbered power stage transistors 31.

The input-side circuit element 40 is disposed on one side of a straight line parallel to a direction in which the plurality of power stage transistors 31 is arranged and passing through at least one power stage transistor 31. As the straight line passing through at least one power stage transistor 31, for example, a straight line passing through the odd-numbered power stage transistor 31 may be adopted, or a straight line passing through the even-numbered power stage transistor 31 may be adopted.

The conductor pattern 25A of the bonding member 25 is disposed so as to cover a minimum bounding rectangle including the plurality of power stage transistors 31 in plan view.

Next, advantageous effects of the ninth embodiment will be described. When the plurality of power stage transistors 31 is disposed in a staggered manner, the distribution density of a plurality of heat sources is sparse as compared to the configuration that the plurality of power stage transistors 31 is disposed along a straight line. Therefore, the effect of heat dissipation from the plurality of power stage transistors 31 is increased.

In addition, under the condition that the dimensions of each of the power stage transistors 31 in plan view, spaces between the power stage transistors 31, and the number of the power stage transistors 31 are the same, the area of a minimum bounding rectangle that includes the plurality of power stage transistors 31 in plan view increases in the ninth embodiment as compared to the configuration that the plurality of power stage transistors 31 is disposed along a straight line as in the case of the fifth embodiment (FIG. 10). Since the conductor pattern 25A of the bonding member 25 is disposed so as to cover a minimum bounding rectangle that includes the plurality of power stage transistors 31 in plan view, the thermal resistance of a heat path from the plurality of power stage transistors 31 toward the first member 10 is reduced. As a result, it is possible to improve heat dissipation to the first member 10.

### Tenth Embodiment

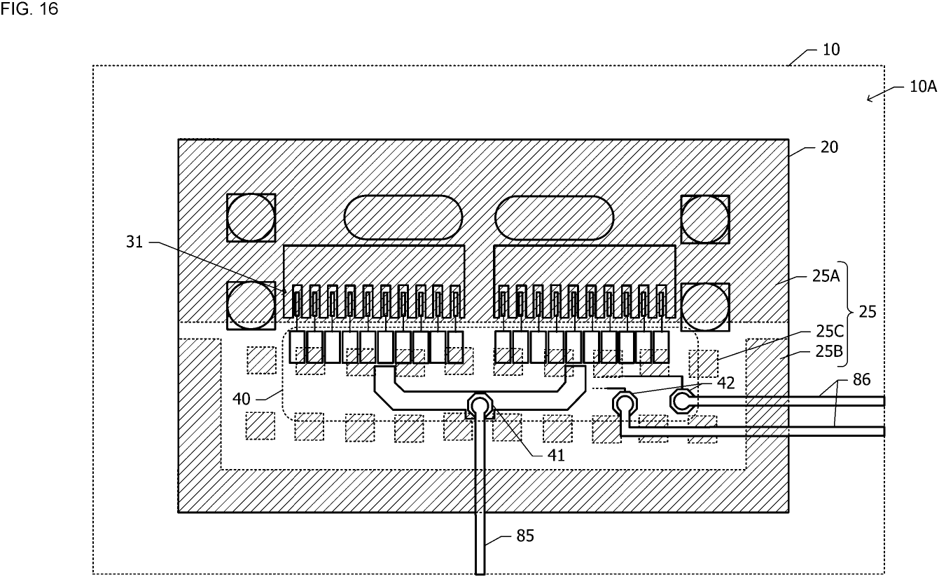

Next, a semiconductor device according to a tenth embodiment will be described with reference to FIG. 15. Hereinafter, the description of components common to those of the semiconductor device according to the first embodiment described with reference to FIGS. 1 to 6 will not be repeated.

FIG. 15 is a schematic plan view of the semiconductor device according to the tenth embodiment. In the tenth embodiment, the conductor pattern 25A of the bonding member 25 provided in the semiconductor device (FIG. 1) according to the first embodiment expands in a direction other than the direction toward the region in which the input-side circuit element 40 is disposed, and reaches the edge of the second member 20. In the tenth embodiment as well, the input-side circuit element 40 is disposed outside the conductor pattern 25A that covers the plurality of power stage transistors 31 in plan view.

In addition, the other conductor pattern 25B is disposed along the edge of the second member 20, not in contact with the conductor pattern 25A that covers the plurality of power stage transistors 31. The conductor pattern 25B does not overlap the input-side circuit element 40 in plan view. In addition, the conductor pattern 25B is separated from the conductor pattern 25A that covers the plurality of power stage transistors 31.

Next, advantageous effects of the tenth embodiment will be described. In the tenth embodiment, the area of the conductor pattern 25A that covers the plurality of power stage transistors 31 in plan view is greater than that in the first embodiment (FIG. 1). Therefore, heat dissipation through a heat path from the plurality of power stage transistors 31 via the conductor pattern 25A to the first member 10 improves. In addition, in the tenth embodiment, the total area of the conductor patterns 25A, 25B that make up the bonding member 25 is wider than that in the first embodiment (FIG. 1). Therefore, the bonding strength of the second member 20 with the first member 10 is increased.

The inter-member connection wire 85 connected to the input terminal 41 overlaps the conductor pattern 25B in plan view; however, the conductor pattern 25B is separated from the conductor pattern 25A that covers the plurality of power stage transistors 31 in plan view. Therefore, the strength of coupling between the input-side inter-member connection wire 85 and the plurality of power stage transistors 31 does not increase.

### Eleventh Embodiment

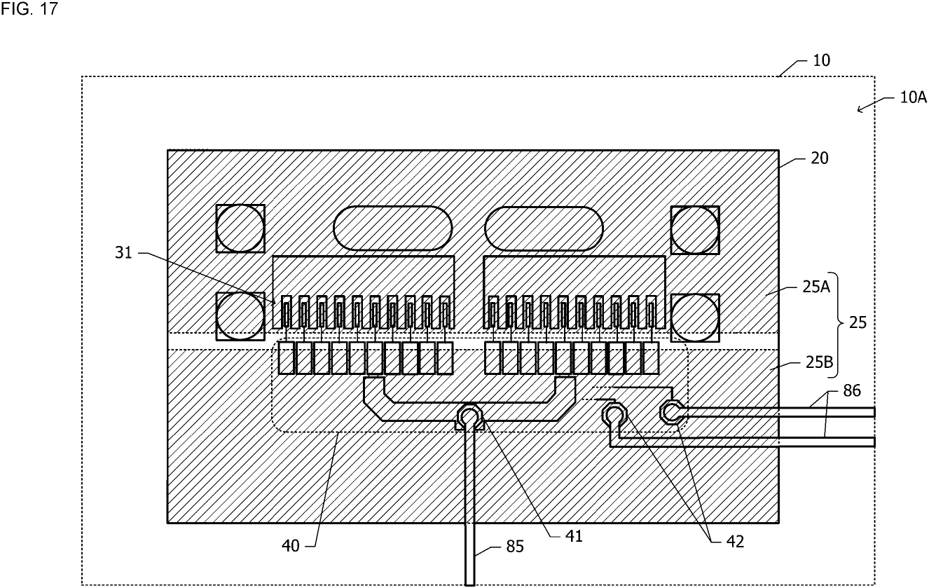

Next, a semiconductor device according to an eleventh embodiment will be described with reference to FIG. 16. Hereinafter, the description of components common to the semiconductor device (FIG. 15) according to the tenth embodiment will not be repeated.

FIG. 16 is a schematic plan view of the semiconductor device according to the eleventh embodiment. In the tenth embodiment (FIG. 15), the bonding member 25 includes the conductor patterns 25A, 25B, and none of the conductor patterns 25A, 25B overlaps the input-side circuit element 40 in plan view. In contrast, in the eleventh embodiment, the bonding member 25 includes a plurality of conductor patterns 25C in addition to the conductor patterns 25A, 25B. The plurality of conductor patterns 25C is dotted in a region surrounded by the two conductor patterns 25A, 25B. Some of the plurality of conductor patterns 25C overlap at least part of the input-side circuit element 40 in plan view.

Next, advantageous effects of the eleventh embodiment will be described. In the eleventh embodiment, the bonding member 25 includes the plurality of conductor patterns 25C in addition to the conductor patterns 25A, 25B. Therefore, the bonding strength of the second member 20 with the first member 10 is increased. Some of the conductor patterns 25C overlap at least part of the input-side circuit element 40 in plan view; however, the conductor patterns 25C are separated from the conductor pattern 25A that covers the plurality of power stage transistors 31 in plan view. Therefore, the effect of reducing the strength of coupling between the input-side circuit element 40 and the plurality of power stage transistors 31 is maintained.

### Twelfth Embodiment

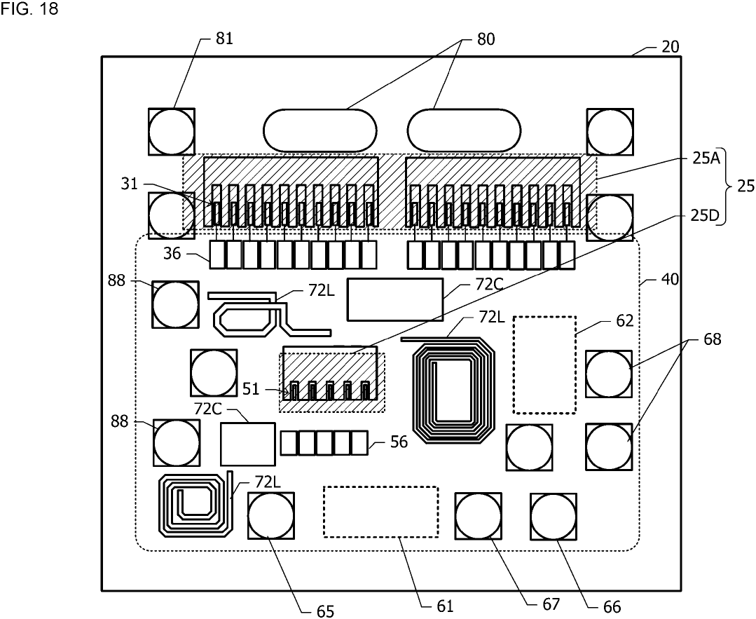

Next, a semiconductor device according to a twelfth embodiment will be described with reference to FIG. 17. Hereinafter, the description of components common to the semiconductor device (FIG. 15) according to the tenth embodiment will not be repeated.

FIG. 17 is a schematic plan view of the semiconductor device according to the twelfth embodiment. In the tenth embodiment (FIG. 15), the conductor pattern 25B that does not overlap the plurality of power stage transistors 31 in plan view also does not overlap the input-side circuit element 40. In contrast, in the twelfth embodiment, the conductor pattern 25B overlaps at least part of the input-side circuit element 40 in plan view. As in the case of the tenth embodiment (FIG. 15), the conductor pattern 25B is separated from the conductor pattern 25A that covers the plurality of power stage transistors 31.

Next, advantageous effects of the twelfth embodiment will be described. In the twelfth embodiment, the total area of the conductor patterns 25A, 25B included in the bonding member 25 is greater than that in the tenth embodiment (FIG. 15). Therefore, the bonding strength of the second member 20 with the first member 10 is increased. Since the conductor patterns 25A, 25B are separated from each other, the effect of reducing the strength of coupling between the input-side circuit element 40 and the plurality of power stage transistors 31 with the bonding member 25 interposed therebetween is maintained.

### Thirteenth Embodiment

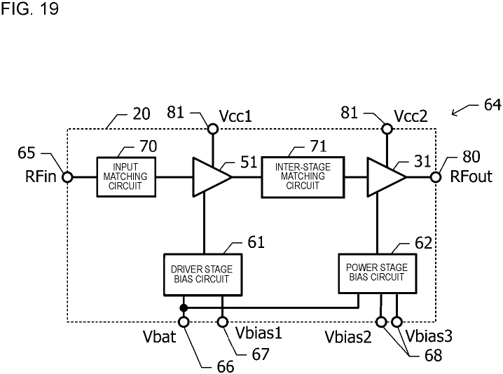

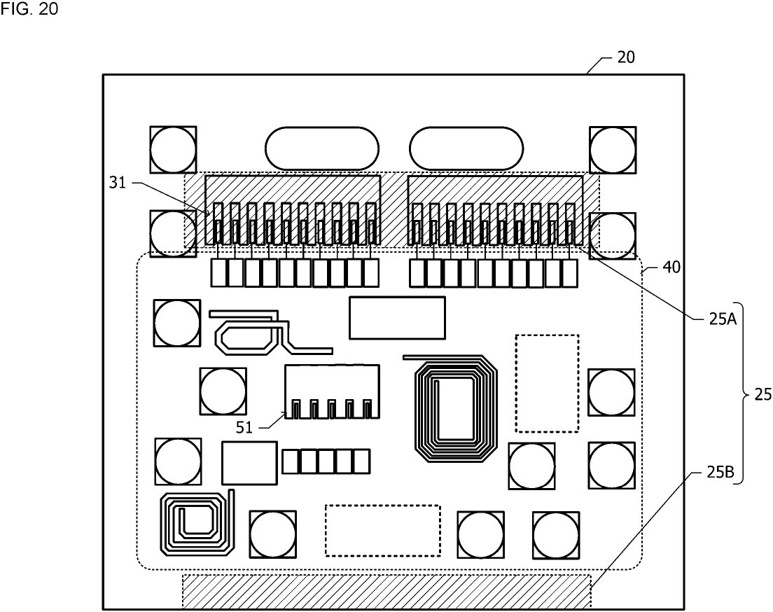

Next, a semiconductor device according to a thirteenth embodiment will be described with reference to FIGS. 18 and 19. Hereinafter, the description of components common to those of the semiconductor device according to the first embodiment described with reference to FIGS. 1 to 6 will not be repeated.

FIG. 18 is a schematic plan view of the second member 20 of the semiconductor device according to the thirteenth embodiment. In the first embodiment (FIG. 1), the plurality of power stage transistors 31 that make up the power stage radio-frequency amplifier circuit 60 of the two-stage radio-frequency amplifier circuit 64 (FIG. 6) is formed in the second member 20, and the plurality of driver stage transistors 51 (FIG. 6) that make up the driver stage radio-frequency amplifier circuit 63 is formed in the first member 10 (FIG. 2A). In contrast, in the thirteenth embodiment, both the plurality of power stage transistors 31 and the plurality of driver stage transistors 51 are formed in the second member 20. The plurality of driver stage transistors 51 is electrically connected to the plurality of power stage transistors 31. The plurality of input capacitors 36 is disposed in correspondence with the plurality of power stage transistors 31. Input capacitors 56 are respectively disposed in correspondence with the plurality of driver stage transistors 51. The plurality of power stage transistors 31 may be equally arranged without being divided into two blocks as in the case of the semiconductor device according to the eighth embodiment (FIG. 13).

The driver stage bias circuit 61, the power stage bias circuit 62, a plurality of capacitors 72C, a plurality of inductors 72L, an input terminal 65, a battery voltage terminal 66, a driver stage bias control terminal 67, and a power stage bias control terminal 68 are further disposed on or in the second member 20. One or some of the plurality of capacitors 72C may be disposed at locations that overlap the conductive protrusions 88.

The input-side circuit element 40 for the plurality of power stage transistors 31 includes the input capacitors 36, the plurality of driver stage transistors 51, the input capacitors 56, the driver stage bias circuit 61, the power stage bias circuit 62, the input terminal 65, and a plurality of passive elements such as the capacitors 72C and the inductors 72L. In this way, the input-side circuit element 40 can include active elements such as the driver stage transistors 51. The input terminal 65, the battery voltage terminal 66, the driver stage bias control terminal 67, and the power stage bias control terminals 68 are conductive protrusions similar to the conductive protrusions 88 (FIG. 2A). The terminal conductive protrusions that are the input terminal 65, the battery voltage terminal 66, the driver stage bias control terminal 67, and the power stage bias control terminals 68 are included in the input-side circuit element 40.

The bonding member 25 includes two conductor patterns 25A, 25D. The conductor pattern 25A covers the plurality of power stage transistors 31 in plan view as in the case of the first embodiment (FIG. 1). The input-side circuit element 40 is disposed outside the conductor pattern 25A in plan view. The other conductor pattern 25D is disposed at a location such that the conductor pattern 25D covers the driver stage transistors 51 in plan view.

FIG. 19 is a block diagram of the semiconductor device according to the thirteenth embodiment. The circuit configuration of the semiconductor device according to the thirteenth embodiment is the same as the circuit configuration (FIG. 6) of the semiconductor device according to the first embodiment. In FIG. 19, the input capacitors 36, 56 are not shown. In the first embodiment, the input matching circuit 70, the plurality of driver stage transistors 51, the inter-stage matching circuit 71, the plurality of power stage transistors 31, the driver stage bias circuit 61, and the power stage bias circuit 62 are provided on or in the first member 10, a module substrate, or the like, while, in the thirteenth embodiment, these are provided on or in the second member 20.

The input terminal 65 is connected to the input matching circuit 70, and a radio-frequency signal RFin is input to the input terminal 65. The radio-frequency signal output from the driver stage transistors 51 is input to the power stage transistors 31 via the inter-stage matching circuit 71. The input matching circuit 70 and the inter-stage matching circuit 71 are made up of the plurality of capacitors 72C and the plurality of inductors 72L (FIG. 18). The output terminal 80 is connected to the power stage transistors 31, and an output signal RFout is output from the output terminal 80. The power supply voltage Vcc1 is applied to the driver stage transistors 51 via the external connection terminal 81, and the power supply voltage Vcc2 is applied to the power stage transistors 31 via the other external connection terminal 81. The power supply voltage Vcc2 may be configured to be applied via the output terminal 80.

The battery voltage terminal 66 is connected to the driver stage bias circuit 61 and the power stage bias circuit 62, and a battery voltage Vbatt is supplied to the battery voltage terminal 66. The driver stage bias control terminal 67 is connected to the driver stage bias circuit 61, and a driver stage bias control signal Vbias1 is input to the driver stage bias control terminal 67. The two power stage bias control terminals 68 are connected to the power stage bias circuit 62, and power stage bias control signals Vbias2, Vbias3 are respectively input to the two power stage bias control terminals 68.

Next, advantageous effects of the thirteenth embodiment will be described. In the thirteenth embodiment as well, as in the case of the first embodiment (FIG. 1), since the plurality of power stage transistors 31 is covered with one conductor pattern 25A of the bonding member 25 in plan view, heat dissipation from the plurality of power stage transistors 31 to the first member 10 is not impaired. In addition, since the plurality of driver stage transistors 51 is covered with the other conductor pattern 25D of the bonding member 25 in plan view, heat dissipation from the plurality of driver stage transistors 51 is ensured.

Furthermore, since the input-side circuit element 40 for the power stage transistors 31 does not overlap the conductor pattern 25A that covers the power stage transistors 31 in plan view, the strength of coupling between the input-side circuit element 40 and the power stage transistors 31 with the bonding member 25 interposed therebetween is reduced as in the case of the first embodiment (FIG. 1).

### Fourteenth Embodiment

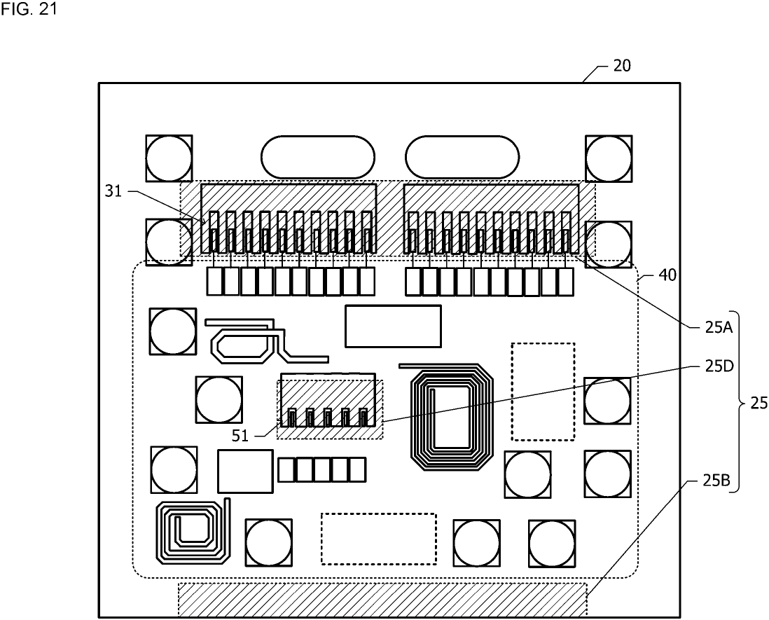

Next, a semiconductor device according to a fourteenth embodiment will be described with reference to FIG. 20. Hereinafter, the description of components common to the semiconductor device (FIGS. 18 and 19) according to the thirteenth embodiment will not be repeated.

FIG. 20 is a schematic plan view of the second member 20 of the semiconductor device according to the fourteenth embodiment. In the thirteenth embodiment (FIG. 18), one conductor pattern 25D of the bonding member 25 covers the driver stage transistors 51 in plan view. In contrast, in the fourteenth embodiment, one conductor pattern 25B is disposed along the edge of the second member 20 across the input-side circuit element 40 from the power stage transistors 31 in plan view. The input-side circuit element 40 does not overlap none of the conductor patterns 25A, 25B of the bonding member 25 in plan view.

Next, advantageous effects of the fourteenth embodiment will be described. With the fourteenth embodiment as well, as in the case of the thirteenth embodiment, heat dissipation from the plurality of power stage transistors 31 to the first member 10 is not impaired, and coupling between the input-side circuit element 40 and the power stage transistors 31 with the bonding member 25 interposed therebetween is reduced. In addition, since the two conductor patterns 25A, 25B of the bonding member 25 are disposed across a region in which the input-side circuit element 40 is disposed, the second member 20 is further stably supported.

### Fifteenth Embodiment

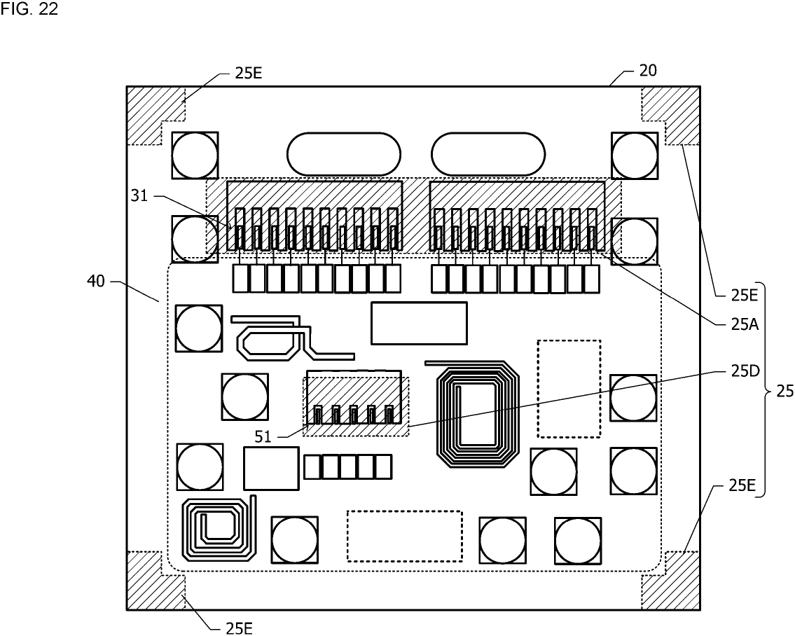

Next, a semiconductor device according to a fifteenth embodiment will be described with reference to FIG. 21. Hereinafter, the description of components common to the semiconductor device (FIGS. 18 and 19) according to the thirteenth embodiment will not be repeated.

FIG. 21 is a schematic plan view of the second member 20 of the semiconductor device according to the fifteenth embodiment. In the fifteenth embodiment, the bonding member 25 includes the conductor pattern 25B in addition to the two conductor patterns 25A, 25D included in the bonding member 25 of the semiconductor device according to the thirteenth embodiment (FIG. 18).

Next, advantageous effects of the fifteenth embodiment will be described. In the fifteenth embodiment as well, as in the case of the thirteenth embodiment (FIG. 19), heat dissipation from the power stage transistors 31 and the driver stage transistors 51 to the first member 10 is not impaired, and coupling between the input-side circuit element 40 and the power stage transistors 31 with the bonding member 25 interposed therebetween is reduced. In addition, as in the case of the fourteenth embodiment (FIG. 20), the second member 20 is further stably supported.

### Sixteenth Embodiment

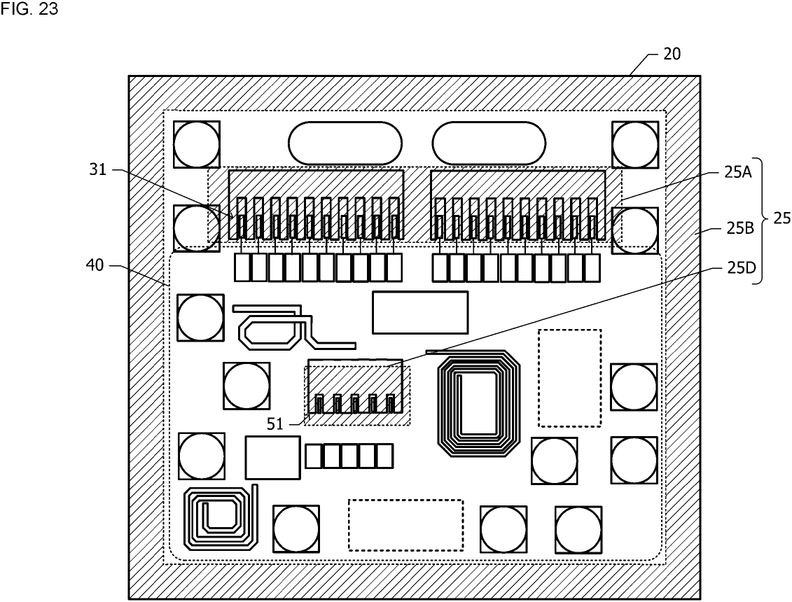

Next, a semiconductor device according to a sixteenth embodiment will be described with reference to FIG. 22. Hereinafter, the description of components common to the semiconductor device (FIGS. 18 and 19) according to the thirteenth embodiment will not be repeated.

FIG. 22 is a schematic plan view of the second member 20 of the semiconductor device according to the sixteenth embodiment. In the sixteenth embodiment, the bonding member 25 includes four conductor patterns 25E respectively disposed at four corners of the second member 20 in addition to the two conductor patterns 25A, 25D included in the bonding member 25 of the semiconductor device according to the thirteenth embodiment (FIG. 18).

Next, advantageous effects of the sixteenth embodiment will be described. In the sixteenth embodiment, the bonding strength of the second member 20 with the first member 10 is increased as compared to the semiconductor device according to the thirteenth embodiment. The four conductor patterns 25E do not overlap none of the power stage transistors 31 and the input-side circuit element 40 in plan view. Therefore, even when the conductor patterns 25E are newly added to the semiconductor device according to the thirteenth embodiment (FIG. 18), the effect of reducing coupling between the input-side circuit element 40 and the power stage transistors 31 with the bonding member 25 interposed therebetween is not impaired.

### Seventeenth Embodiment

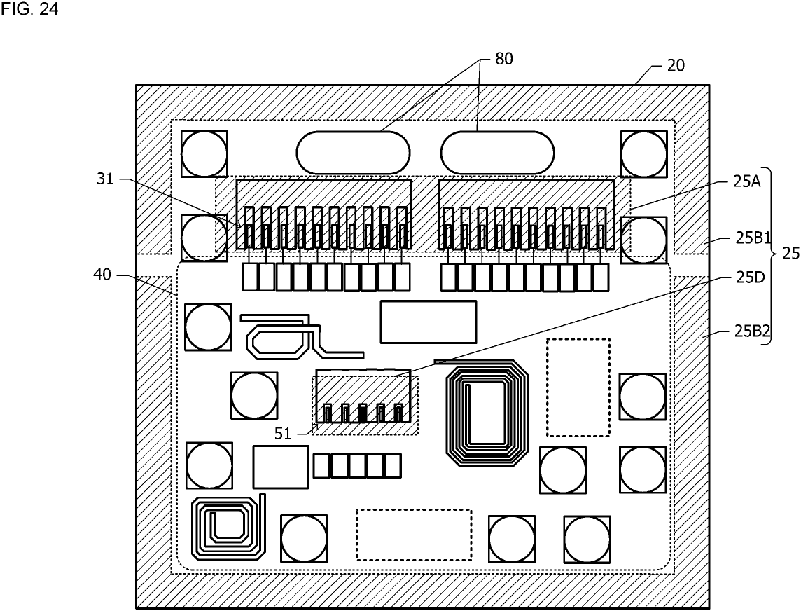

Next, a semiconductor device according to a seventeenth embodiment will be described with reference to FIG. 23. Hereinafter, the description of components common to the semiconductor device (FIGS. 18 and 19) according to the thirteenth embodiment will not be repeated.

FIG. 23 is a schematic plan view of the second member 20 of the semiconductor device according to the seventeenth embodiment. In the seventeenth embodiment, the bonding member 25 includes the conductor pattern 25B disposed along the edge of the second member 20 in addition to the two conductor patterns 25A, 25D included in the bonding member 25 of the semiconductor device according to the thirteenth embodiment (FIG. 18). The conductor pattern 25B has a continuous annular shape in plan view and is disposed all around the second member 20.

Next, advantageous effects of the seventeenth embodiment will be described. In the seventeenth embodiment, since the bonding member 25 includes the conductor pattern 25B disposed along the edge of the second member 20, the bonding strength of the second member 20 with the first member 10 is further increased as compared to the semiconductor device according to the thirteenth embodiment (FIG. 18). The conductor pattern 25B do not overlap none of the power stage transistors 31 and the input-side circuit element 40 in plan view. Therefore, even when the conductor pattern 25B is newly added to the semiconductor device according to the thirteenth embodiment (FIG. 18), the effect of reducing coupling between the input-side circuit element 40 and the power stage transistors 31 with the bonding member 25 interposed therebetween is not impaired.

### Eighteenth Embodiment

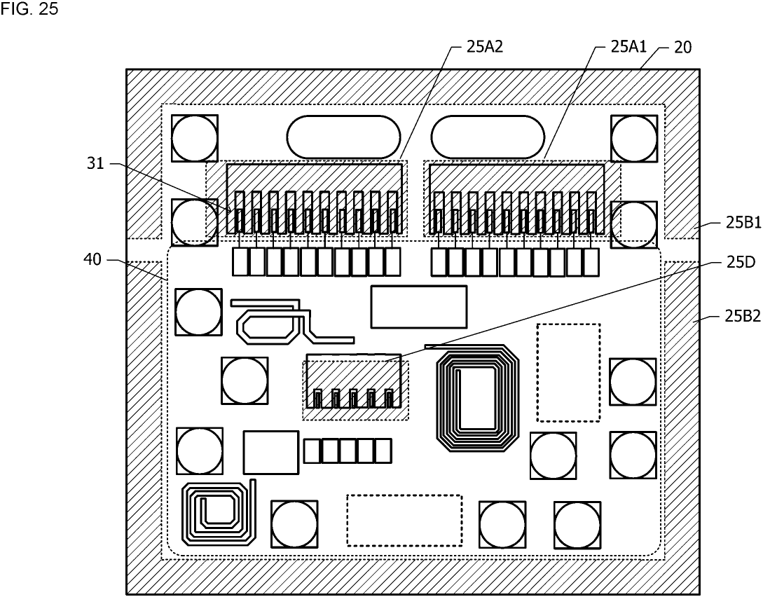

Next, a semiconductor device according to an eighteenth embodiment will be described with reference to FIG. 24. Hereinafter, the description of components common to the semiconductor device (FIG. 23) according to the seventeenth embodiment will not be repeated.

FIG. 24 is a schematic plan view of the second member 20 of the semiconductor device according to the eighteenth embodiment. In the seventeenth embodiment (FIG. 23), no gap is provided in the conductor pattern 25B provided along the edge of the second member 20, and the conductor pattern 25B has a closed annular shape. In contrast, in the eighteenth embodiment, the conductor pattern 25B (FIG. 23) according to the seventeenth embodiment is divided into a conductor pattern 25B1 adjacent to a region in which the plurality of power stage transistors 31 and the output terminals 80 are disposed and a conductor pattern 25B2 adjacent to a region in which the input-side circuit element 40 is disposed.

Next, advantageous effects of the eighteenth embodiment will be described. In the eighteenth embodiment, since the conductor patterns 25B1, 25B2 provided along the edge of the second member 20 are separated, the strength of coupling between the input-side circuit element 40 and the plurality of power stage transistors 31 with the bonding member 25 interposed therebetween is further reduced as compared to the seventeenth embodiment (FIG. 23).

### Nineteenth Embodiment

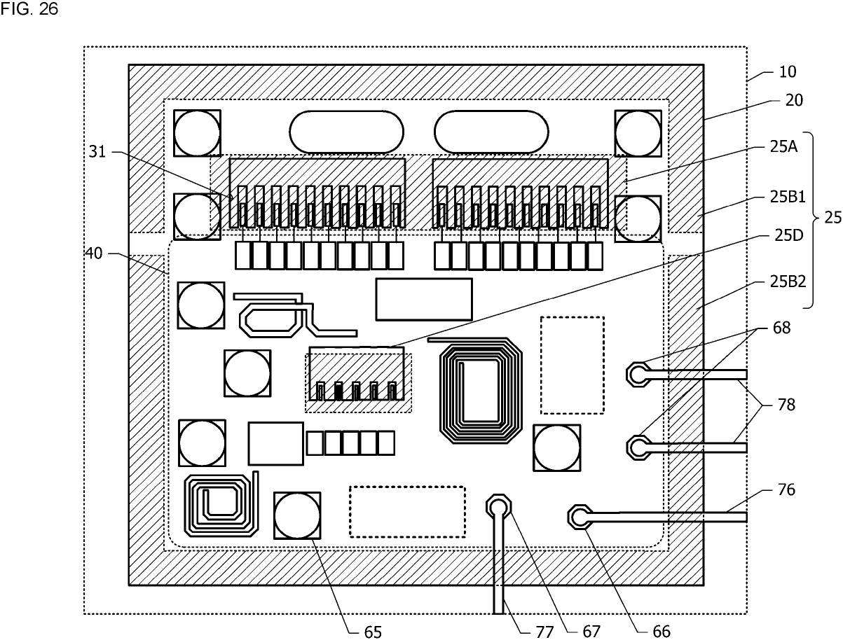

Next, a semiconductor device according to a nineteenth embodiment will be described with reference to FIG. 25. Hereinafter, the description of components common to the semiconductor device (FIG. 24) according to the eighteenth embodiment will not be repeated.

FIG. 25 is a schematic plan view of the second member 20 of the semiconductor device according to the nineteenth embodiment. In the eighteenth embodiment (FIG. 24), the plurality of power stage transistors 31 is divided into two blocks, and one conductor pattern 25A is disposed for the two blocks. In contrast, in the nineteenth embodiment, as in the case of the seventh embodiment (FIG. 12), conductor patterns 25A1, 25A2 are respectively disposed for the blocks and are separated from each other.

Next, advantageous effects of the nineteenth embodiment will be described. In the nineteenth embodiment, as in the case of the seventh embodiment, thermal influence between the blocks of the plurality of power stage transistors 31 reduces. When the plurality of power stage transistors 31 makes up a Doherty power amplifier, thermal influence between a carrier amplifier and a peak amplifier is reduced, and the high-efficiency operation of the Doherty power amplifier is implemented.

### Twentieth Embodiment

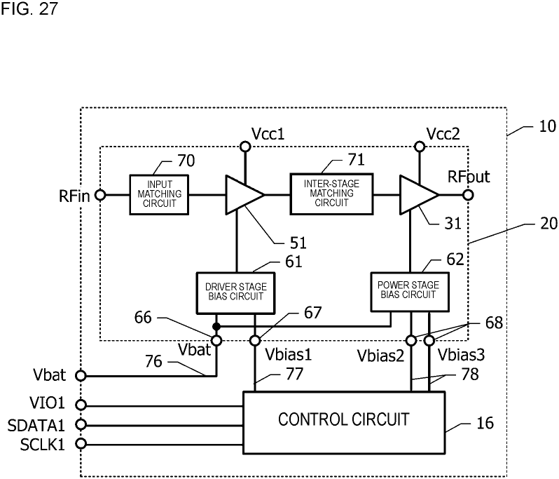

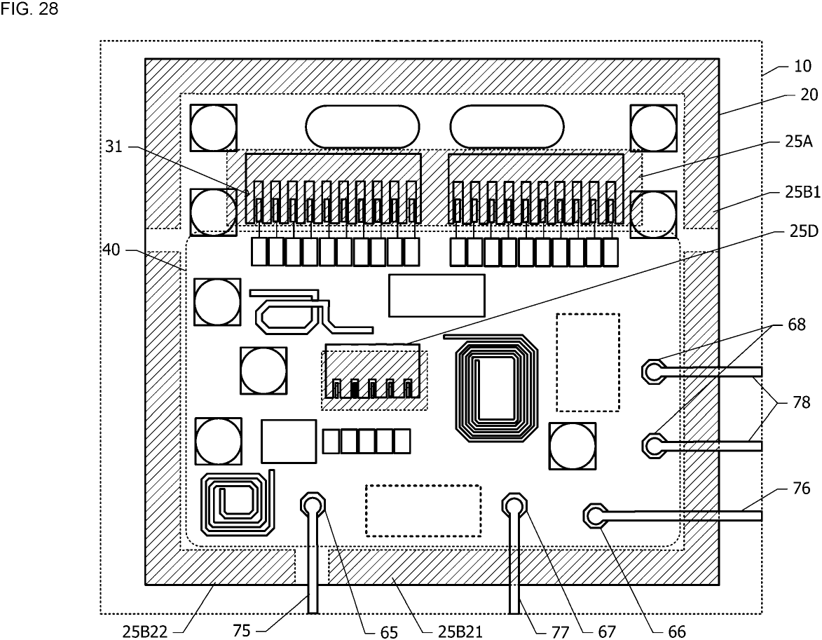

Next, a semiconductor device according to a twentieth embodiment will be described with reference to FIGS. 26 and 27. Hereinafter, the description of components common to the semiconductor device (FIG. 24) according to the eighteenth embodiment will not be repeated.

FIG. 26 is a schematic plan view of the semiconductor device according to the twentieth embodiment. The second member 20 is bonded to the first member 10. In the eighteenth embodiment, the battery voltage terminal 66, the driver stage bias control terminal 67, and the two power stage bias control terminals 68 are conductive protrusions for connection with an external circuit. In contrast, in the twentieth embodiment, an inter-member connection wire 76 is connected to the battery voltage terminal 66, an inter-member connection wire 77 is connected to the driver stage bias control terminal 67, and two inter-member connection wires 78 are respectively connected to the two power stage bias control terminals 68.

The inter-member connection wires 76, 77, 78 connect a circuit formed in the first member 10 with a circuit formed in the second member 20 as in the case of the inter-member connection wires 86 (FIG. 2) of the semiconductor device according to the first embodiment. These inter-member connection wires 76, 77, 78 are connected to a control circuit formed on or in the first member 10. These inter-member connection wires 76, 77, 78 respectively intersect with the conductor pattern 25B2 in plan view and overlap the conductor pattern 25B2 at intersecting portions.

FIG. 27 is a block diagram of the semiconductor device according to the twentieth embodiment. The configuration of the power stage transistors 31, driver stage transistors 51, driver stage bias circuit 61, power stage bias circuit 62, input matching circuit 70, and inter-stage matching circuit 71 formed in the second member 20 is the same as the configuration of those of the semiconductor device (FIG. 19) according to the thirteenth embodiment. A control circuit 16 is formed on or in the first member 10.

A power supply voltage VIO1, a control signal SDATA1, and a clock signal SCLK1 are supplied to the control circuit 16. The control circuit 16 supplies a driver stage bias control signal Vbias1 to the driver stage bias circuit 61 via the inter-member connection wire 77 and the driver stage bias control terminal 67 in accordance with the control signal SDATA1. In addition, the control circuit 16 supplies power stage bias control signals Vbias2, Vbias3 to the power stage bias circuit 62 via the inter-member connection wires 78 and the power stage bias control terminals 68 in accordance with the control signal SDATA1. A battery voltage Vbatt is supplied from the first member 10 to the driver stage bias circuit 61 and the power stage bias circuit 62 via the inter-member connection wire 76 and the battery voltage terminal 66.

Next, advantageous effects of the twentieth embodiment will be described. With the twentieth embodiment as well, as in the case of the eighteenth embodiment (FIG. 24), coupling between the input-side circuit element 40 and the power stage transistors 31 with the bonding member 25 interposed therebetween is reduced without impairing heat dissipation from the power stage transistors 31 to the first member 10.

In the eighteenth embodiment (FIG. 24), the battery voltage terminal 66, the driver stage bias control terminal 67, and the power stage bias control terminals 68 are connected to a module substrate or the like and are connected to a control circuit with wires in the module substrate, interposed therebetween. In contrast, in the twentieth embodiment, the battery voltage terminal 66, the driver stage bias control terminal 67, and the two power stage bias control terminals 68 are connected to the control circuit 16 within the semiconductor device according to the twentieth embodiment without passing through wires in the module substrate.

### Twenty-First Embodiment

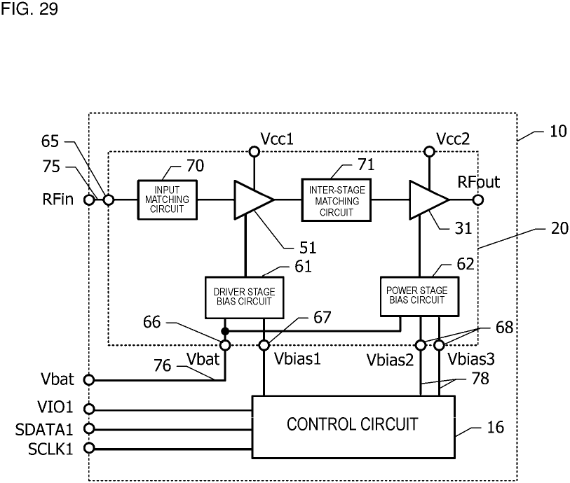

Next, a semiconductor device according to a twenty-first embodiment will be described with reference to FIGS. 28 and 29. Hereinafter, the description of components common to the semiconductor device (FIGS. 26 and 27) according to the twentieth embodiment will not be repeated.

FIG. 28 is a schematic plan view of the semiconductor device according to the twenty-first embodiment. In the twentieth embodiment (FIG. 26), the input terminal 65 is made up of a conductive protrusion. A radio-frequency signal is input from the module substrate, connected to the conductive protrusion, to the input terminal 65. In contrast, in the twenty-first embodiment, the inter-member connection wire 75 is connected to the input terminal 65.

The conductor pattern 25B2 of the semiconductor device (FIG. 26) according to the twentieth embodiment is divided into two conductor patterns 25B21, 25B22 at a portion at which the conductor pattern 25B2 intersects with the inter-member connection wire 75. In other words, the inter-member connection wire 75 does not overlap none of the conductor patterns 25A, 25B1, 25B21, 25B22, 25D of the bonding member 25 in plan view.

FIG. 29 is a block diagram of the semiconductor device according to the twenty-first embodiment. A radio-frequency signal RFin is input from the first member 10 via the inter-member connection wire 75 to the input terminal 65 of the second member 20.

Next, advantageous effects of the twenty-first embodiment will be described. In the twenty-first embodiment, a radio-frequency signal is input from the circuit formed on or in the first member 10 to the input terminal 65 of the second member 20 without passing through wires in the module substrate or the like. Alternatively, a switch for selecting one from among a plurality of nodes to which a radio-frequency signal is supplied may be formed on or in the first member 10, and the selected node may be connected to the input terminal 65 with the inter-member connection wire 75 interposed therebetween. For example, when a mixer that up-converts an intermediate frequency signal to a radio-frequency signal is formed on or in the first member 10, a radio-frequency signal RFin can be supplied from the mixer to the second member 20 within the semiconductor device according to the twenty-first embodiment.

Since the inter-member connection wire 75 through which a radio-frequency signal RFin is transmitted does not overlap the bonding member 25 in plan view, an increase in parasitic capacitance between the inter-member connection wire 75 and the bonding member 25 is suppressed. Thus, the effect of suppressing the feedback of an output signal from the power stage transistors 31 to the inter-member connection wire 75 is further increased.

### Twenty-Second Embodiment

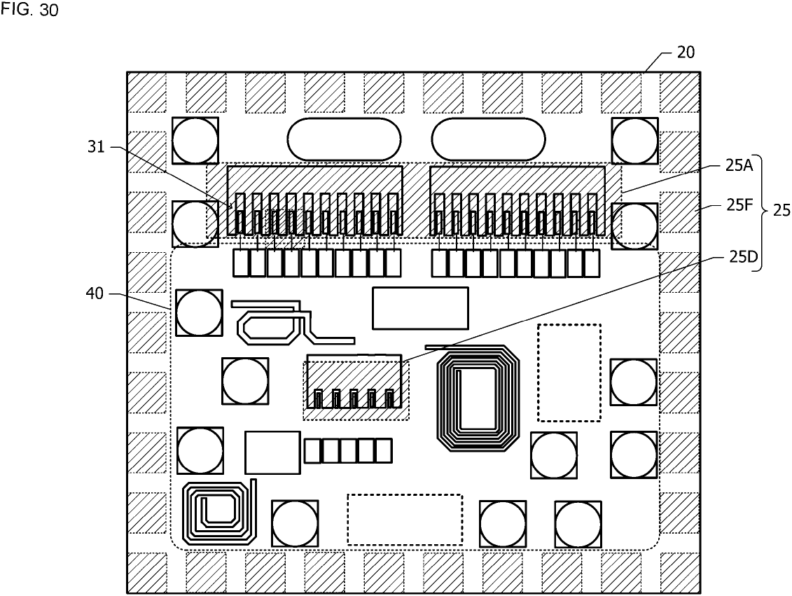

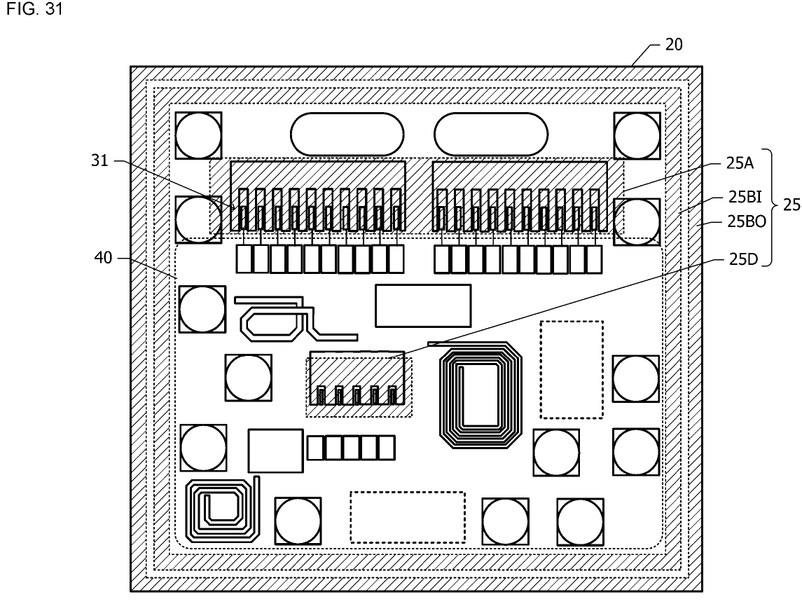

Next, a semiconductor device according to a twenty-second embodiment will be described with reference to FIG. 30. Hereinafter, the description of components common to the semiconductor device (FIG. 23) according to the seventeenth embodiment will not be repeated.

FIG. 30 is a schematic plan view of the second member 20 of the semiconductor device according to the twenty-second embodiment. In the seventeenth embodiment (FIG. 23), the conductor pattern 25B disposed along the edge of the second member 20 has a closed annular shape. In contrast, in the twenty-second embodiment, a plurality of conductor patterns 25F is arranged at intervals in a circumferential direction along the edge of the second member 20.

Next, advantageous effects of the twenty-second embodiment will be described. With the twenty-second embodiment as well, as in the case of the seventeenth embodiment (FIG. 23), coupling between input-side circuit element 40 and the power stage transistors 31 with the bonding member 25 interposed therebetween is reduced without impairing heat dissipation from the power stage transistors 31 to the first member 10. In addition, in the twenty-second embodiment, coupling of circuit elements disposed near the edge of the second member 20 with each other with the conductor pattern 25B disposed along the edge of the second member 20 and interposed therebetween is suppressed.

### Twenty-Third Embodiment

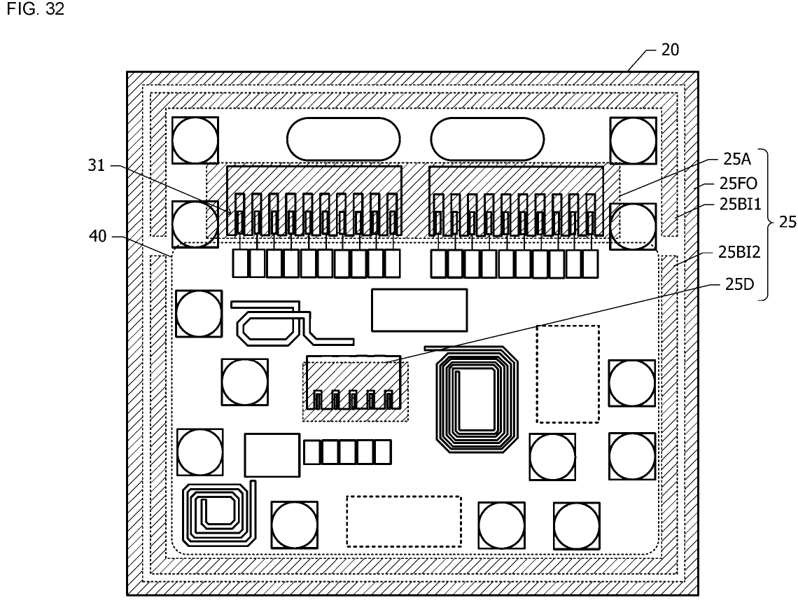

Next, a semiconductor device according to a twenty-third embodiment will be described with reference to FIG. 31. Hereinafter, the description of components common to the semiconductor device (FIG. 23) according to the seventeenth embodiment will not be repeated.

FIG. 31 is a schematic plan view of the second member 20 of the semiconductor device according to the twenty-third embodiment. In the seventeenth embodiment (FIG. 23), a single line of the conductor pattern 25B disposed along the edge of the second member 20 surrounds a region inside the second member 20 in plan view. In contrast, in the twenty-third embodiment, double lines of conductor patterns 25BO, 25BI disposed along the edge of the second member 20 surround a region inside the second member 20 in plan view. The conductor pattern 25BO is disposed on an outer peripheral side of the other conductor pattern 25BI, and a space is ensured therebetween. Each of the conductor patterns 25BO, 25BI has a continuous closed annular shape.

Next, advantageous effects of the twenty-third embodiment will be described. With the twenty-third embodiment as well, as in the case of the seventeenth embodiment (FIG. 23), coupling between input-side circuit element 40 and the power stage transistors 31 with the bonding member 25 interposed therebetween is reduced without impairing heat dissipation from the power stage transistors 31 to the first member 10. In the twenty-third embodiment as well, the bonding strength equivalent to that of the seventeenth embodiment (FIG. 23) is ensured.

### Twenty-Fourth Embodiment

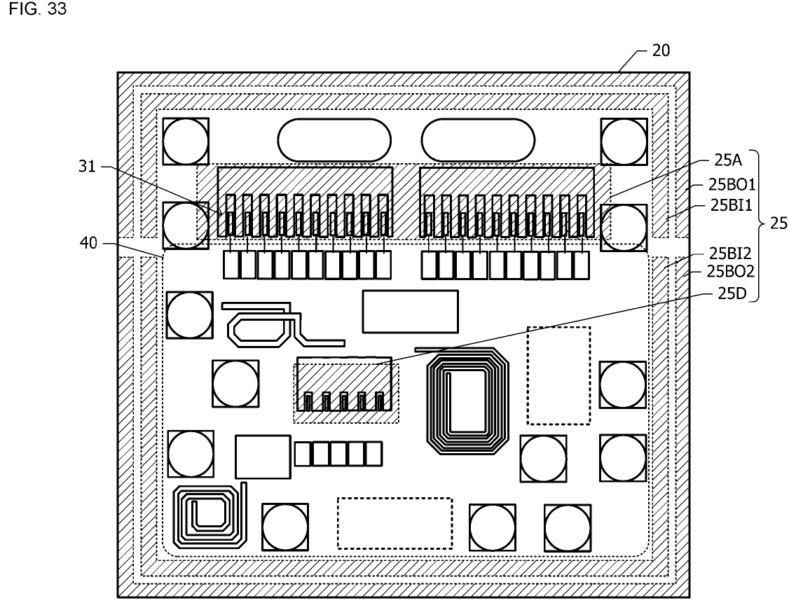

Next, a semiconductor device according to a twenty-fourth embodiment will be described with reference to FIG. 32. Hereinafter, the description of components common to the semiconductor device (FIG. 31) according to the twenty-third embodiment will not be repeated.

FIG. 32 is a schematic plan view of the second member 20 of the semiconductor device according to the twenty-fourth embodiment. In the twenty-third embodiment (FIG. 31), any of the double lines of conductor patterns 25BO, 25BI disposed along the edge of the second member 20 has a continuous closed annular shape. In contrast, in the twenty-fourth embodiment, instead of the inner peripheral-side closed conductor pattern 25BI (FIG. 31), two conductor patterns 25BI1, 25BI2 separated in the circumferential direction are disposed. The conductor pattern 25BI1 surrounds in a U-shape from three sides a region in which the plurality of power stage transistors 31 and the output terminals 80 are disposed. The other conductor pattern 25BI2 surrounds in a U-shape from three sides a region in which the input-side circuit element 40 is disposed.

Next, advantageous effects of the twenty-fourth embodiment will be described. In the present embodiment, since the inner peripheral-side conductor patterns 25BI1, 25BI2 disposed along the edge of the second member 20 are separated from each other, the strength of coupling between the input-side circuit element 40 and the power stage transistors 31 with the bonding member 25 interposed therebetween is further reduced as compared to the twenty-third embodiment (FIG. 31).

### Twenty-Fifth Embodiment

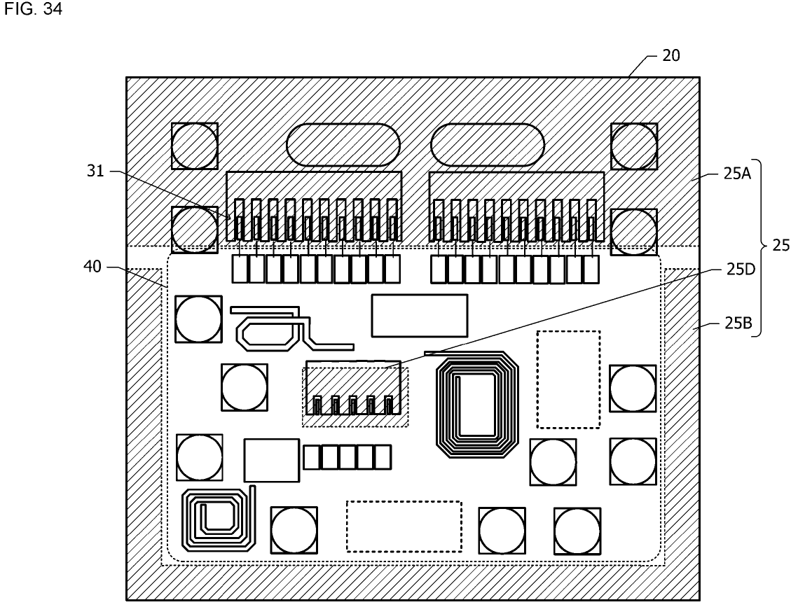

Next, a semiconductor device according to a twenty-fifth embodiment will be described with reference to FIG. 33. Hereinafter, the description of components common to the semiconductor device (FIG. 32) according to the twenty-fourth embodiment will not be repeated.

FIG. 33 is a schematic plan view of the second member 20 of the semiconductor device according to the twenty-fifth embodiment. In the twenty-fourth embodiment (FIG. 32), two conductor patterns 25BI1, 25BI2 are disposed on the inner peripheral side along the edge of the second member 20, and one conductor pattern 25BO is disposed on the outer peripheral side. In contrast, in the twenty-fifth embodiment, instead of the outer peripheral-side conductor pattern 25BO according to the twenty-fourth embodiment (FIG. 32), two conductor patterns 25BO1, 25BO2 separated in the circumferential direction are disposed. The outer peripheral-side two conductor patterns 25BO1, 25BO2 are separated at substantially the same portion at which the inner peripheral-side conductor patterns 25BI1, 25BI2 are separated in the circumferential direction. The separated portion of the outer peripheral-side conductor patterns 25BO1, 25BO2 and the separated portion of the inner peripheral-side conductor patterns 25BI1, 25BI2 may be shifted in the circumferential direction.

Next, advantageous effects of the twenty-fifth embodiment will be described. In the twenty-fifth embodiment, since not only the inner peripheral-side conductor patterns 25BI1, 25BI2 disposed along the edge of the second member 20 but also the outer peripheral-side conductor patterns 25BO1, 25BO2 are separated from each other, the strength of coupling between the input-side circuit element 40 and the power stage transistors 31 with the bonding member 25 interposed therebetween is further reduced as compared to the twenty-fourth embodiment (FIG. 32).

### Twenty-Sixth Embodiment

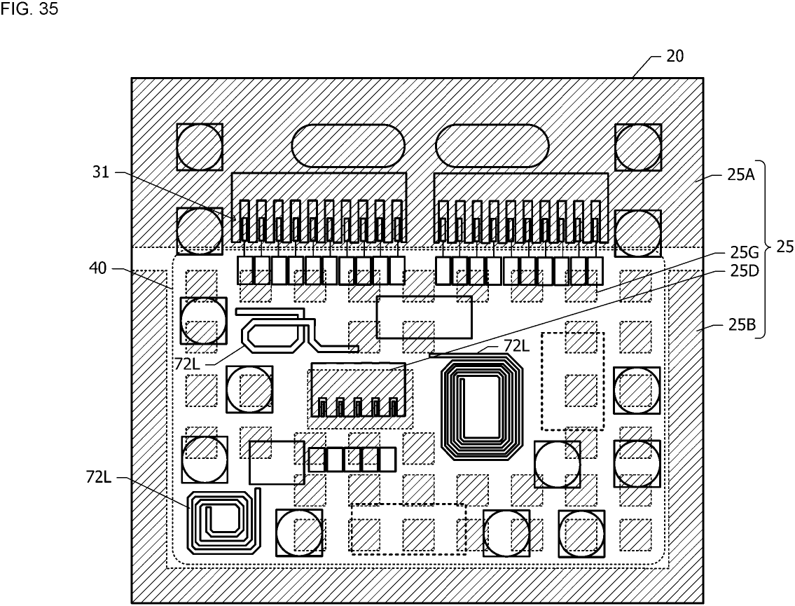

Next, a semiconductor device according to a twenty-sixth embodiment will be described with reference to FIG. 34. Hereinafter, the description of components common to the semiconductor device (FIGS. 18 and 19) according to the thirteenth embodiment will not be repeated.

FIG. 34 is a schematic plan view of the second member 20 of the semiconductor device according to the twenty-sixth embodiment. In the thirteenth embodiment (FIG. 18), the conductor pattern 25A that covers the plurality of power stage transistors 31 in plan view is disposed with a space apart from the edge of the second member 20. In contrast, in the twenty-sixth embodiment, the conductor pattern 25A that covers the plurality of power stage transistors 31 in plan view expands in a direction not to overlap the input-side circuit element 40, and reaches the edge of the second member 20.

In addition, the conductor pattern 25B is disposed along the edge of the second member 20 so as to surround the input-side circuit element 40 in a U-shape from three sides. The conductor pattern 25B has substantially the same shape as the conductor pattern 25B2 of the semiconductor device (FIG. 24) according to the eighteenth embodiment and is disposed at substantially the same location in plan view.

Next, advantageous effects of the twenty-sixth embodiment will be described. Since the conductor pattern 25A of the semiconductor device according to the twenty-sixth embodiment is larger than the conductor pattern 25A of the semiconductor device (FIG. 18) according to the thirteenth embodiment, heat dissipation from the plurality of power stage transistors 31 to the first member 10 is increased. Since the conductor pattern 25A does not overlap the input-side circuit element 40 in plan view even when the conductor pattern 25A that covers the plurality of power stage transistors 31 in plan view is expanded, the effect of reducing coupling between the input-side circuit element 40 and the plurality of power stage transistors 31 with the bonding member 25 interposed therebetween is not impaired.

### Twenty-Seventh Embodiment

Next, a semiconductor device according to a twenty-seventh embodiment will be described with reference to FIG. 35. Hereinafter, the description of components common to the semiconductor device (FIG. 34) according to the twenty-sixth embodiment will not be repeated.

FIG. 35 is a schematic plan view of the second member 20 of the semiconductor device according to the twenty-seventh embodiment. The bonding member 25 of the semiconductor device according to the twenty-seventh embodiment includes a plurality of conductor patterns 25G in addition to the conductor patterns 25A, 25B, 25D of the semiconductor device (FIG. 34) according to the twenty-sixth embodiment. The plurality of conductor patterns 25G is dotted around a region in which the input-side circuit element 40 is disposed. However, the plurality of conductor patterns 25G is disposed so as not to overlap the inductors 72L of the input-side circuit element 40 in plan view.

Next, advantageous effects of the twenty-seventh embodiment will be described. In the twenty-seventh embodiment, since the plurality of conductor patterns 25G is disposed in addition to the conductor patterns 25A, 25B, 25D according to the twenty-sixth embodiment (FIG. 34), the bonding strength of the second member 20 with the first member 10 is further increased. Since the conductor patterns 25G do not overlap the inductors 72L in plan view, radio-frequency magnetic fields generated in the inductors 72L are not blocked by the conductor patterns 25G. Therefore, the influence of the conductor patterns 25G on the inductance of each of the inductors 72L is small.

### Twenty-Eighth Embodiment

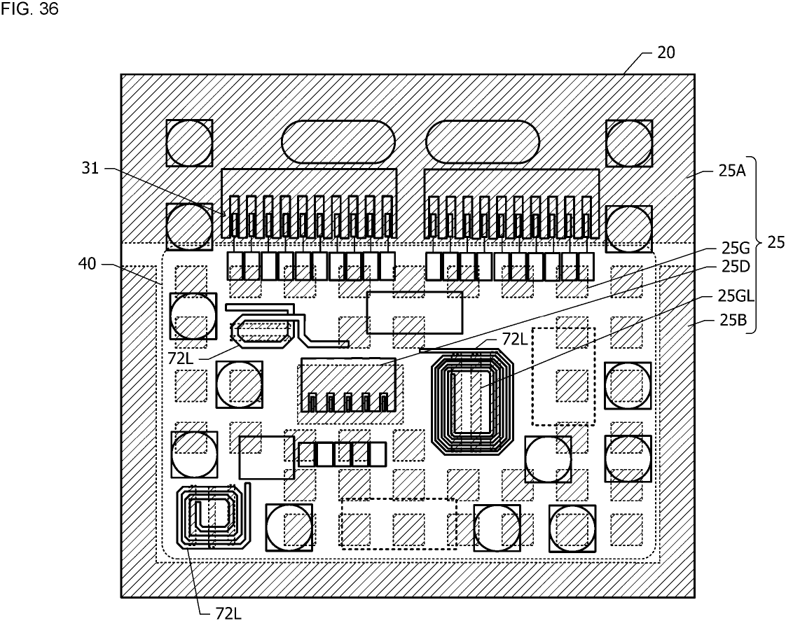

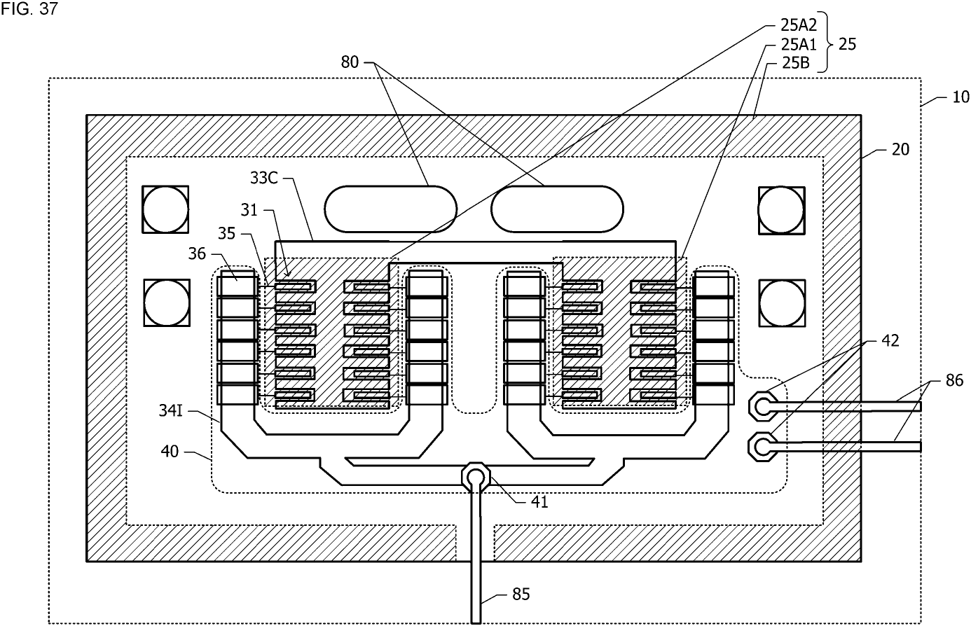

Next, a semiconductor device according to a twenty-eighth embodiment will be described with reference to FIG. 36. Hereinafter, the description of components common to the semiconductor device (FIG. 35) according to the twenty-seventh embodiment will not be repeated.

FIG. 36 is a schematic plan view of the second member 20 of the semiconductor device according to the twenty-eighth embodiment. In the twenty-seventh embodiment (FIG. 35), the plurality of conductor patterns 25G is disposed so as not to overlap the inductors 72L in plan view. In contrast, in the twenty-eighth embodiment, conductor patterns 25GL are disposed in a region that overlaps the spiral inductor 72L in plan view. The conductor patterns 25GL that overlap the inductor 72L in plan view each have a narrow and long shape as compared to the other conductor patterns 25G.

Next, advantageous effects of the twenty-eighth embodiment will be described. In the twenty-eighth embodiment, since the conductor patterns 25GL are also disposed at a location that overlaps the inductor 72L, the bonding strength of the second member 20 with the first member 10 is further increased as compared to the twenty-seventh embodiment (FIG. 35). Since the conductor patterns 25GL disposed at a location that overlaps the inductor 72L each have a narrow and long shape, an eddy current due to a radio-frequency magnetic field generated by the inductor 72L is less likely to flow. Therefore, the influence on the inductance of the inductor 72L is reduced.

### TWENTY-NINTH EMBODIMENT

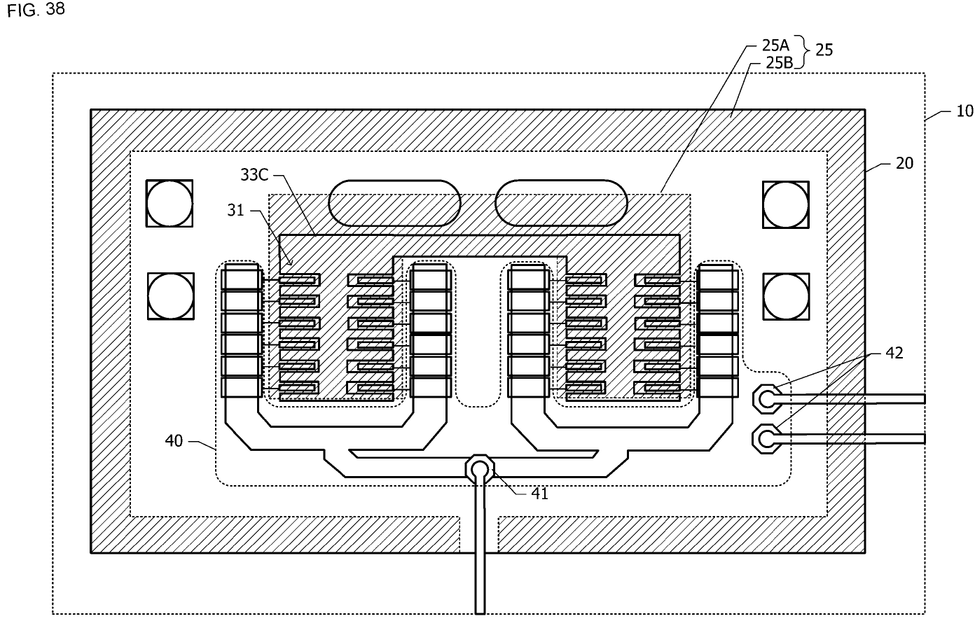

Next, a semiconductor device according to a twenty-ninth embodiment will be described with reference to FIG. 37. Hereinafter, the description of components common to the semiconductor device (FIG. 10) according to the fifth embodiment will not be repeated.

FIG. 37 is a schematic plan view of the semiconductor device according to the twenty-ninth embodiment. In the fifth embodiment (FIG. 10), the plurality of power stage transistors 31 of the two blocks is disposed along a straight line as a whole. In contrast, in the twenty-ninth embodiment, a plurality of power stage transistors 31 arranged substantially parallel in two lines makes up one block, and the two blocks are disposed. The two blocks are disposed so as to be arranged in a direction substantially orthogonal to the array direction of the power stage transistors 31.

In each of the blocks, the input wire 35 extends from each of the plurality of power stage transistors 31 in two lines toward the outside of the transistor array, and the input capacitor 36 is connected to each of the input wires 35. An array of the input capacitors 36 is formed in correspondence with each array of the power stage transistors 31. The collector wires 33C are disposed between the two transistor arrays.

The input terminal 41 is disposed on one side of a band-shaped region that extends in a direction parallel to a direction in which the two blocks are arranged (right and left direction in FIG. 37) and that covers the plurality of power stage transistors 31 of two blocks, and the output terminals 80 are disposed on the other side. In addition, the two bias terminals 42 are disposed. The collector wire 33C of one of the blocks and the collector wire 33C of the other one of the blocks are connected to each other on the side where the output terminals 80 are disposed and are further connected to the output terminals 80. The collector wire 33C of one of the blocks, the conductor wire 33C of the other one of the blocks, and the portion connecting both are made up of one conductor pattern.

The signal input wires 34I are disposed so as to respectively overlap the capacitor arrays each including the plurality of input capacitors 36. Each of the signal input wires 34I extends to the side on which the input terminal 41 is disposed and is connected to the input terminal 41. The inter-member connection wire 85 is connected to the input terminal 41, and the two inter-member connection wires 86 are respectively connected to the two bias terminals 42.

A radio-frequency signal input to the input terminal 41 is output to the output terminals 80 through the signal input wires 34I, the plurality of input capacitors 36, the plurality of power stage transistors 31, and the collector wires 33C.

The bonding member 25 includes conductor patterns 25A1, 25A2, 25B. In plan view, the conductor pattern 25A1 overlaps the plurality of power stage transistors 31 of one of the blocks, and the conductor pattern 25A2 overlaps the plurality of power stage transistors 31 of the other one of the blocks. The input-side circuit element 40 including the plurality of input capacitors 36 and the input terminal 41 is disposed outside the conductor patterns 25A1, 25A2 in plan view.

The conductor pattern 25B is disposed along the edge of the second member 20 in plan view. The conductor pattern 25B has a gap. The gap is disposed at a portion at which the conductor pattern 25B intersects with the inter-member connection wire 85 connected to the input terminal 41.

Next, advantageous effects of the twenty-ninth embodiment will be described. In the twenty-ninth embodiment as well, as in the case of the fifth embodiment, since the conductor patterns 25A1, 25A2 that cover the plurality of power stage transistors 31 in plan view are provided, heat dissipation from the plurality of power stage transistors 31 to the first member 10 is not impaired. In addition, since the strength of coupling between the input-side circuit element 40 and the output-side circuit of the plurality of power stage transistors 31 with the bonding member 25 interposed therebetween reduces, the oscillation and characteristics deterioration, such as a decrease in gain due to interference therebetween, are suppressed. In addition, since the conductor pattern 25B is disposed along the edge of the second member 20, the bonding strength of the second member 20 with the first member 10 is increased.

### Thirtieth Embodiment

Next, a semiconductor device according to a thirtieth embodiment will be described with reference to FIG. 38. Hereinafter, the description of components common to the semiconductor device (FIG. 37) according to the twenty-ninth embodiment will not be repeated.

FIG. 38 is a schematic plan view of the semiconductor device according to the thirtieth embodiment. In the twenty-ninth embodiment (FIG. 37), the conductor pattern 25A1 and the conductor pattern 25A2 that respectively overlap the pluralities of power stage transistors 31 of two blocks in plan view are separated from each other. In contrast, in the thirtieth embodiment, one conductor pattern 25A overlaps the plurality of power stage transistors 31 of two blocks in plan view. In this case as well, the one conductor pattern 25A does not overlap the input-side circuit element 40 in plan view.

Next, advantageous effects of the thirtieth embodiment will be described. In the thirtieth embodiment, the area of the conductor pattern 25A that covers the plurality of power stage transistors 31 in plan view is wider than that in the twenty-ninth embodiment (FIG. 37). Therefore, heat dissipation from the plurality of power stage transistors 31 to the first member 10 is improved.

### Thirty-First Embodiment

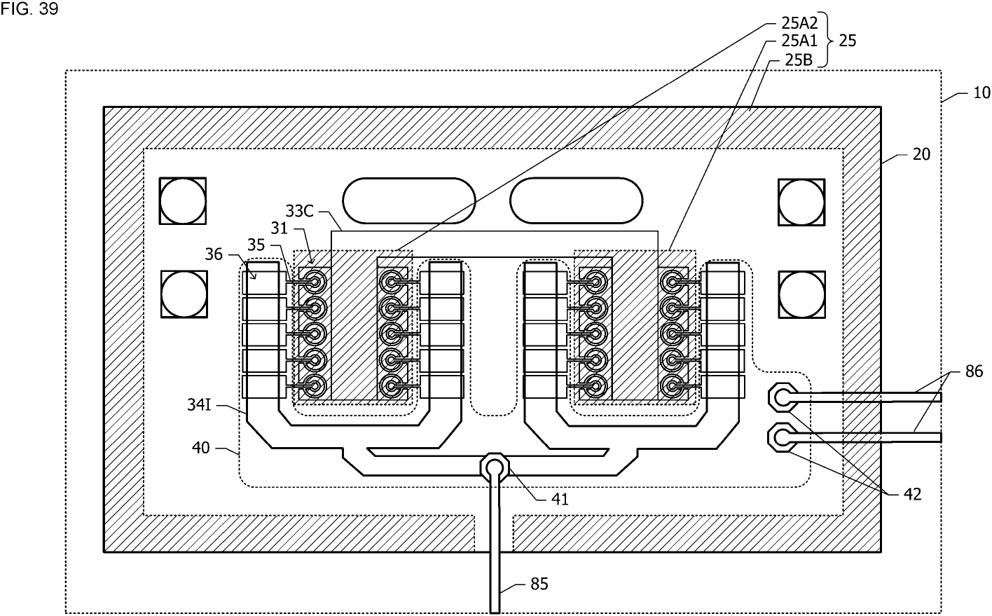

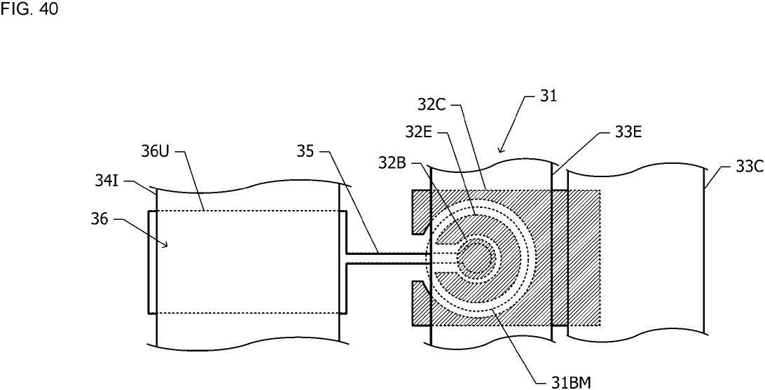

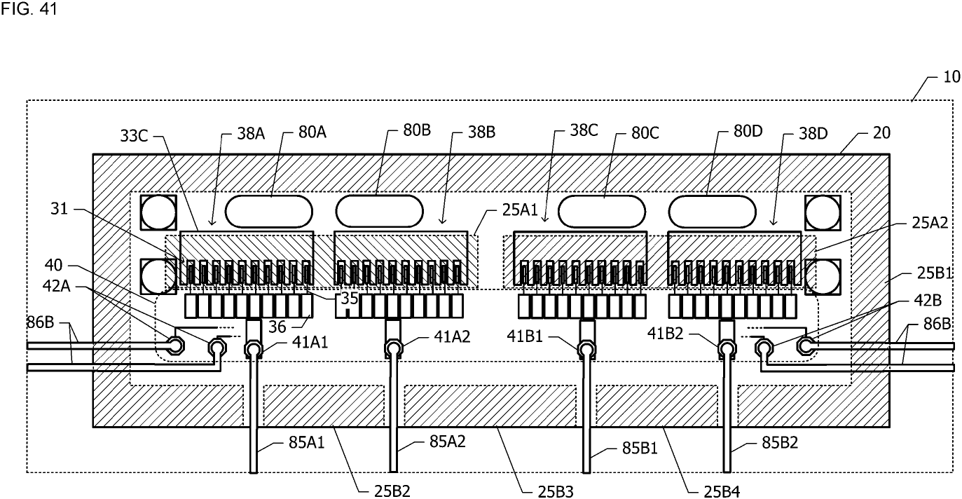

Next, a semiconductor device according to a thirty-first embodiment will be described with reference to FIGS. 39 and 40. Hereinafter, the description of components common to the semiconductor device (FIG. 37) according to the twenty-ninth embodiment will not be repeated.

FIG. 39 is a schematic plan view of the semiconductor device according to the thirty-first embodiment. FIG. 40 is an enlarged plan view of one of the power stage transistors. In the twenty-ninth embodiment (FIG. 37), as shown in FIG. 4 of the first embodiment, the emitter electrode 32E, the base electrode 32B, and the collector electrode 32C connected to the power stage transistor 31 each have a long shape in one direction in plan view, and are disposed such that the longitudinal directions of the respective electrodes are substantially parallel to one another.

In contrast, in the thirty-first embodiment, as shown in FIG. 40, the emitter electrode 32E surrounds the circular base electrode 32B in plan view, and the collector electrode 32C surrounds the emitter electrode 32E. In FIG. 40, hatching is applied to the base electrode 32B, the emitter electrode 32E, and the collector electrode 32C.

The input wire 35 extends from the base electrode 32B in one direction (leftward direction in FIG. 40). The emitter electrode 32E and the collector electrode 32C each have a gap such that the emitter electrode 32E and the collector electrode 32C do not contact with the input wire 35. The base mesa 31BM of the power stage transistor 31 is disposed so as to cover the base electrode 32B and the emitter electrode 32E and not to overlap the collector electrode 32C in plan view.

In FIG. 40, the emitter electrode 32E has a C-shape obtained by cutting part of an annular shape in plan view. Alternatively, the emitter electrode 32E may have a U-shape. In this case, the base mesa 31BM can be formed in a shape made up of a semicircular part and a rectangular part connected to the edge of a straight line of the semicircular part. As another configuration example, the shape of the base electrode 32B may be a polygonal shape, such as an octagonal shape. In this case, the inner peripheral-side edge and outer peripheral-side edge of the emitter electrode 32E and the inner peripheral-side edge of the collector electrode 32C can be formed in a shape that reflects the outer shape of the base electrode 32B.

The collector electrode 32C extends in a direction (rightward direction in FIG. 35) opposite to a direction in which the input wire 35 extends and is connected to the collector wire 33C at its distal end. The emitter electrode 32E is connected to the emitter wire 33E that overlaps the emitter electrode 32E in plan view.

The input wire 35 is connected to the lower electrode 36U of the input capacitor 36. The signal input wire 34I is disposed so as to overlap the lower electrode 36U in plan view. The signal input wire 34I functions as an upper electrode of the input capacitor 36.

As shown in FIG. 39, the bonding member 25 includes three conductor patterns 25A1, 25A2, 25B. The conductor pattern 25A1 is disposed so as to cover the plurality of power stage transistors 31 of one of the blocks, and the conductor pattern 25A2 is disposed so as to cover the plurality of power stage transistors 31 of the other one of the blocks. The conductor pattern 25B is disposed along the edge of the second member 20 in plan view.

The plurality of input capacitors 36, the input terminal 41, and the signal input wires 34I that connect the input capacitors 36 to the input terminal 41 are included in the input-side circuit element 40 for the plurality of power stage transistors 31. The input-side circuit element 40 is disposed outside the conductor patterns 25A1, 25A2 that cover the plurality of power stage transistors 31 in plan view.

Next, advantageous effects of the thirty-first embodiment will be described. In the thirty-first embodiment as well, as in the case of the twenty-ninth embodiment (FIG. 37), coupling between the input-side circuit element 40 and the output-side circuit of the plurality of power stage transistors 31 is reduced without impairing heat dissipation from the plurality of power stage transistors 31 to the first member 10.

### Thirty-Second Embodiment

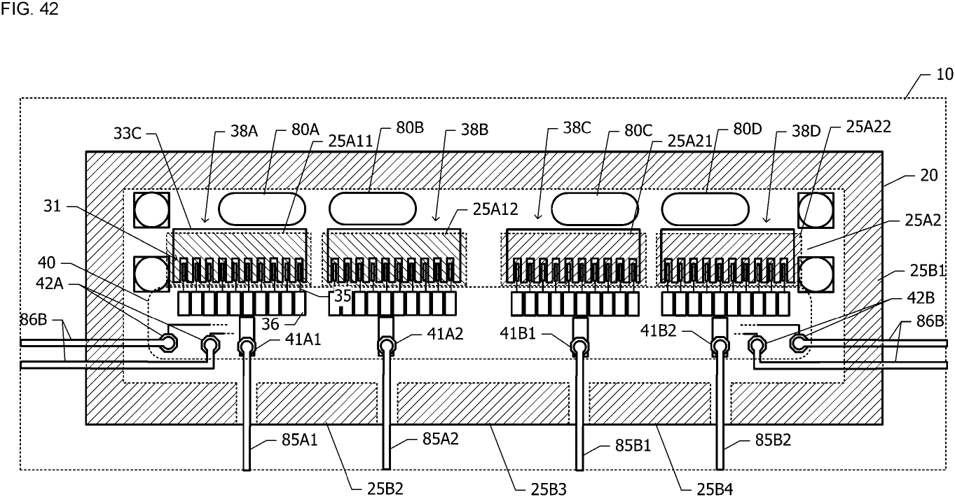

Next, a semiconductor device according to a thirty-second embodiment will be described with reference to FIG. 41. Hereinafter, the description of components common to the semiconductor device (FIG. 10) according to the fifth embodiment will not be repeated.

FIG. 41 is a schematic plan view of the semiconductor device according to the thirty-second embodiment. The second member 20 is bonded to the first member 10. In the fifth embodiment (FIG. 10), the plurality of power stage transistors 31 is divided into two blocks. In contrast, in the thirty-second embodiment, the plurality of power stage transistors 31 is divided into four blocks 38A, 38B, 38C, 38D. The plurality of power stage transistors 31 makes up a differential Doherty power amplifier.

For example, the plurality of power stage transistors 31 of the blocks 38A, 38C makes up a Doherty amplifier for a non-inverted signal, and the plurality of power stage transistors 31 of the blocks 38B, 38D makes up a Doherty amplifier for an inverted signal. The plurality of power stage transistors 31 of the blocks 38A, 38B operates as a carrier amplifier of the Doherty power amplifier, and the plurality of power stage transistors 31 of the blocks 38C, 38D operates as a peak amplifier of the Doherty power amplifier.

Input terminals 41A1, 41A2, 41B1, 41B2 are respectively connected to inter-member connection wires 85A1, 85A2, 85B1, 85B2. Two bias terminals 42A are respectively connected to two inter-member connection wires 86B, and two bias terminals 42B are respectively connected to two inter-member connection wires 86B.

A non-inverted signal is input to each of the input terminals 41A1, 41B1 via a corresponding one of the inter-member connection wires 85A1, 85B1. An inverted signal is input to each of the input terminals 41A2, 41B2 via a corresponding one of the inter-member connection wires 85A2, 85B2. A non-inverted signal may be input to each of the input terminals 41A1, 41B2 via a corresponding one of the inter-member connection wires 85A1, 85B2, and an inverted signal may be input to each of the input terminals 41A2, 41B1 via a corresponding one of the inter-member connection wires 85A2, 85B1. A non-inverted signal input to each of the two input terminals 41A1, 41B1 passes through the input capacitor 36 and the input wire 35 is input to the plurality of power stage transistors 31 of a corresponding one of the blocks 38A, 38C. An inverted signal input to each of the other two input terminals 41A2, 41B2 passes through the input capacitor 36 and the input wire 35 and is input to the plurality of power stage transistors 31 of a corresponding one of the blocks 38B, 38D.

Four output terminals 80A, 80B, 80C, 80D are disposed in correspondence with the four blocks 38A, 38B, 38C, 38D. Output signals amplified by the plurality of power stage transistors 31 of each of the four blocks 38A, 38B, 38C, 38D are output from corresponding output terminals 80A, 80B, 80C, 80D.

The plurality of input capacitors 36, the four input terminals 41A1, 41A2, 41B1, 41B2, wires connecting these input terminals to the input capacitors 36, the two sets of bias terminals 42A, 42B, and the like are included in the input-side circuit element 40 for the plurality of power stage transistors 31. The collector wires 33C respectively connected to the plurality of power stage transistors 31 of the four blocks 38A, 38B, 38C, 38D, the four output terminals 80A, 80B, 80C, 80D, and the like make up an output-side circuit for the power stage transistors 31.

The four bias terminals 42A, 42B in total are in correspondence with the four blocks 38A, 38B, 38C, 38D, respectively. A bias supplied to each of the bias terminals 42A, 42B is supplied to the plurality of power stage transistors 31 of a corresponding one of the blocks.

The bonding member 25 includes conductor patterns 25A1, 25A2, 25B1, 25B2, 25B3, 25B4. The conductor pattern 25A1 covers the plurality of power stage transistors 31 of the blocks 38A, 38B in plan view. The conductor pattern 25A2 covers the plurality of power stage transistors 31 of the blocks 38C, 38D in plan view. In other words, the conductor pattern 25A1 covers in plan view the plurality of power stage transistors 31 that operate as a carrier amplifier of a Doherty power amplifier, and the conductor pattern 25A2 covers in plan view the plurality of power stage transistors 31 that operate as a peak amplifier of the Doherty power amplifier in plan view.

The conductor patterns 25B1, 25B2, 25B3, 25B4 are disposed along the edge of the second member 20 in plan view and are separated from each other at portions where the inter-member connection wires 85A1, 85A2, 85B1, 85B2 are disposed. Therefore, the inter-member connection wires 85A1, 85A2, 85B1, 85B2 respectively connected to the input terminals 41A1, 41A2, 41B1, 41B2 do not overlap none of the conductor patterns of the bonding member 25 in plan view.

Next, advantageous effects of the semiconductor device according to the thirty-second embodiment will be described. In the thirty-second embodiment as well, as in the case of the fifth embodiment (FIG. 10), coupling between the input-side circuit element 40 and the plurality of power stage transistors 31 is reduced without impairing heat dissipation from the plurality of power stage transistors 31 to the first member 10.

The conductor pattern 25A1 that covers in plan view the plurality of power stage transistors 31 of the blocks 38A, 38B that operate as a carrier amplifier and the conductor pattern 25A2 that covers in plan view the plurality of power stage transistors 31 of the blocks 38C, 38D that operate as a peak amplifier are separated from each other. With this configuration, thermal influence between the carrier amplifier and the peak amplifier is reduced, so thermal equilibrium of the carrier amplifier is maintained, and high-efficiency operation can be implemented.

### Thirty-Third Embodiment

Next, a semiconductor device according to a thirty-third embodiment will be described with reference to FIG. 42. Hereinafter, the description of components common to the semiconductor device (FIG. 41) according to the thirty-second embodiment will not be repeated.

FIG. 42 is a schematic plan view of the semiconductor device according to the thirty-third embodiment. In the thirty-second embodiment (FIG. 41), one conductor pattern 25A1 covers the plurality of power stage transistors 31 of the two blocks 38A, 38B in plan view. In contrast, in the thirty-third embodiment, conductor patterns 25A11, 25A12, 25A21, 25A22 are disposed respectively for the blocks 38A, 38B, 38C, 38D. In plan view, the plurality of power stage transistors 31 of the four blocks 38A, 38B, 38C, 38D are respectively covered with the conductor patterns 25A11, 25A12, 25A21, 25A22.

The conductor pattern 25A11 that covers the plurality of power stage transistors 31 of the carrier amplifier for a non-inverted signal and the conductor pattern 25A12 that covers the plurality of power stage transistors 31 of the carrier amplifier for an inverted signal are separated from each other. Similarly, the conductor pattern 25A21 that covers the plurality of power stage transistors 31 of the peak amplifier for a non-inverted signal and the conductor pattern 25A22 that covers the plurality of power stage transistors 31 of the peak amplifier for an inverted signal are separated from each other.

Next, advantageous effects of the thirty-third embodiment will be described. In the thirty-third embodiment, thermal influence between the carrier amplifier for a non-inverted signal and the carrier amplifier for an inverted signal is reduced. In addition, thermal influence between the peak amplifier for a non-inverted signal and the peak amplifier for an inverted signal is reduced. Thermal equilibrium of each of the two carrier amplifiers for a non-inverted signal and an inverted signal is maintained, and high-efficiency operation is implemented.

### Thirty-Fourth Embodiment

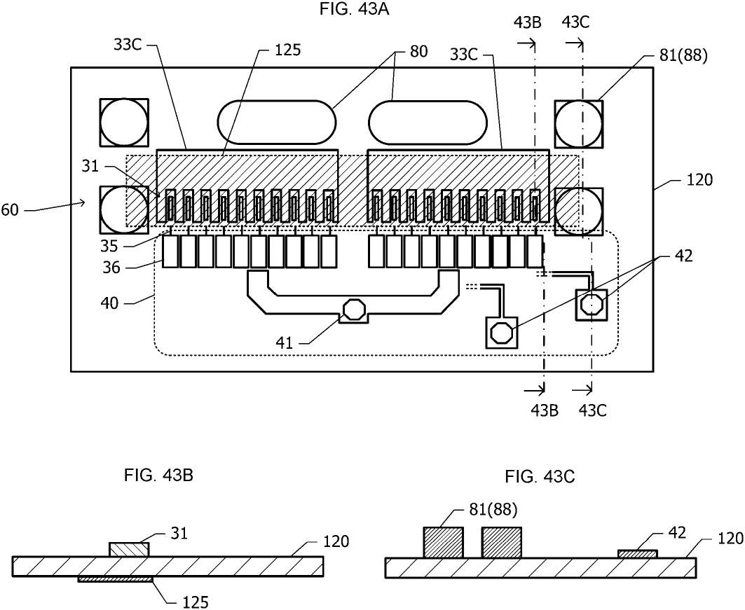

Next, a semiconductor device according to a thirty-fourth embodiment will be described with reference to FIGS. 43A, 43B, and 43C. Hereinafter, the description of components common to those of the semiconductor device according to the first embodiment described with reference to FIGS. 1 to 6 will not be repeated.

FIG. 43A is a schematic plan view of the semiconductor device according to the thirty-fourth embodiment. FIG. 43B is a schematic cross-sectional view taken along the alternate long and short dashed line 43B-43B in FIG. 43A. FIG. 43C is a schematic cross-sectional view taken along the alternate long and short dashed line 43C-43C in FIG. 43A. The semiconductor device (FIGS. 1 and 2A) according to the first embodiment includes the first member 10 and the second member 20 made of different materials. In contrast, the semiconductor device according to the thirty-fourth embodiment includes a semiconductor member 120 made up of a compound semiconductor, the power stage radio-frequency amplifier circuit 60 formed on the semiconductor member 120, and a conductor member 125.

The configuration of the power stage radio-frequency amplifier circuit 60 is the same as the configuration of the power stage radio-frequency amplifier circuit 60 of the semiconductor device (FIG. 1) according to the first embodiment. Specifically, the power stage radio-frequency amplifier circuit 60 includes the plurality of power stage transistors 31, the plurality of input wires 35, the plurality of input capacitors 36, the input terminal 41, the two bias terminals 42, the collector wires 33C, the output terminals 80, and the like. The input capacitors 36, the input terminal 41, wires connecting the input terminal 41 with the input capacitors 36, the bias terminals 42, and the like are included in the input-side circuit element 40 for the plurality of power stage transistors 31.

The input terminal 41 and the bias terminals 42 are pads for connecting wires and are used as terminals for connecting the inter-member connection wires 85, 86 (FIG. 1) as in the case of, for example, the input terminal 41 and bias terminals 42 of the semiconductor device (FIG. 1) according to the first embodiment.

The conductor member 125 is disposed on a surface of the semiconductor member 120 on an opposite side to a surface on which the power stage radio-frequency amplifier circuit 60 is formed. In FIG. 43A, hatching is applied to the conductor member 125. The conductor member 125 is used as a bonding layer for bonding to another member as in the case of, for example, the bonding member 25 according to the first embodiment (FIGS. 1 and 2A).

In plan view, the conductor member 125 is disposed so as to cover the plurality of power stage transistors 31. The input-side circuit element 40 is disposed outside the conductor member 125 in plan view. The same material as that of the bonding member 25 according to the first embodiment (FIG. 1) is used for the conductor member 125.

Other external connection terminals 81 are disposed on a surface of the semiconductor member 120 on which the power stage radio-frequency amplifier circuit 60 is formed. The output terminals 80 and the external connection terminals 81 are made up of conductive protrusions 88 (FIG. 2A).

Next, advantageous effects of the thirty-fourth embodiment will be described. In plan view, the conductor member 125 that covers the plurality of power stage transistors 31 makes up part of a heat dissipation path from the plurality of power stage transistors 31. When the conductor member 125 is bonded to another member as in the case of the first embodiment (FIGS. 1 and 2A,B), heat is dissipated from the power stage transistors 31 to the another member through the conductor member 125.

Since the conductor member 125 that covers the plurality of power stage transistors 31 in plan view does not overlap the input-side circuit element 40 in plan view, coupling between the input-side circuit element 40 and the plurality of power stage transistors 31 with the conductor member 125 interposed therebetween is reduced.

### Thirty-Fifth Embodiment

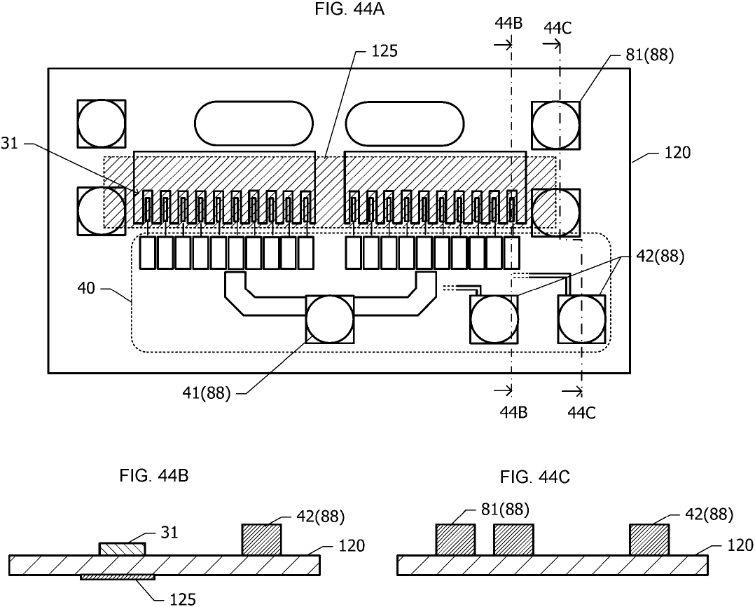

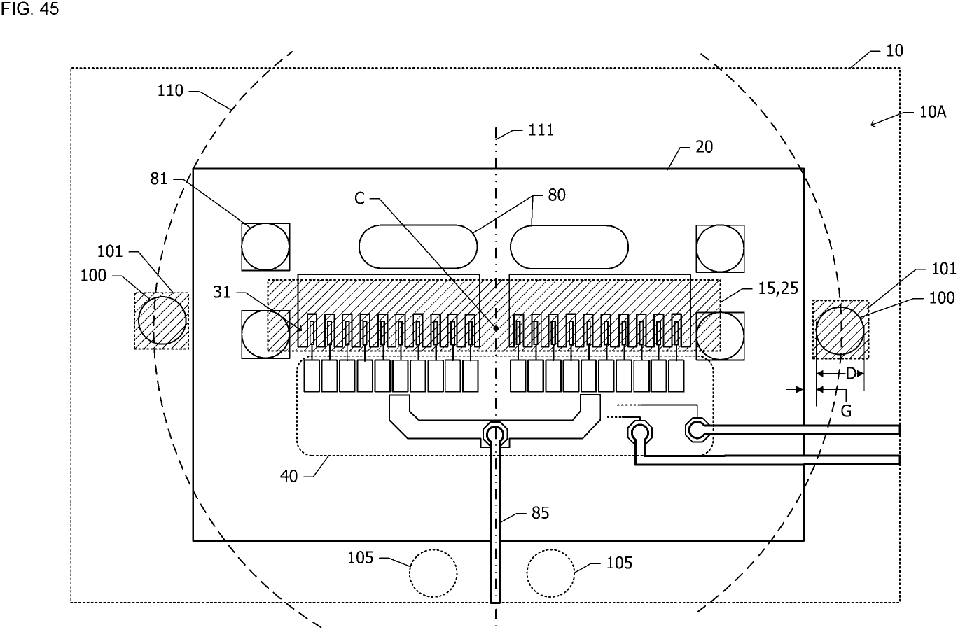

Next, a semiconductor device according to a thirty-fifth embodiment will be described with reference to FIGS. 44A, 44B, and 44C. Hereinafter, the description of components common to the semiconductor device according to the thirty-fourth embodiment (FIGS. 43A, 43B, and 43C) will not be repeated.

FIG. 44A is a schematic plan view of the semiconductor device according to the thirty-fifth embodiment. FIG. 44B is a schematic cross-sectional view taken along the alternate long and short dashed line 44B-44B in FIG. 44A. FIG. 44C is a schematic cross-sectional view taken along the alternate long and short dashed line 44C-44C in FIG. 44A. In the thirty-fourth embodiment, the input terminal 41 and the bias terminals 42 are terminals for connecting the inter-member connection wires 85, 86 (FIG. 1) and the like. In contrast, in the thirty-fifth embodiment, the input terminal 41 and the bias terminals 42 are made up of the conductive protrusions 88 (FIG. 2A), such as bumps.

When the semiconductor device according to the thirty-fifth embodiment is flip-chip bonded to a module substrate or the like, an input signal is input from the module substrate to the input terminal 41, and a bias is supplied to the bias terminals 42.

Next, advantageous effects of the thirty-fifth embodiment will be described. In the thirty-fifth embodiment as well, when the conductor member 125 is bonded to another member as in the case of the thirty-fourth embodiment (FIGS. 43A, 43B, and 43C), heat is dissipated from the power stage transistors 31 to the another member through the conductor member 125. In addition, coupling between the input-side circuit element 40 and the plurality of power stage transistors 31 with the conductor member 125 interposed therebetween is reduced.

### Thirty-Sixth Embodiment

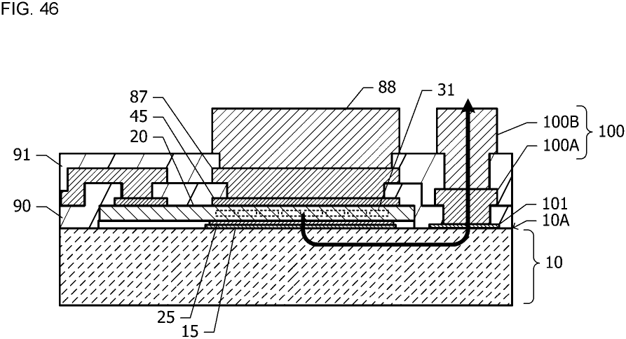

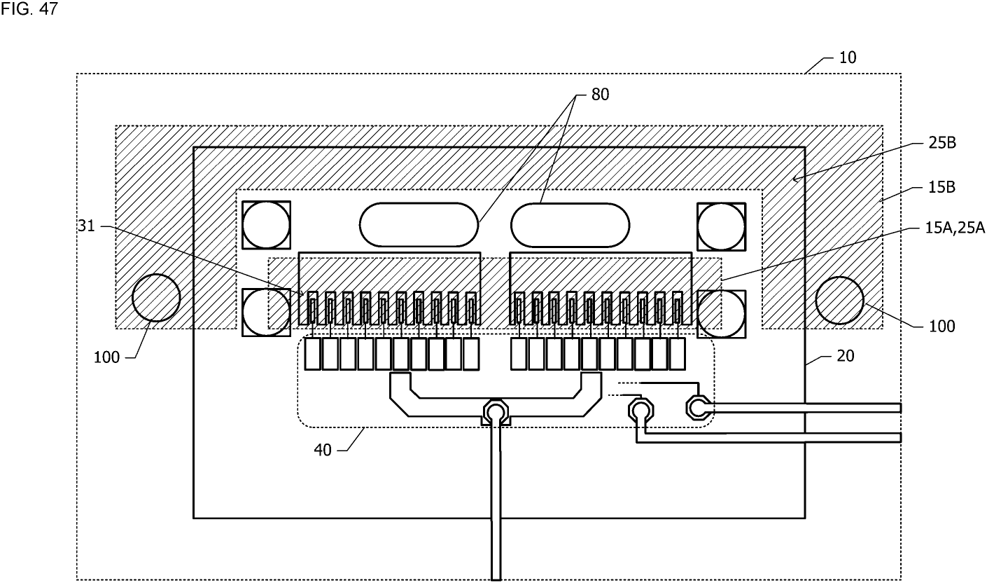

Next, a semiconductor device according to a thirty-sixth embodiment will be described with reference to FIGS. 45 and 46. Hereinafter, the description of components common to those of the semiconductor device according to the first embodiment described with reference to FIGS. 1 to 6 will not be repeated.

FIG. 45 is a schematic plan view of the semiconductor device according to the thirty-sixth embodiment. The plurality of conductive protrusions 88 that make up the output terminals 80 and the external connection terminals 81 are shown in FIGS. 1 and 2A that show the semiconductor device according to the first embodiment. Some of the conductive protrusions 88 are connected to the pads 87 provided on the second member 20, and the remaining some of the conductive protrusions 88 are connected to the pads 87 provided on the first member 10.

In the thirty-sixth embodiment, two first member conductive protrusions 100 are provided in addition to these conductive protrusions 88. The number of the first member conductive protrusions 100 may be one or may be three or more. The first member conductive protrusions 100 are disposed outside the second member 20 in plan view and protrude from the first surface 10A of the first member 10. For example, the two first member conductive protrusions 100 are disposed at locations on both sides of the plurality of power stage transistors 31 along an extension extended from the array of the plurality of power stage transistors 31. A conductive protrusion base pattern 101 is disposed between the first surface 10A and each of the first member conductive protrusions 100. In FIG. 45, the same hatching as those for the bonding members 15, 25 is applied to the conductive protrusion base patterns 101.

FIG. 46 is a cross-sectional view of part of the semiconductor device shown in FIG. 45. Each of the conductive protrusion base patterns 101 is disposed in a region where the second member 20 is not disposed on the first surface 10A of the first member 10. The conductive protrusion base patterns 101 are formed in the same process as the process of forming the first member 10-side bonding member 15. In other words, the conductive protrusion base patterns 101 are made from the same electrically conductive material as the first member 10-side bonding member 15.

The electrically insulating film 90 is disposed on the conductive protrusion base patterns 101. The electrically insulating film 90 has openings for exposing the conductive protrusion base patterns 101, and the first member conductive protrusion lower part 100A is disposed in each of the openings. The first member conductive protrusion lower parts 100A are formed in the same process as the process of forming the pads 87. The electrically insulating film 91 is disposed on the first member conductive protrusion lower parts 100A and the electrically insulating film 90. The electrically insulating film 91 has openings for exposing the first member conductive protrusion lower parts 100A, and the first member conductive protrusion upper part 100B is disposed in each of the openings. The first member conductive protrusion upper parts 100B are formed in the same process as the process of forming the terminal conductive protrusions 88. The first member conductive protrusion lower part 100A and the first member conductive protrusion upper part 100B make up each of the first member conductive protrusions 100. In other words, each of the first member conductive protrusions 100 is connected to the first member 10 with a corresponding one of the conductive protrusion base patterns 101 with electrical conductivity, interposed therebetween. The first member conductive protrusions 100 protrude upward beyond the top surface of the electrically insulating film 91 as in the case of the conductive protrusions 88.

Next, advantageous effects of the thirty-sixth embodiment will be described. In the thirty-sixth embodiment as well, as in the case of the first embodiment, oscillation due to a positive feedback from the output-side circuit to the input-side circuit element 40 is suppressed without decreasing heat transfer characteristics from the power stage transistors 31 provided on the second member 20 to the first member 10.

In addition, in the thirty-sixth embodiment, in the configuration that the first member conductive protrusions 100 are mounted on a module substrate or the like, heat transferred from the power stage transistors 31 to the first member 10 is transferred to the module substrate via the first member conductive protrusions 100 as indicated by the wide arrow in FIG. 46. Therefore, heat dissipation from the second member 20, particularly, the power stage transistors 31, is improved.

Next, a preferred positional relationship between the first member conductive protrusions 100 and the second member 20 will be described with reference to FIG. 45.

A radio-frequency signal to be amplified by the power stage transistors 31 is input to the second member 20 from a side at which the input-side circuit element 40 is disposed when viewed from the power stage transistors 31 (a side facing downward in FIG. 45). The radio-frequency signal amplified by the power stage transistors 31 is output to a side opposite to the side at which the input-side circuit element 40 is disposed when viewed from the power stage transistors 31 (a side facing upward in FIG. 45).

Therefore, a radio-frequency signal transmission line and a radio-frequency circuit element are disposed on each of the side from which a radio-frequency signal is input and the side from which a radio-frequency signal is output when viewed from the second member 20. The first member conductive protrusions 100 are preferably disposed outside the region in which the radio-frequency signal transmission line and the radio-frequency circuit element are disposed. For example, the first member conductive protrusions 100 are preferably respectively disposed on both sides in a direction extended from the array made up of the plurality of power stage transistors 31 when viewed from the power stage transistors 31.

In addition, in order to decrease the thermal resistance of a heat conduction path from the power stage transistors 31 via the first member conductive protrusions 100 to the module substrate, the first member conductive protrusions 100 are preferably disposed near the second member 20.

For example, where the dimension of the shape of the first member conductive protrusion 100 in plan view is D and the shortest distance from the first member conductive protrusion 100 to the second member 20 in plan view is G, the shortest distance G is preferably less than or equal to twice the dimension D. When the shape of the first member conductive protrusion 100 in plan view is circular, the dimension D is equal to the diameter of the first member conductive protrusion 100. When the shape of the first member conductive protrusion 100 in plan view is a narrow and long shape, the width of the long shape may be adopted as the dimension D. Generally, in plan view, the minimum space between two parallel lines tangent to the first member conductive protrusion 100 on both sides may be defined as the dimension D.

Since the power stage transistors 31 disposed in the second member 20 are main heat generating sources, the first member conductive protrusions 100 are preferably disposed near the power stage transistors 31 as much as possible. For example, the shape of the second member 20 in plan view may have a convex polygon (preferably, a convex quadrilateral, more preferably, a rectangle or a square), a geometric center C of a region in which the power stage transistors 31 are disposed may be defined as a center, and at least part of each of the first member conductive protrusions 100 may be configured to overlap a region inside a circle 110 passing through the corner of the second member 20 nearest to the geometric center C. The geometric center of a minimum bounding rectangle including the plurality of power stage transistors 31, for example, the base mesas 31BM (FIG. 3), in plan view may be adopted as the geometric center C of the region in which the power stage transistors 31 are disposed.

Variations in temperature among the plurality of power stage transistors 31 are preferably suppressed. For example, the symmetry of the heat dissipation path is preferably ensured. For example, in plan view, the first member conductive protrusions 100 are preferably disposed at line-symmetric locations with respect to a straight line 111 passing through the geometric center C of the region in which the power stage transistors 31 are disposed and orthogonal to the direction in which the power stage transistors 31 are arranged. By suppressing variations in temperature among the plurality of power stage transistors, the characteristics deterioration of the transistors and breakage of the transistors due to thermal runaway are suppressed.

Next, a modification of the thirty-sixth embodiment will be described. In the thirty-sixth embodiment, the first member conductive protrusions 100 are disposed along an extension extended from the array of the plurality of power stage transistors 31. Alternatively, the first member conductive protrusions 100 may be disposed at other portions. For example, the first member conductive protrusions 100 may be respectively disposed on both sides of the inter-member connection wire 85 through which an input signal is transferred to the second member 20. For example, the first member conductive protrusions 100 may be respectively disposed at portions 105 indicated by the dashed lines in FIG. 45.

### Thirty-Seventh Embodiment

Next, a semiconductor device according to a thirty-seventh embodiment will be described with reference to FIG. 47. Hereinafter, the description of components common to the semiconductor device (FIG. 8) according to the third embodiment will not be repeated.

In the third embodiment (FIG. 8), two conductor patterns that make up the first member 10-side bonding member 15 (FIG. 2A) respectively substantially overlap the conductor patterns 25A, 25B of the second member 20-side bonding member 25. In contrast, in the thirty-seventh embodiment, the first member 10-side conductor pattern 15B that overlaps the conductor pattern 25B having a U-shape that is open from the power stage transistors 31 toward the input-side circuit element 40 extends to outside from the inside of the second member 20 in plan view. The other first member 10-side conductor pattern 15A substantially overlaps the second member 20-side conductor pattern 25A.

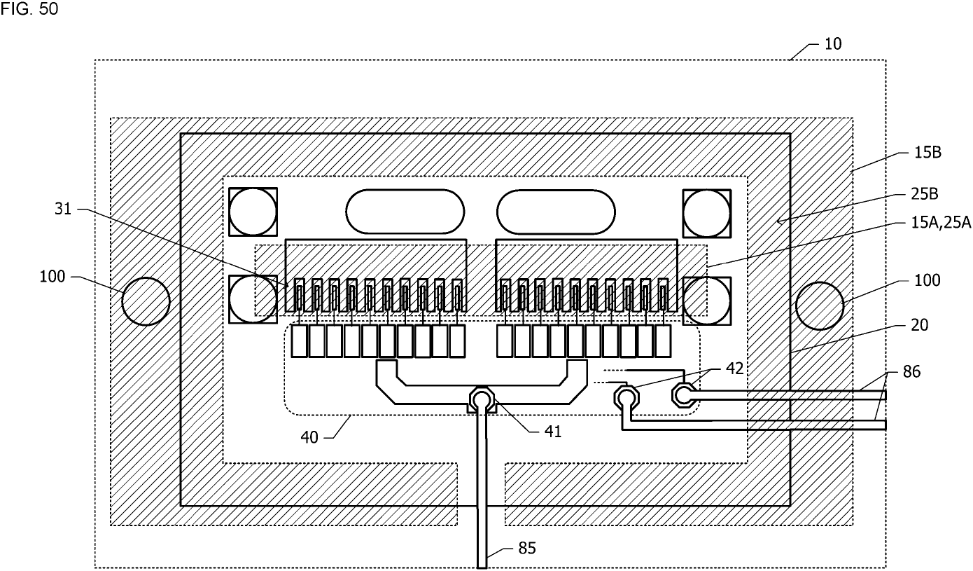

In FIG. 47, hatching is applied to the first member 10-side conductor patterns 15A, 15B. The same applies to FIG. 49 and the following figures. In the specification, of the plurality of conductor patterns that make up the first member 10-side bonding member 15, the conductor pattern that extends to outside from the inside of the second member 20 in plan view may be referred to as “extended conductor pattern”. In the thirty-seventh embodiment, the conductor pattern 15B is an extended conductor pattern.

In the thirty-seventh embodiment as well, as in the case of the thirty-sixth embodiment (FIG. 45), the two first member conductive protrusions 100 are disposed. In the thirty-sixth embodiment (FIG. 45), the conductive protrusion base patterns 101 to which the first member conductive protrusions 100 are connected are not connected to the second member 20 in plan view. In contrast, in the thirty-seventh embodiment, the first member conductive protrusions 100 are disposed in the extended part of the extended conductor pattern 15B. In other words, the extended conductor pattern 15B is used as the conductive protrusion base patterns 101 (FIG. 45).

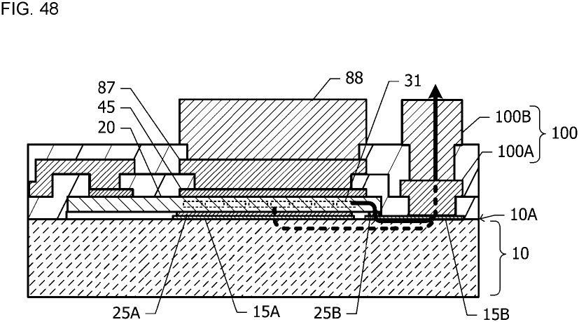

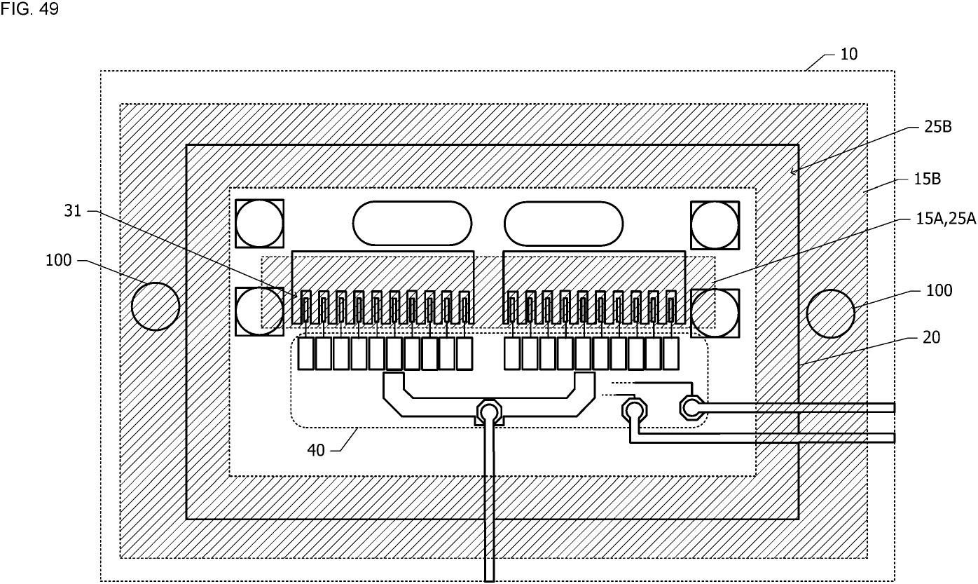

FIG. 48 is a cross-sectional view of part of the semiconductor device shown in FIG. 47. The first member 10-side conductor pattern 15B extends from a region just below the second member 20 to outside the second member 20. The extended conductor pattern 15B is connected to the second member 20 with the second member 20-side conductor pattern 25B interposed therebetween. The first member conductive protrusions 100 are connected to the extended part of the extended conductor pattern 15B.

Next, advantageous effects of the thirty-seventh embodiment will be described. In the thirty-seventh embodiment as well, as in the case of the third embodiment, oscillation due to a positive feedback from the output-side circuit to the input-side circuit element 40 is suppressed without decreasing heat transfer characteristics from the power stage transistors 31 to the first member 10.

In the thirty-seventh embodiment, in addition to the heat conduction path (dashed arrow) of the semiconductor device according to the thirty-sixth embodiment (FIG. 46), a heat conduction path (continuous arrow) from the second member 20 through the second member 20-side conductor pattern 25B and the first member 10-side conductor pattern 15B to the first member conductive protrusions 100 is formed. Therefore, as compared to the thirty-sixth embodiment, the thermal resistance of the heat conduction path from the power stage transistors 31 to the first member conductive protrusions 100 decreases. Thus, heat dissipation from the power stage transistors 31 is improved.

### Thirty-Eighth Embodiment

Next, a semiconductor device according to a thirty-eighth embodiment will be described with reference to FIG. 49. Hereinafter, the description of components common to the semiconductor device (FIG. 9) according to the fourth embodiment will not be repeated.

FIG. 49 is a schematic plan view of the semiconductor device according to the thirty-eighth embodiment. In the thirty-eighth embodiment, the first member 10-side conductor pattern 15B that overlaps the second member 20-side conductor pattern 25B according to the fourth embodiment (FIG. 9) extends from the second member 20 in four directions in plan view. The two first member conductive protrusions 100 are connected to the extended part of the conductor pattern 15B.

Next, advantageous effects of the thirty-eighth embodiment will be described. In the thirty-eighth embodiment, the bonding strength of the second member 20 with the first member 10 is increased as in the case of the fourth embodiment (FIG. 9). In addition, as in the case of the thirty-seventh embodiment (FIGS. 47 and 48), heat dissipation from the power stage transistors 31 is improved.

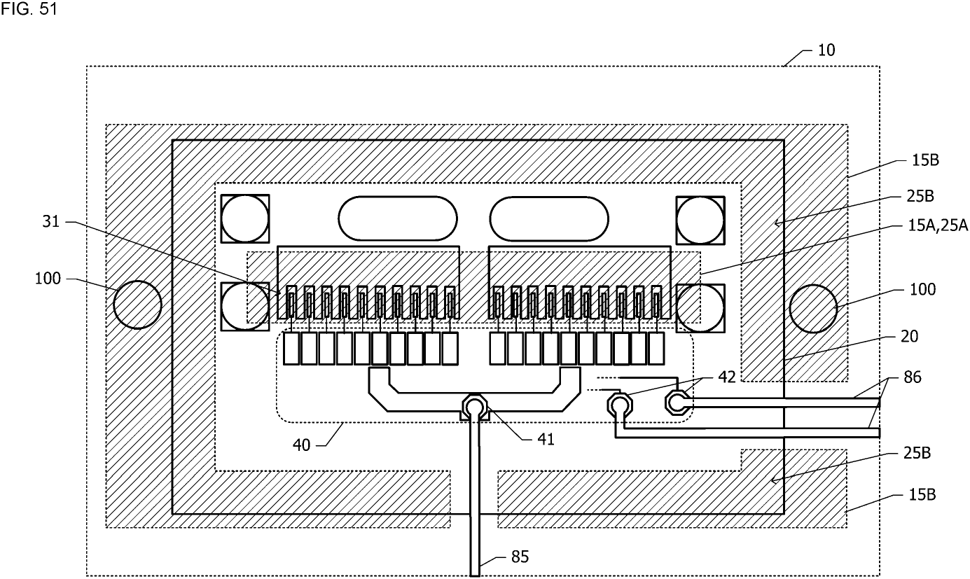

Next, semiconductor devices according to modifications of the thirty-eighth embodiment will be described with reference to FIGS. 50 to 54. FIGS. 50 to 54 are schematic plan views of the semiconductor devices according to the modifications of the thirty-eighth embodiment. In the thirty-eighth embodiment (FIG. 49), the second member 20-side conductor pattern 25B and the first member 10-side conductor pattern 15B are continuously disposed along the edge of the second member 20 in plan view.

In the modification shown in FIG. 50, as in the case of the semiconductor device (FIG. 10) according to the fifth embodiment, a gap of each of the conductor pattern 25B and the conductor pattern 15B is provided at a portion at which the conductor pattern 25B and the conductor pattern 15B intersect with the inter-member connection wire 85 connected to the input terminal 41. In other words, the conductor patterns 15B, 25B do not overlap the inter-member connection wire 85. The two first member conductive protrusions 100 are connected to the extended part of the conductor pattern 15B.

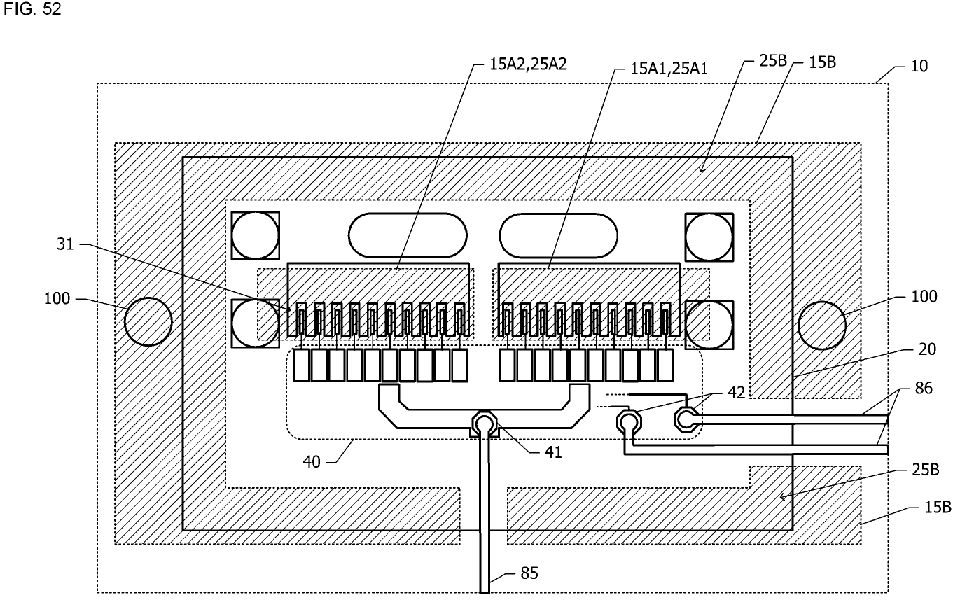

In the modification shown in FIG. 51, as in the case of the semiconductor device (FIG. 11) according to the sixth embodiment, a gap of each of the conductor pattern 25B and the conductor pattern 15B is provided at a portion at which the conductor pattern 25B and the conductor pattern 15B intersect with the inter-member connection wire 85 connected to the input terminal 41 and a portion at which the conductor pattern 25B and the conductor pattern 15B intersect with the two inter-member connection wires 86 respectively connected to the two bias terminals 42. In other words, the conductor patterns 15B, 25B do not overlap the inter-member connection wires 85, 86.

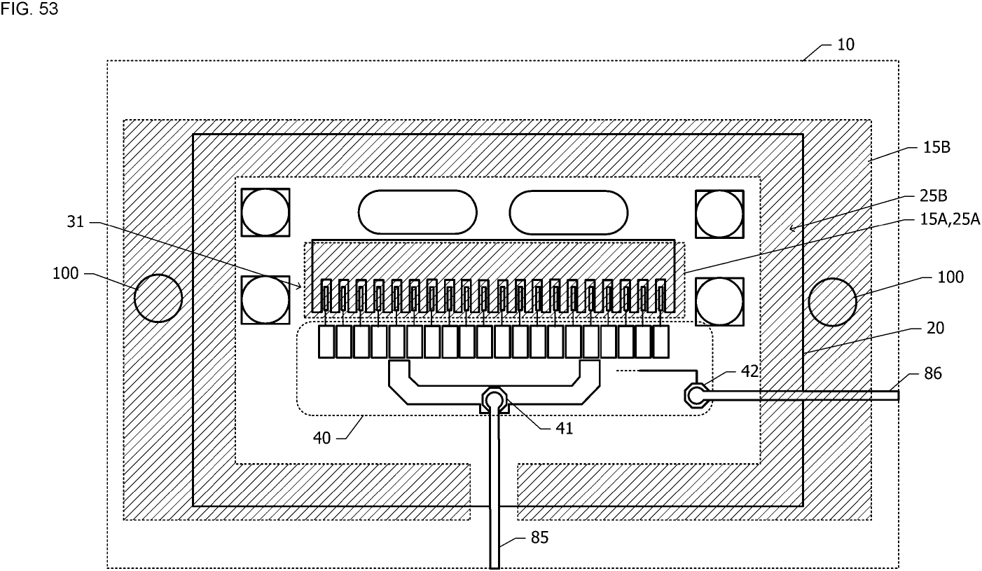

In the modification shown in FIG. 52, as in the case of the semiconductor device (FIG. 12) according to the seventh embodiment, the conductor pattern 25A is divided into two conductor patterns 25A1, 25A2, and the conductor pattern 15A is also divided into two conductor patterns 15A1, 15A2. In addition, as in the case of the modification shown in FIG. 51, a gap is provided at two portions of each of the conductor patterns 15B, 25B. The conductor patterns 15A1, 25A1 are disposed for one of the two blocks of the plurality of power stage transistors 31, and the conductor patterns 15A2, 25A2 are disposed for the other one of the two blocks. The two first member conductive protrusions 100 are connected to the extended part of the conductor pattern 15B.

In the modification shown in FIG. 53, as in the case of the semiconductor device (FIG. 13) according to the eighth embodiment, the plurality of power stage transistors 31 is not divided into blocks, all the power stage transistors 31 are arranged at equal intervals, the number of the bias terminals 42 is one, and the number of the inter-member connection wires 86 connected to the bias terminal 42 is also one. In addition, as in the case of the modification shown in FIG. 50, a gap is provided at one portion of each of the conductor patterns 15B, 25B. All the power stage transistors 31 are covered with the conductor patterns 15A, 25A in plan view. The two first member conductive protrusions 100 are connected to the extended part of the conductor pattern 15B.

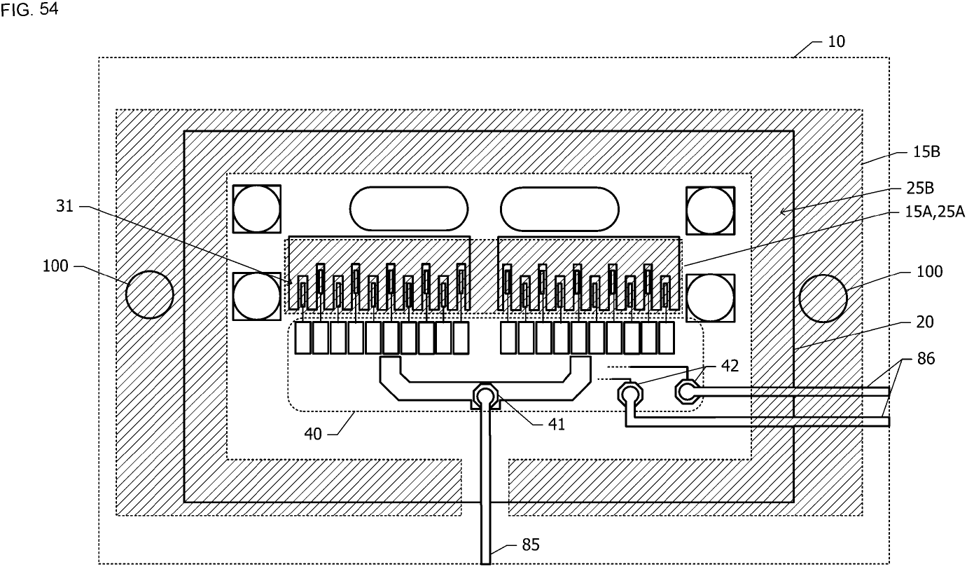

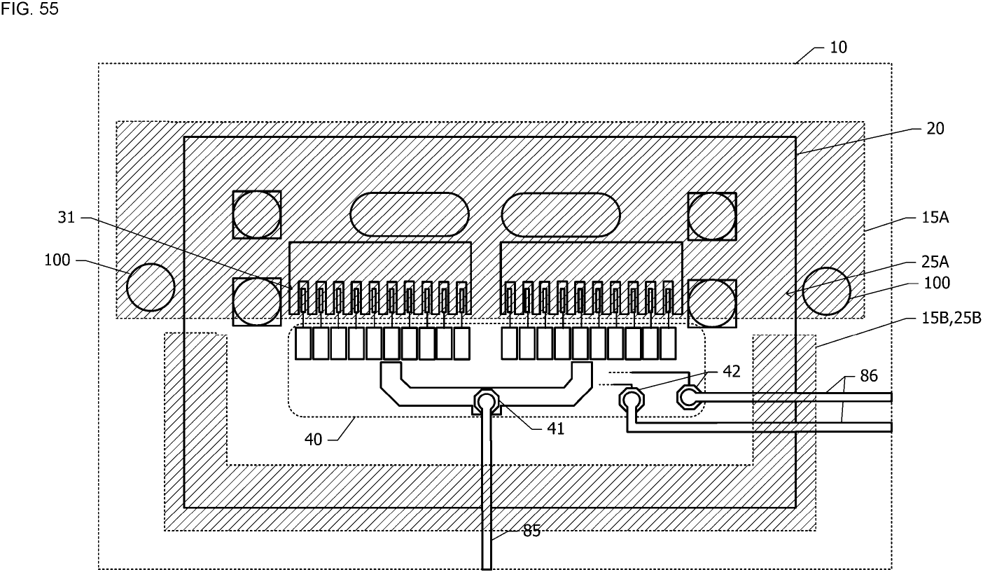

In the modification shown in FIG. 54, as in the case of the semiconductor device (FIG. 14) according to the ninth embodiment, the plurality of power stage transistors 31 is disposed in a staggered manner, and, as in the case of the modification shown in FIG. 50, a gap is provided at one portion of each of the conductor patterns 15B, 25B. The two first member conductive protrusions 100 are connected to the extended part of the conductor pattern 15B.

In the modifications shown in FIGS. 50 to 54 as well, as in the case of the semiconductor device according to the thirty-eighth embodiment, heat dissipation from the power stage transistors 31 is improved.

### Thirty-Ninth Embodiment

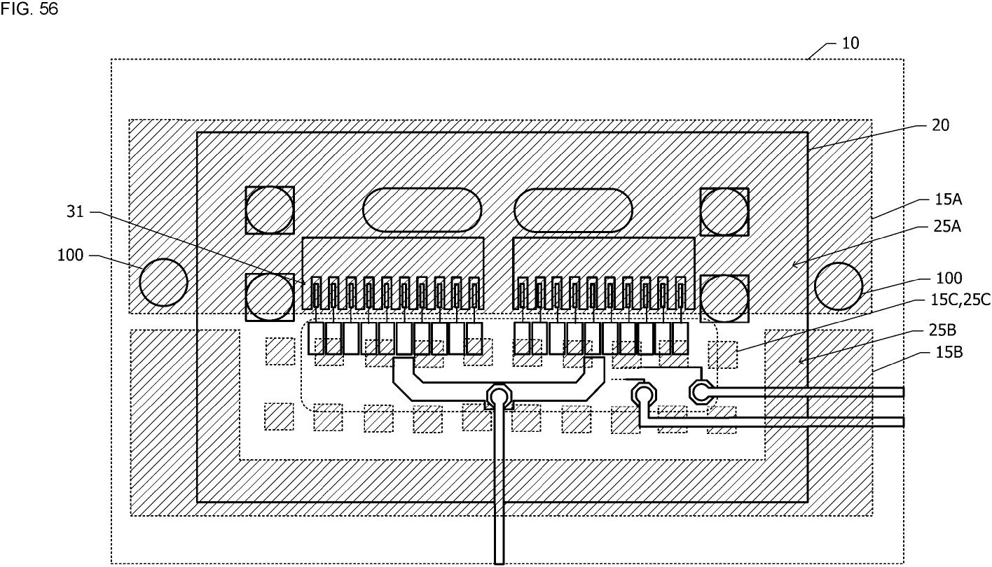

Next, a semiconductor device according to a thirty-ninth embodiment will be described with reference to FIG. 55. Hereinafter, the description of components common to the semiconductor device (FIG. 15) according to the tenth embodiment will not be repeated.

FIG. 55 is a schematic plan view of the semiconductor device according to the thirty-ninth embodiment. In the tenth embodiment (FIG. 15), the first member 10-side conductor pattern 15A and the second member 20-side conductor pattern 25A expand from a region, in which the plurality of power stage transistors 31 is disposed, in a direction other than a direction toward the region in which the input-side circuit element 40 is disposed, and reach the edge of the second member 20. In contrast, in the thirty-ninth embodiment, the first member 10-side conductor pattern 15A extends to outside from the inside of the second member 20 in plan view. The two first member conductive protrusions 100 are disposed in the extended part and are connected to the conductor pattern 15A. In other words, the extended conductor pattern 15A covers the plurality of power stage transistors 31 in plan view.

Next, advantageous effects of the thirty-ninth embodiment will be described. In the thirty-ninth embodiment as well, as in the case of the tenth embodiment (FIG. 15), oscillation due to a positive feedback from the output-side circuit to the input-side circuit element 40 is suppressed. In addition, in the thirty-ninth embodiment, the area of the conductor patterns 15A, 25A that cover the plurality of power stage transistors 31 in plan view is greater than that in the thirty-seventh embodiment (FIG. 47). Therefore, heat dissipation through a heat path from the plurality of power stage transistors 31 via the conductor patterns 15A, 25A to the first member 10 improves.

In addition, in the thirty-ninth embodiment, since the conductor pattern 15A is connected to the first member conductive protrusions 100, a heat path from the power stage transistors 31 through the second member 20-side conductor pattern 25A, the first member 10-side conductor pattern 15A, and the first member conductive protrusions 100 to the module substrate is formed. Therefore, heat dissipation from the power stage transistors 31 is further improved.

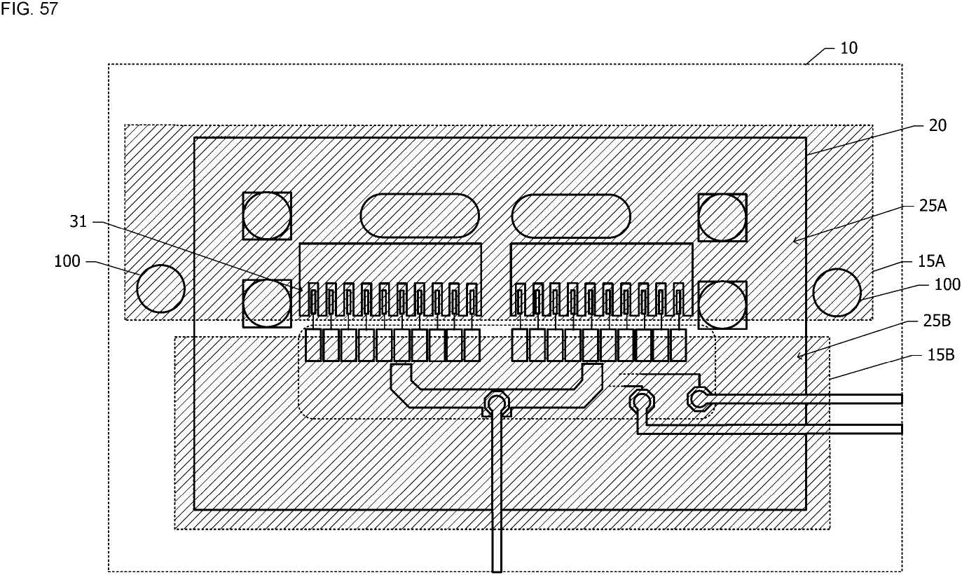

Next, a semiconductor device according to a modification of the thirty-ninth embodiment will be described with reference to FIG. 56. FIG. 56 is a schematic plan view of the semiconductor device according to the modification of the thirty-ninth embodiment.

In the modification shown in FIG. 56, as in the case of the semiconductor device (FIG. 16) according to the eleventh embodiment, a plurality of conductor patterns 25C is dotted in a region surrounded by the conductor patterns 15A, 25A and the conductor patterns 15B, 25B. The first member 10-side conductor patterns 15C are disposed so as to substantially overlap the plurality of second member 20-side conductor patterns 25C. The two first member conductive protrusions 100 are disposed in the extended part of the conductor pattern 15A and connected to the conductor pattern 15A.

In the modification of the thirty-ninth embodiment shown in FIG. 56 as well, oscillation due to a positive feedback from the output-side circuit to the input-side circuit element 40 is suppressed. In addition, the bonding strength of the second member 20 with the first member 10 is increased.

### Fortieth Embodiment

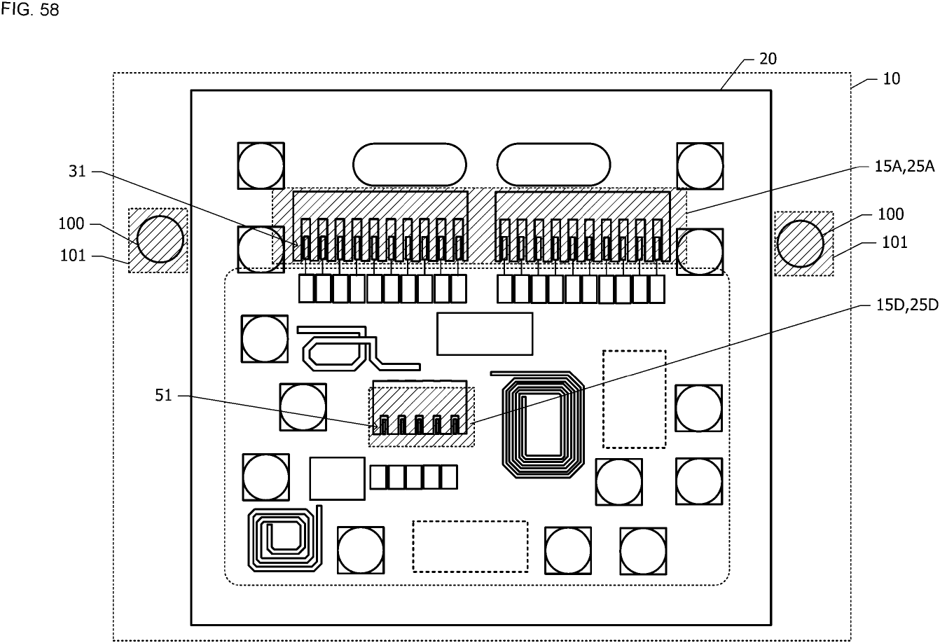

Next, a semiconductor device according to a fortieth embodiment will be described with reference to FIG. 57. Hereinafter, the description of components common to the semiconductor device (FIG. 17) according to the twelfth embodiment will not be repeated.

FIG. 57 is a schematic plan view of the semiconductor device according to the fortieth embodiment. In the twelfth embodiment (FIG. 17), the conductor patterns 15A, 25A and the conductor patterns 15B, 25B are covered with the second member 20 in plan view. In contrast, in the fortieth embodiment, the conductor patterns 15A, 15B extend to outside the second member 20 in plan view. The two first member conductive protrusions 100 are disposed in the extended part of the conductor pattern 15A and connected to the conductor pattern 15A.

Next, advantageous effects of the fortieth embodiment will be described. In the fortieth embodiment as well, as in the case of the twelfth embodiment, oscillation due to a positive feedback from the output-side circuit to the input-side circuit element 40 is suppressed. In addition, in the fortieth embodiment, as in the case of the thirty-ninth embodiment, heat dissipation from the power stage transistors 31 is improved.

### Forty-First Embodiment

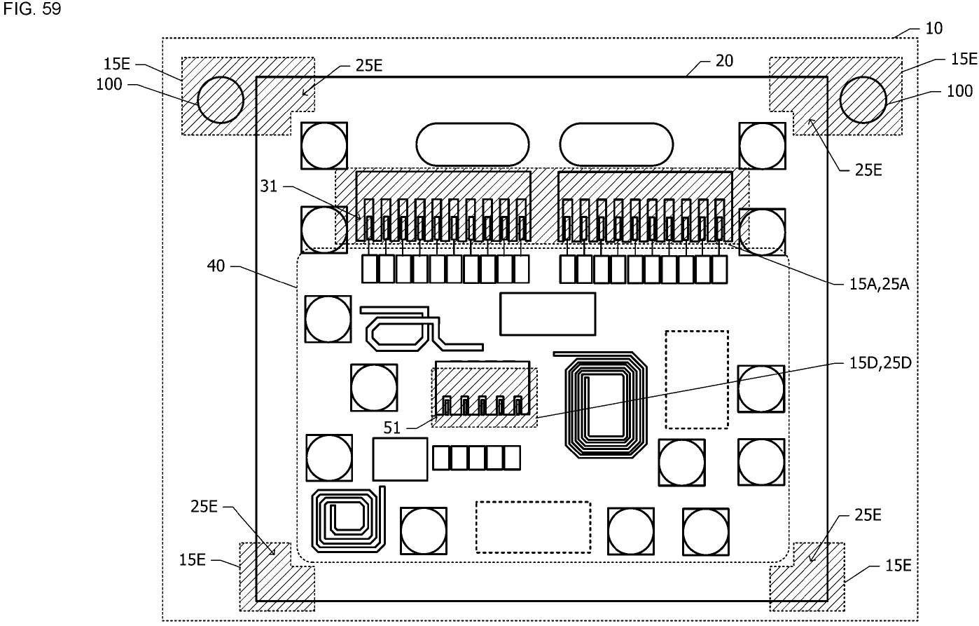

Next, a semiconductor device according to a forty-first embodiment will be described with reference to FIG. 58. Hereinafter, the description of components common to the semiconductor device according to the thirteenth embodiment (FIGS. 18 and 19) will not be repeated.

FIG. 58 is a schematic plan view of the semiconductor device according to the forty-first embodiment. In FIG. 18 that shows the semiconductor device according to the thirteenth embodiment, only the second member 20 is shown, the first member 10 is not shown, and first member conductive protrusions are not explicitly shown. In the forty-first embodiment, in plan view, the conductive protrusion base patterns 101 are disposed outside the second member 20 as in the case of the thirty-sixth embodiment (FIGS. 45 and 46) and the first member conductive protrusions 100 are disposed so as to be covered with the conductive protrusion base patterns 101.

As in the case of the thirteenth embodiment (FIG. 18), in plan view, the first member 10-side conductor pattern 15A and the second member 20-side conductor pattern 25A are disposed so as to cover the power stage transistors 31. In addition, a first member 10-side conductor pattern 15D and a second member 20-side conductor pattern 25D are disposed so as to cover the driver stage transistors 51.

Next, advantageous effects of the forty-first embodiment will be described. In the forty-first embodiment as well, as in the case of the thirteenth embodiment (FIGS. 18 and 19), oscillation due to a positive feedback from the output-side circuit to the input-side circuit element 40 is suppressed without decreasing heat transfer characteristics from the power stage transistors 31 provided in the second member 20 to the first member 10. In addition, in the forty-first embodiment, as in the case of the thirty-sixth embodiment (FIGS. 45 and 46), heat dissipation from the second member 20 is improved.

Next, a preferred location where the first member conductive protrusions 100 are disposed will be described. A preferred positional relationship between the first member conductive protrusions 100 and the second member 20 is similar to the case of the thirty-sixth embodiment (FIG. 45). The amount of heat generated from the power stage transistors 31 provided in the second member 20 is greater than the amount of heat generated from the driver stage transistors 51. Therefore, each of the first member conductive protrusions 100 is preferably disposed at a location at which the shortest distance from the first member conductive protrusion 100 to the power stage transistors 31 is shorter than the shortest distance from the first member conductive protrusion 100 to the driver stage transistors 51.

### Forty-Second Embodiment

Next, a semiconductor device according to a forty-second embodiment will be described with reference to FIG. 59. Hereinafter, the description of components common to the semiconductor device according to the sixteenth embodiment (FIG. 22) will not be repeated.

FIG. 59 is a schematic plan view of the semiconductor device according to the forty-second embodiment. In the sixteenth embodiment (FIG. 22), four first member 10-side conductor patterns 25E are respectively disposed at four corners of the second member 20, and first member 10-side conductor patterns (not explicitly shown in FIG. 22) are disposed at locations that overlap the conductor patterns 25E. The first member 10-side conductor patterns (not explicitly shown in FIG. 22) are disposed so as to respectively overlap the second member 20-side conductor patterns 25A, 25D.

In the forty-second embodiment, each of the conductor patterns 15E disposed at the four corners of the second member 20 extends to outside from the inside of the second member 20 in plan view. The first member conductive protrusions 100 are disposed in the extended parts of the two conductor patterns 15E and connected to the conductor patterns 15E. For example, of the four conductor patterns 15E, the first member conductive protrusions 100 are respectively disposed in the extended part of the conductor pattern 15E of which the shortest distance from the power stage transistors 31 is the shortest and in the extended part of the conductor pattern 15E of which the shortest distance is the second shortest. The first member conductive protrusion 100 may be connected to the extended part of one conductor pattern 15E, or the first member conductive protrusions 100 may be respectively connected to the extended parts of three or more conductor patterns 15E.

The first member 10-side conductor patterns 15A, 15D are disposed so as to overlap the second member 20-side conductor patterns 25A, 25D.

Next, advantageous effects of the forty-second embodiment will be described. In the forty-second embodiment as well, as in the case of the sixteenth embodiment (FIG. 22), oscillation due to a positive feedback from the output-side circuit to the input-side circuit element 40 is suppressed without decreasing heat transfer characteristics from the power stage transistors 31 provided in the second member 20 to the first member 10. In addition, in the forty-second embodiment, as in the case of the thirty-sixth embodiment (FIGS. 45 and 46), heat dissipation from the second member 20 is improved.

### Forty-Third Embodiment

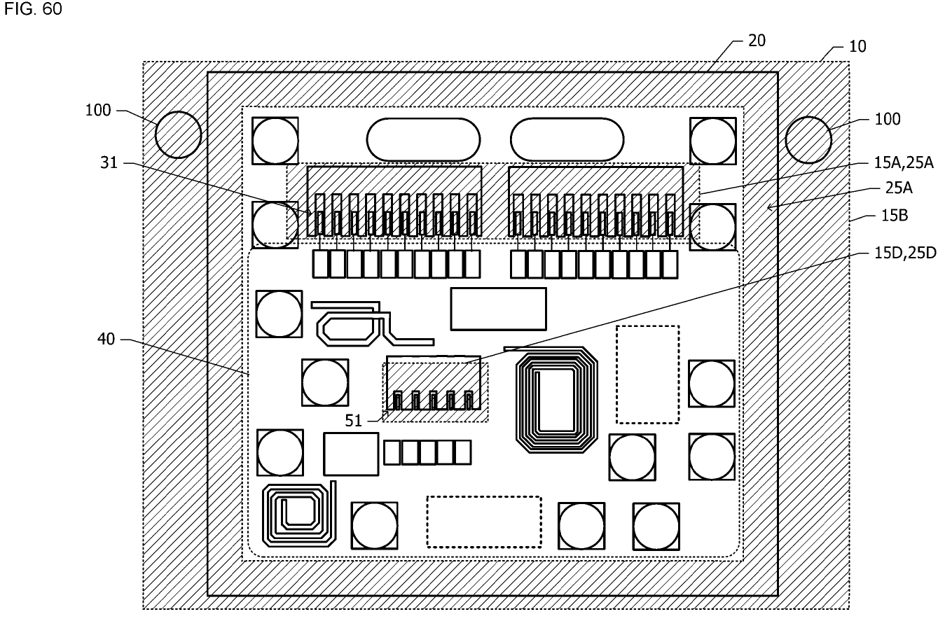

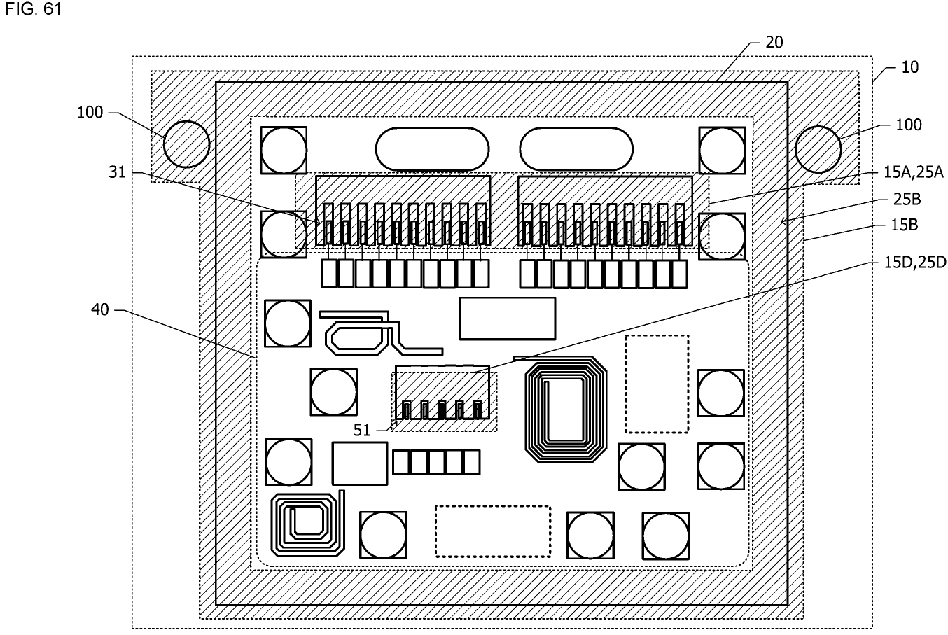

Next, a semiconductor device according to a forty-third embodiment will be described with reference to FIG. 60. Hereinafter, the description of components common to the semiconductor device according to the seventeenth embodiment (FIG. 23) will not be repeated.

FIG. 60 is a schematic plan view of the semiconductor device according to the forty-third embodiment. In the seventeenth embodiment (FIG. 23), the second member 20-side conductor pattern 25B, and the first member 10-side conductor pattern that substantially overlaps the conductor pattern 25B are covered with the second member 20 in plan view. In contrast, in the forty-third embodiment, the first member 10-side conductor pattern 15B disposed along the edge of the second member 20 extends to outside from the inside of the second member 20 in plan view. The two first member conductive protrusions 100 are disposed in the extended part of the conductor pattern 15A and connected to the conductor pattern 15A.

Next, advantageous effects of the forty-third embodiment will be described. In the forty-third embodiment as well, as in the case of the seventeenth embodiment (FIG. 23), oscillation due to a positive feedback from the output-side circuit to the input-side circuit element 40 is suppressed without decreasing heat transfer characteristics from the power stage transistors 31 provided in the second member 20 to the first member 10. In addition, in the forty-third embodiment, as in the case of the thirty-sixth embodiment (FIGS. 45 and 46), heat dissipation from the second member 20 is improved.

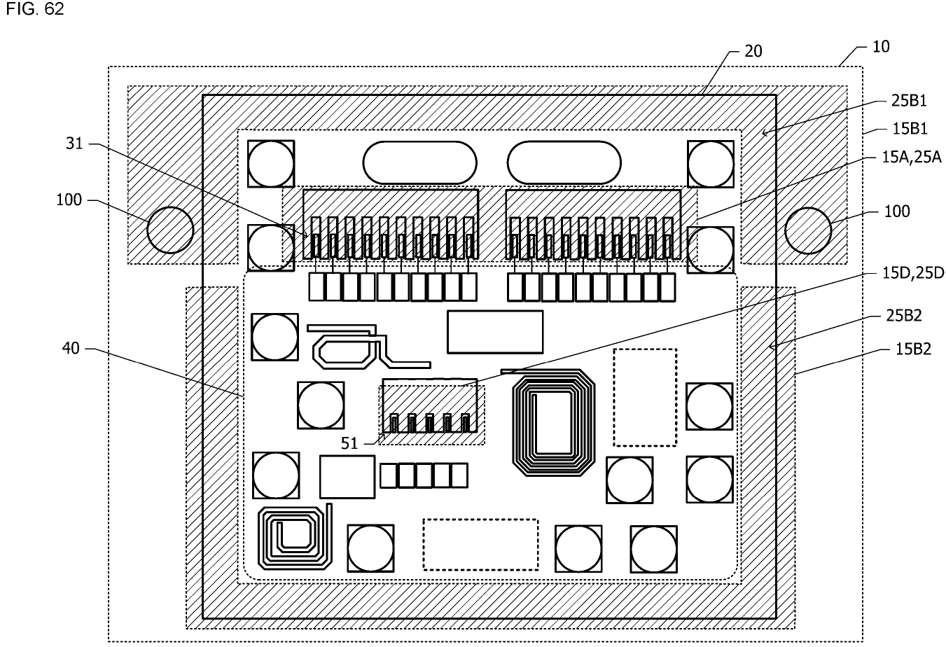

Next, semiconductor devices according to modifications of the forty-third embodiment will be described with reference to FIGS. 61 to 67. FIGS. 61 to 67 are schematic plan views of the semiconductor devices according to the modifications of the forty-third embodiment.

In the forty-third embodiment (FIG. 60), the extended amount of the conductor pattern 15B from the edge is uniform in a range from one end to the other end of each of the four edges of the second member 20. In contrast, in the modification shown in FIG. 61, the extended conductor pattern 15B provided along two edges (the right-side edge and the left-side edge in FIG. 61) of the second member 20 includes a part where the extended amount is relatively large and a part where the extended amount is relatively small. Therefore, the outer peripheral line of the extended conductor pattern 15B changes in a stepwise manner at the boundary between the part where the extended amount is relatively large and the part where the extended amount is relatively small. The first member conductive protrusions 100 are connected to the part where the extended amount is relatively large in the extended part of the extended conductor pattern 15B.

In the modification shown in FIG. 62, as in the case of the eighteenth embodiment (FIG. 24), a conductor pattern provided along the edge of the second member 20 is divided into signal output-side conductor patterns 15B1, 25B1 and signal input-side conductor patterns 15B2, 25B2. The conductor patterns 15B1, 15B2 extend to outside from the inside of the second member 20 in plan view. The two first member conductive protrusions 100 are connected to the extended part of the signal output-side conductor pattern 15B1.

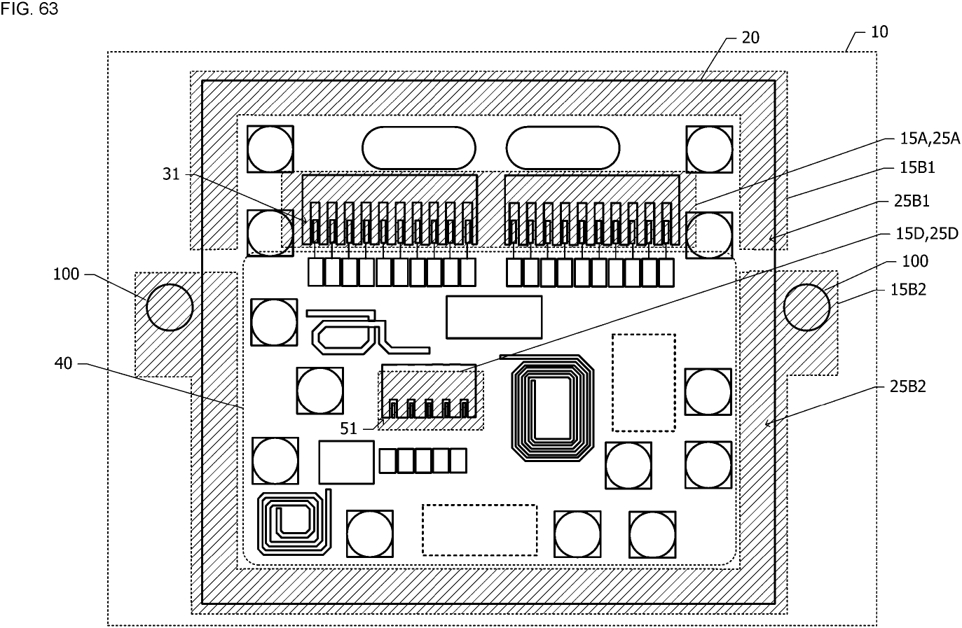

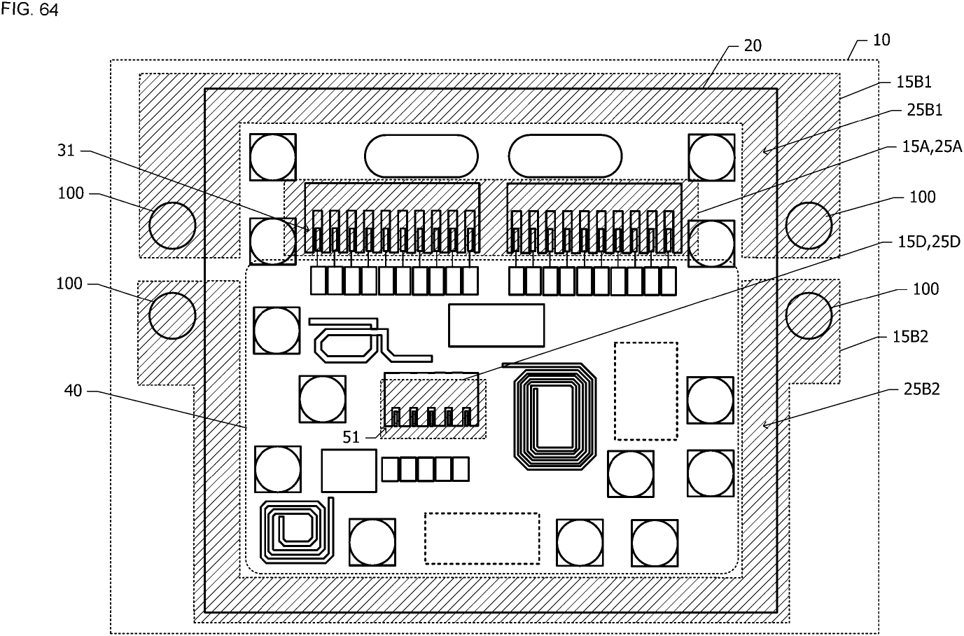

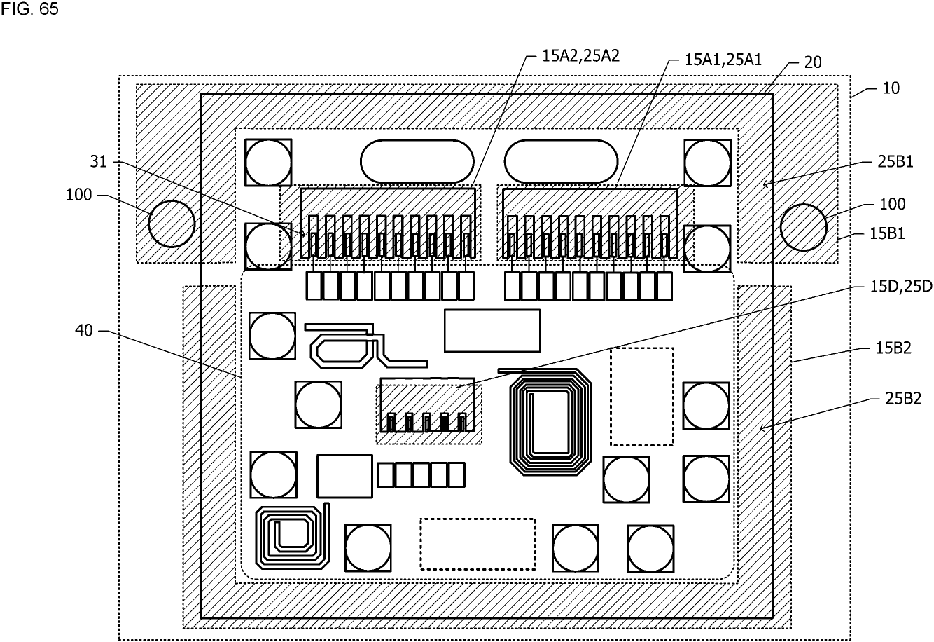

In the modification shown in FIG. 63, the two first member conductive protrusions 100 are connected to the extended part of the signal input-side conductor pattern 15B2. In the modification shown in FIG. 64, the two first member conductive protrusions 100 are connected to the extended part of the signal output-side conductor pattern 15B1, and the other two first member conductive protrusions 100 are connected to the extended part of the signal input-side conductor pattern 15B2.

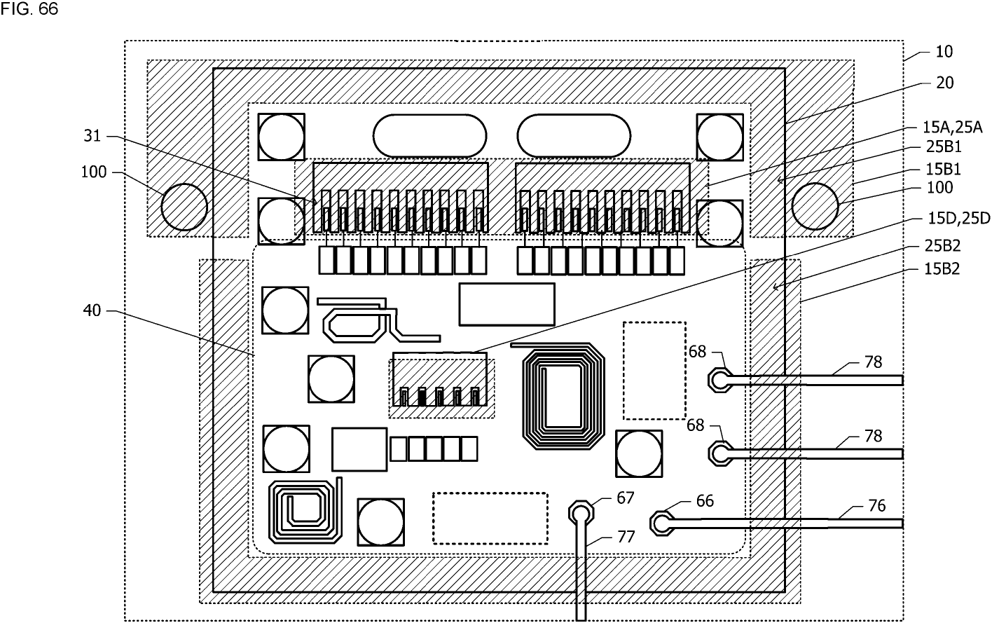

In the modification shown in FIG. 65, as in the case of the modification shown in FIG. 62, the first member conductive protrusions 100 are connected to the extended part of the signal output-side conductor pattern 15B1. In addition, in the modification shown in FIG. 65, as in the case of the nineteenth embodiment (FIG. 25), a conductor pattern that covers the plurality of power stage transistors 31 is divided into two conductor patterns 25A1, 25A2 in correspondence with the two blocks of the power stage transistors 31. Similarly, the first member 10-side conductor pattern is also divided into two conductor patterns 15A1, 15A2.

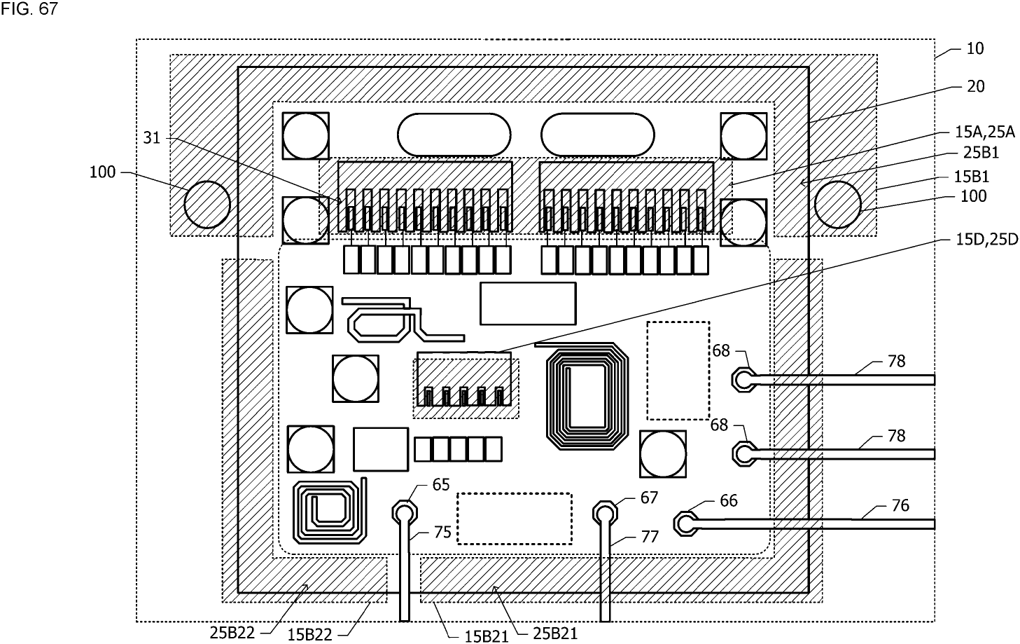

In the modification shown in FIG. 66, as in the case of the modification shown in FIG. 62, the two first member conductive protrusions 100 are connected to the extended part of the extended conductor pattern 15B1. In addition, in the modification shown in FIG. 66, as in the case of the twentieth embodiment (FIGS. 26 and 27), the battery voltage terminal 66, the driver stage bias control terminal 67, and the two power stage bias control terminals 68 are disposed on or in the second member 20.

The inter-member connection wire 76 is connected to the battery voltage terminal 66, the inter-member connection wire 77 is connected to the driver stage bias control terminal 67, and the two inter-member connection wires 78 are respectively connected to the two power stage bias control terminals 68. The inter-member connection wires 76, 77, 78 intersect with the conductor patterns 15B2, 25B2 in plan view and extend to outside the second member 20, and overlap the conductor patterns 15B2, 25B2 at the intersecting portions. These inter-member connection wires 76, 77, 78 are connected to a control circuit formed on or in the first member 10.

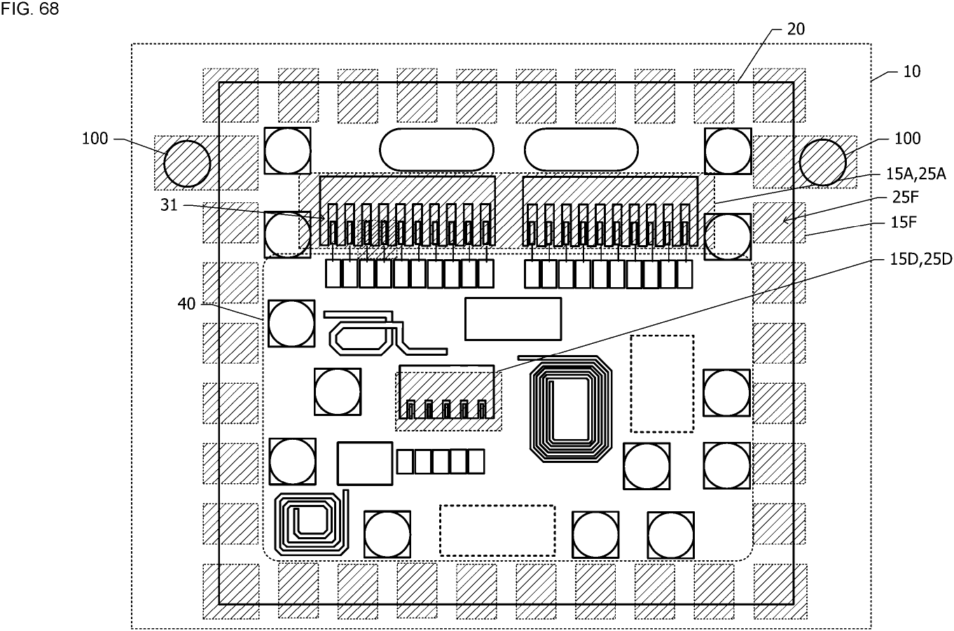

In the modification shown in FIG. 67, the input terminal 65 is further disposed on the second member 20 in the modification shown in FIG. 66, and the inter-member connection wire 75 is connected to the input terminal 65. The inter-member connection wire 75 extends to outside the second member 20 in plan view. A radio-frequency signal is input from a circuit provided in the first member 10 via the inter-member connection wire 75 to the input terminal 65.

The second member 20-side conductor pattern disposed along the edge of the second member 20 is divided into two conductor patterns 25B21, 25B22 at a portion at which the second member 20-side conductor pattern intersects with the inter-member connection wire 75. The first member 10-side conductor pattern is also divided into two conductor patterns 15B21, 15B22 at a portion at which the first member 10-side conductor pattern intersects with the inter-member connection wire 75. In other words, the inter-member connection wire 75 does not overlap any of the conductor patterns in plan view. The two first member conductive protrusions 100 are connected to the extended part of the extended conductor pattern 15B1.

In the modifications shown in FIGS. 61 to 67 as well, as in the case of the forty-third embodiment (FIG. 60), oscillation due to a positive feedback from the output-side circuit to the input-side circuit element 40 is suppressed and heat dissipation from the second member 20 is improved, without decreasing heat transfer characteristics from the power stage transistors 31 to the first member 10.

### Forty-Fourth Embodiment

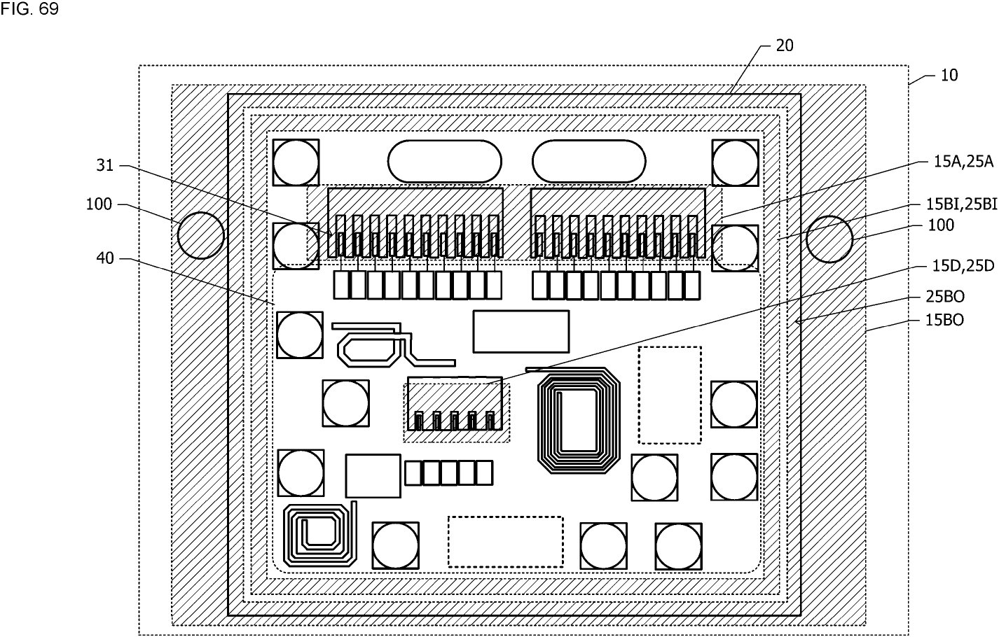

Next, a semiconductor device according to a forty-fourth embodiment will be described with reference to FIG. 68. Hereinafter, the description of components common to the semiconductor device according to the twenty-second embodiment (FIG. 30) will not be repeated.

FIG. 68 is a schematic plan view of the semiconductor device according to the forty-fourth embodiment. The semiconductor device according to the forty-fourth embodiment includes a plurality of conductor patterns 25F disposed at intervals along the edge of the second member 20 as in the case of the twenty-second embodiment (FIG. 30). First member 10-side conductor patterns 15F are disposed so as to respectively overlap the plurality of conductor patterns 25F. Each of the plurality of conductor patterns 15F extends to outside from the inside of the second member 20 in plan view. The two first member conductive protrusions 100 are respectively connected to the extended parts of the two extended conductor patterns 15F. The number of the first member conductive protrusions 100 may be one or may be three or more.

Next, advantageous effects of the forty-fourth embodiment will be described. In the forty-fourth embodiment as well, as in the case of the twenty-second embodiment (FIG. 30), oscillation due to a positive feedback from the output-side circuit to the input-side circuit element 40 is suppressed without decreasing heat transfer characteristics from the power stage transistors 31 provided in the second member 20 to the first member 10. In addition, in the forty-fourth embodiment, as in the case of the thirty-sixth embodiment (FIGS. 45 and 46), heat dissipation from the second member 20 is improved.

### Forty-Fifth Embodiment

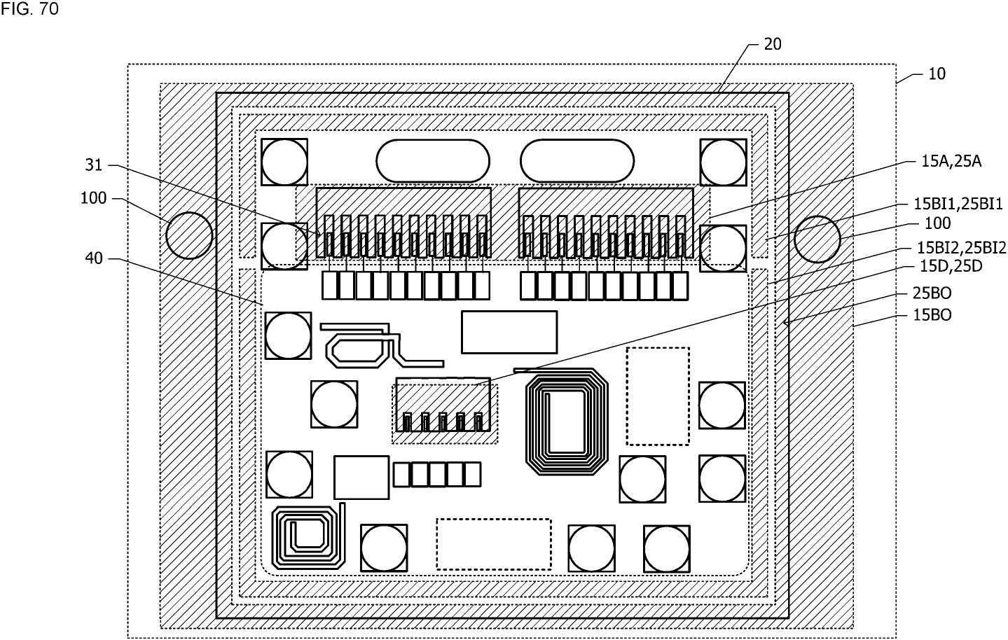

Next, a semiconductor device according to a forty-fifth embodiment will be described with reference to FIG. 69. Hereinafter, the description of components common to the semiconductor device according to the twenty-third embodiment (FIG. 31) will not be repeated.

FIG. 69 is a schematic plan view of the semiconductor device according to the forty-fifth embodiment. In the semiconductor device according to the forty-fifth embodiment, as in the case of the semiconductor device (FIG. 31) according to the twenty-third embodiment, the double lines of conductor patterns 25BO, 25BI disposed along the edge of the second member 20 surround the region inside the second member 20 in plan view. First member 10-side conductor patterns 15BO, 15BI are disposed so as to respectively overlap the conductor patterns 25BO, 25BI. The outer peripheral-side conductor pattern 15BO extends to outside from the inside of the second member 20 in plan view.

The two first member conductive protrusions 100 are connected to the extended part of the extended conductor pattern 15BO. The number of the first member conductive protrusions 100 may be one or may be three or more.

Next, advantageous effects of the forty-fifth embodiment will be described. In the forty-fifth embodiment as well, as in the case of the twenty-third embodiment (FIG. 31), oscillation due to a positive feedback from the output-side circuit to the input-side circuit element 40 is suppressed without decreasing heat transfer characteristics from the power stage transistors 31 provided in the second member 20 to the first member 10. In addition, in the forty-fifth embodiment, as in the case of the thirty-sixth embodiment (FIGS. 45 and 46), heat dissipation from the second member 20 is improved.

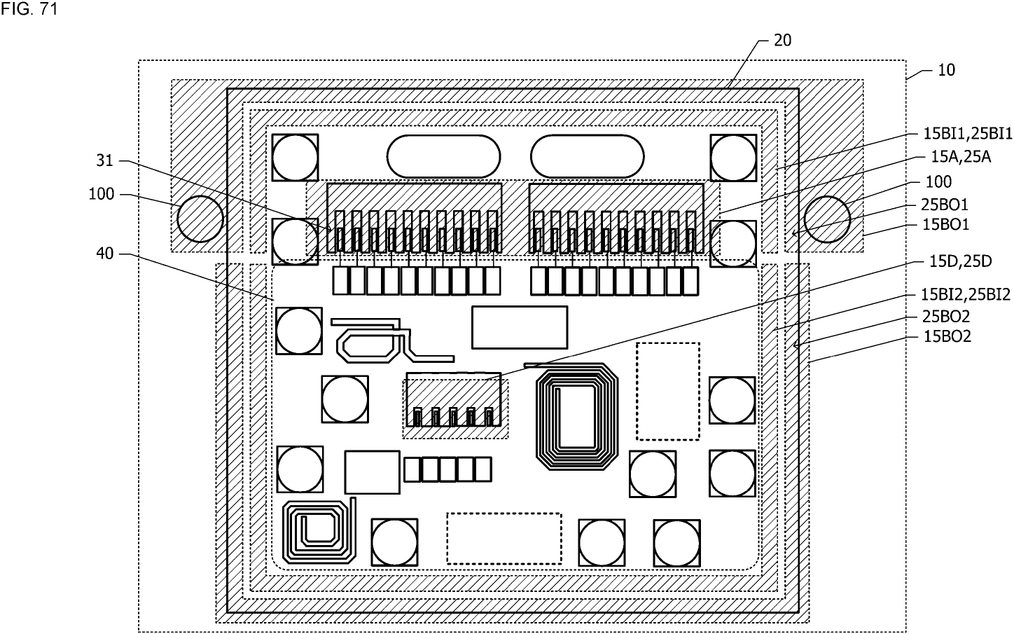

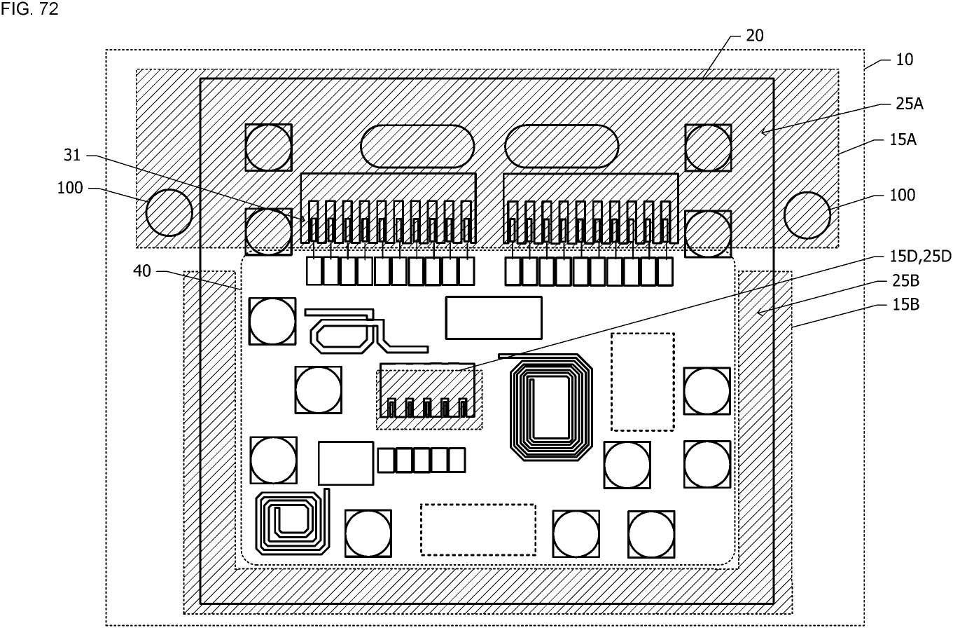

Next, semiconductor devices according to modifications of the forty-fifth embodiment will be described with reference to FIGS. 70 and 71. FIGS. 70 and 71 are schematic plan views of the semiconductor devices according to the modifications of the forty-fifth embodiment.

In the modification shown in FIG. 70, the inner peripheral-side conductor pattern disposed along the edge of the second member 20 is divided into a signal output-side conductor pattern 25BI1 and a signal input-side conductor pattern 25BI2 as in the case of the twenty-fourth embodiment (FIG. 32). The first member 10-side conductor pattern 15BI is also similarly divided into a signal output-side conductor pattern 15BI1 and a signal input-side conductor pattern 15BI2. The two first member conductive protrusions 100 are connected to the extended part of the extended conductor pattern 15BO.

In the modification shown in FIG. 71, not only the inner peripheral-side conductor pattern but also the outer peripheral-side conductor pattern is divided into a signal output-side conductor pattern 25BO1 and a signal input-side conductor pattern 25BO2 as in the case of the twenty-fifth embodiment (FIG. 33). The first member 10-side conductor pattern is also similarly divided into a signal output-side conductor pattern 15BO1 and a signal input-side conductor pattern 15BO2. The two first member conductive protrusions 100 are connected to the extended part of the extended conductor pattern 15BO1. The extended amount at a portion to which the first member conductive protrusion 100 is connected is greater than the extended amount of the signal input-side conductor pattern 15BO2.

In the modifications shown in FIGS. 70 and 71 as well, as in the case of the forty-fifth embodiment, oscillation due to a positive feedback from the output-side circuit to the input-side circuit element 40 is suppressed without decreasing heat transfer characteristics from the power stage transistors 31 provided in the second member 20 to the first member 10. In addition, heat dissipation from the second member 20 is improved.

### Forty-Sixth Embodiment

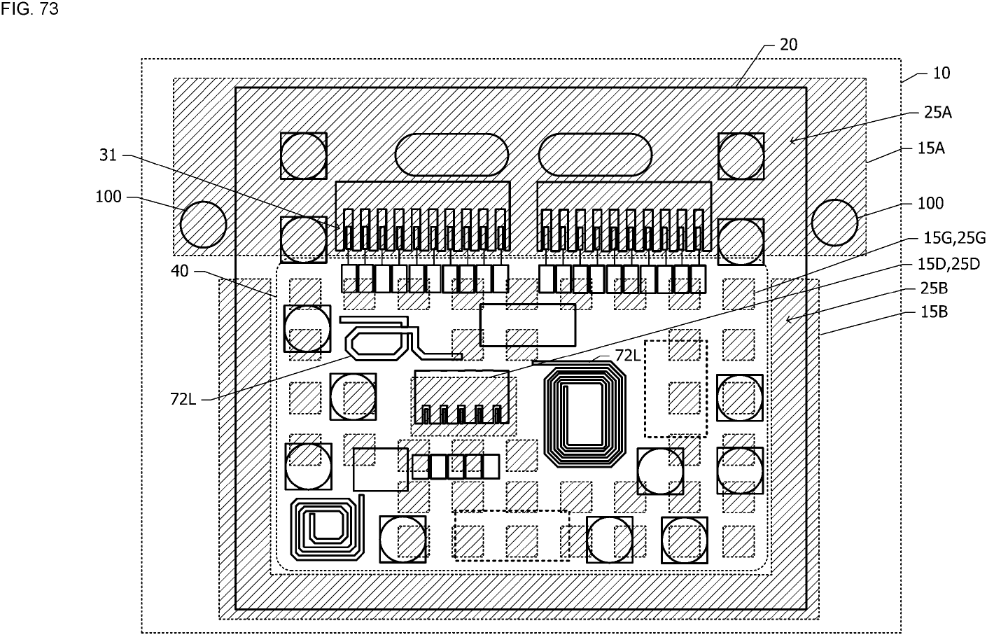

Next, a semiconductor device according to a forty-sixth embodiment will be described with reference to FIG. 72. Hereinafter, the description of components common to the semiconductor device (FIG. 34) according to the twenty-sixth embodiment will not be repeated.

FIG. 72 is a schematic plan view of the semiconductor device according to the forty-sixth embodiment. As in the case of the twenty-sixth embodiment (FIG. 34), the second member 20-side conductor patterns 25A, 25B, 25D are disposed, and the first member 10-side conductor patterns 15A, 15B, 15D are disposed so as to respectively overlap the second-member 20-side conductor patterns 25A, 25B, 25D. In the twenty-sixth embodiment (FIG. 34), the conductor patterns 15A, 15B are covered with the second member 20 in plan view. In contrast, in the forty-sixth embodiment, the conductor patterns 15A, 15B extend to outside from the inside of the second member 20 in plan view. The two first member conductive protrusions 100 are connected to the extended part of the extended conductor pattern 15A.

Next, advantageous effects of the forty-sixth embodiment will be described. In the forty-sixth embodiment as well, as in the case of the twenty-sixth embodiment (FIG. 34), oscillation due to a positive feedback from the output-side circuit to the input-side circuit element 40 is suppressed without decreasing heat transfer characteristics from the power stage transistors 31 provided in the second member 20 to the first member 10. In addition, as in the case of the thirty-sixth embodiment (FIGS. 45 and 46), heat dissipation from the second member 20 is improved.

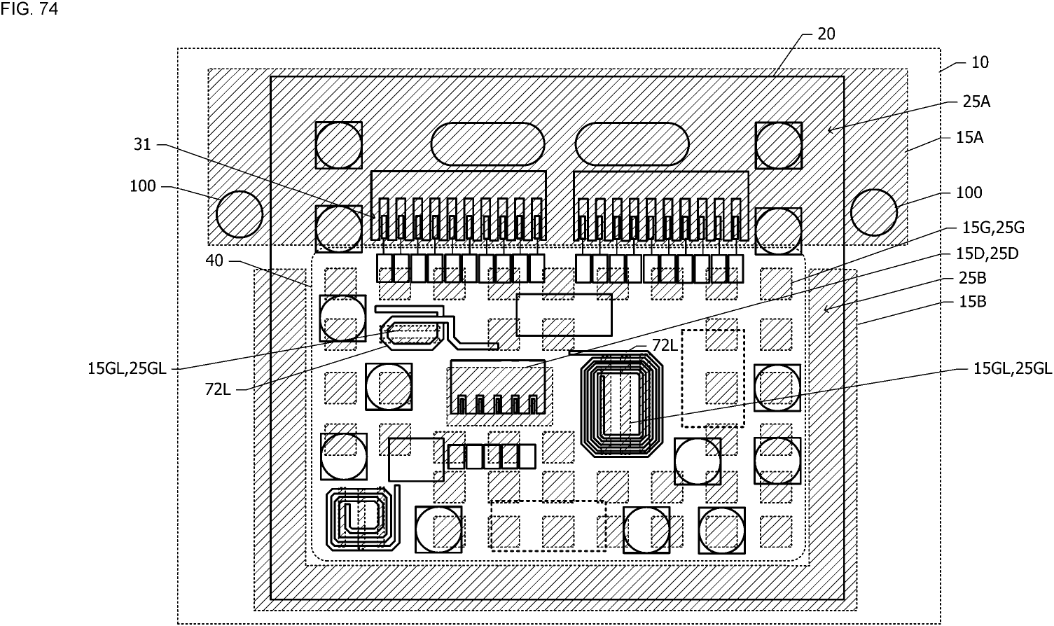

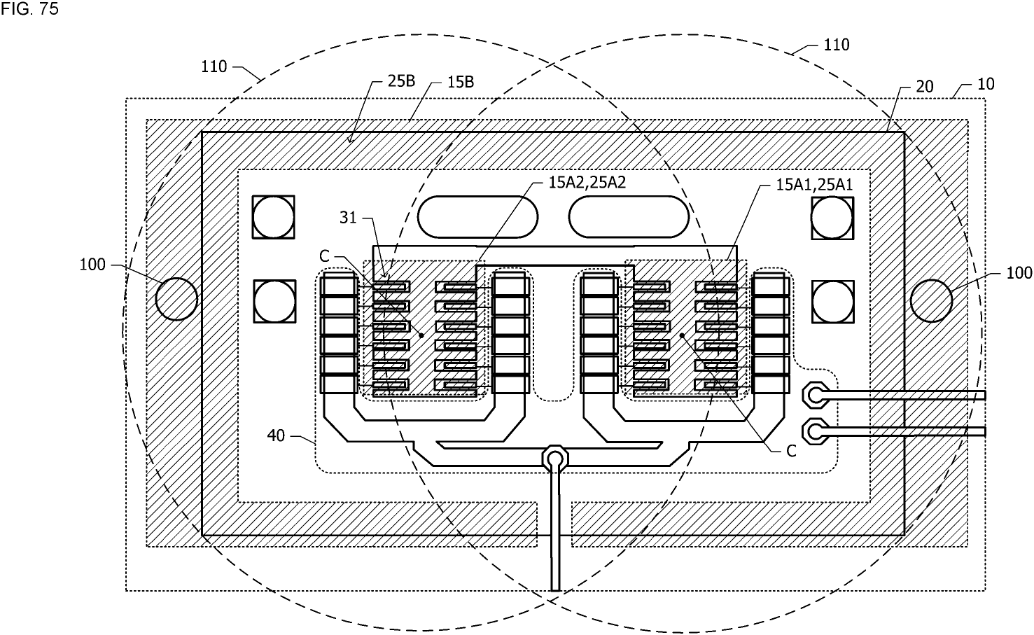

Next, semiconductor devices according to modifications of the forty-sixth embodiment will be described with reference to FIGS. 73 and 74. FIGS. 73 and 74 are schematic plan views of the semiconductor devices according to the modifications of the forty-sixth embodiment.

In the modification shown in FIG. 73, as in the case of the twenty-seventh embodiment (FIG. 35), a plurality of conductor patterns 25G is dotted in a region in which the input-side circuit element 40 is disposed. First member 10-side conductor patterns 15G are disposed so as to respectively overlap the plurality of conductor patterns 25G. However, the plurality of conductor patterns 15G, 25G do not overlap the inductors 72L of the input-side circuit element 40 in plan view. The two first member conductive protrusions 100 are connected to the extended part of the extended conductor pattern 15A.

In the modification of the forty-sixth embodiment shown in FIG. 74, in addition to the conductor patterns 15G, 25G dotted so as not to overlap the inductors 72L, conductor patterns 15GL, 25GL that overlap the inductors 72L are disposed. The two first member conductive protrusions 100 are connected to the extended part of the extended conductor pattern 15A.

In the modifications shown in FIGS. 73 and 74 as well, as in the case of the forty-sixth embodiment, oscillation due to a positive feedback from the output-side circuit to the input-side circuit element 40 is suppressed, and heat dissipation from the second member 20 is improved.

### Forty-Seventh Embodiment

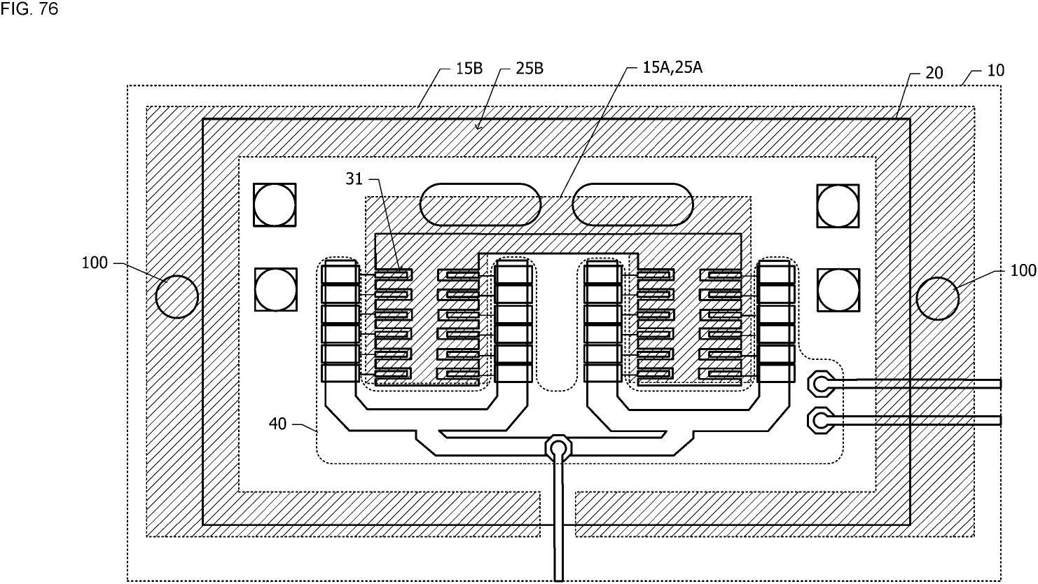

Next, a semiconductor device according to a forty-seventh embodiment will be described with reference to FIG. 75. Hereinafter, the description of components common to the semiconductor device (FIG. 37) according to the twenty-ninth embodiment will not be repeated.

FIG. 75 is a schematic plan view of the semiconductor device according to the forty-seventh embodiment. In the twenty-ninth embodiment (FIG. 37), the conductor pattern 25B disposed along the edge of the second member 20 is covered with the second member 20 in plan view, and the first member 10-side conductor pattern 15B is also covered with the second member 20 in plan view. In contrast, in the forty-seventh embodiment, the first member 10-side conductor pattern 15B extends to outside from the inside of the second member 20 in plan view. The two first member conductive protrusions 100 are connected to the extended part of the extended conductor pattern 15B.

The conductor patterns 15A1, 25A1 are disposed so as to cover one of the blocks of the plurality of power stage transistors 31, and the conductor patterns 15A2, 25A2 are disposed so as to cover the other one of the blocks.

Next, advantageous effects of the forty-seventh embodiment will be described. In the forty-seventh embodiment as well, as in the case of the twenty-ninth embodiment (FIG. 37), oscillation due to a positive feedback from the output-side circuit to the input-side circuit element 40 is suppressed without decreasing heat transfer characteristics from the power stage transistors 31 provided in the second member 20 to the first member 10. In addition, in the forty-seventh embodiment, as in the case of the thirty-sixth embodiment (FIGS. 45 and 46), heat dissipation from the second member 20 is improved.

Next, a preferred positional relationship between the power stage transistors 31 and the first member conductive protrusions 100 will be described. In the thirty-sixth embodiment (FIG. 45), the plurality of power stage transistors 31 is arranged in a line, whereas, in the forty-seventh embodiment, a plurality of power stage transistors 31 arranged in two lines substantially parallel to each other makes up one block, and the two blocks are disposed.

In the thirty-sixth embodiment (FIG. 45), one geometric center is defined for a region in which the plurality of power stage transistors 31 is disposed. In the forty-seventh embodiment, for each of the blocks of the power stage transistors 31, the geometric center C of the region in which the plurality of power stage transistors 31 is disposed is defined. In addition, for each of the geometric centers C, the geometric center C is used as a center, and a circle 110 that passes the nearest corner of the second member 20 is defined.

For one of the blocks, the first member conductive protrusion 100 is preferably disposed so as to at least partially overlap a region inside the circle 110 about the geometric center C of the block. For the other one of the blocks as well, the first member conductive protrusion 100 is preferably disposed so as to at least partially overlap a region inside the circle 110 about the geometric center C of the block.

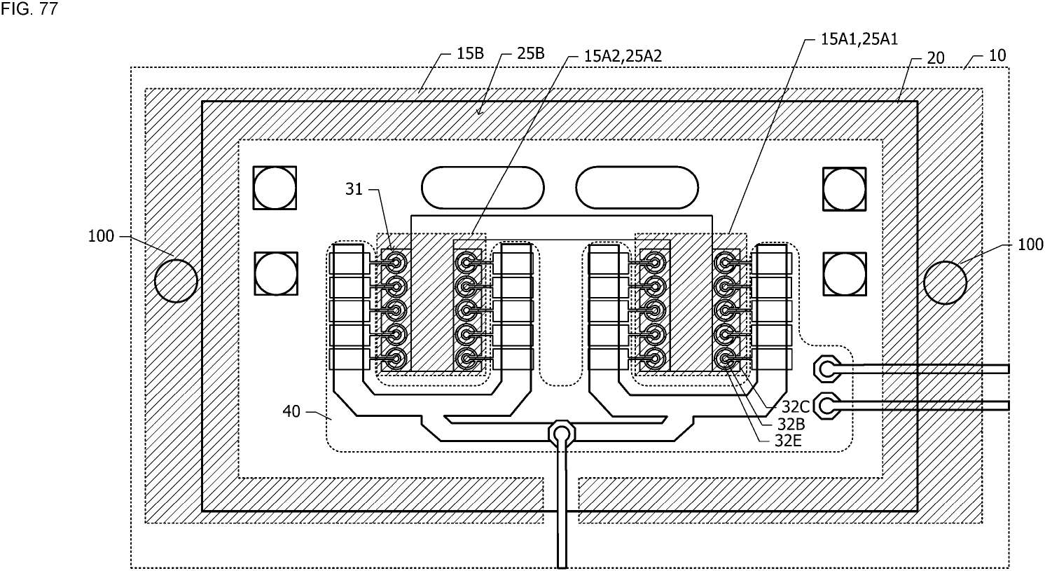

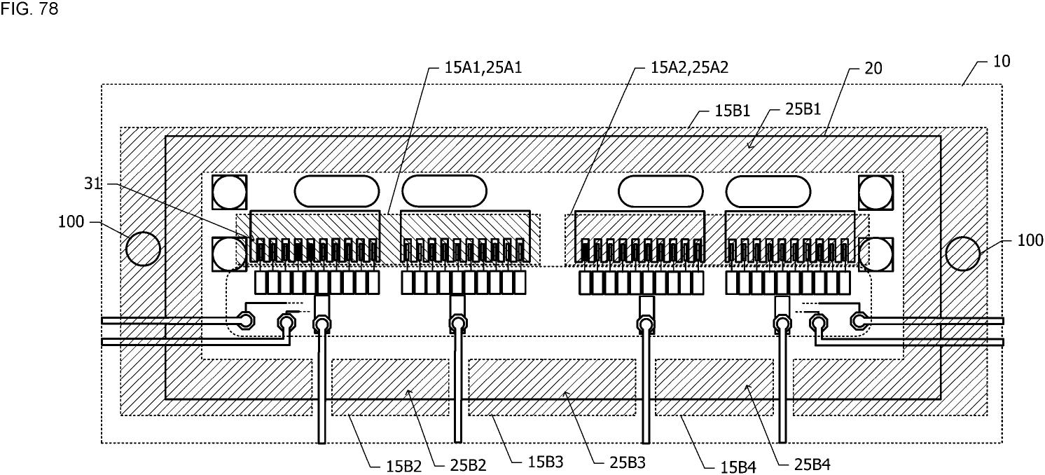

Next, semiconductor devices according to modifications of the forty-seventh embodiment will be described with reference to FIGS. 76 and 77. FIGS. 76 and 77 are schematic plan views of the semiconductor devices according to the modifications of the forty-seventh embodiment.

In the modification shown in FIG. 76, as in the case of the thirtieth embodiment (FIG. 38), the conductor patterns 15A, 25A that cover one of the blocks of the plurality of power stage transistors 31 and the conductor patterns 15B, 25B that cover the other one of the blocks are continuous with each other. The two first member conductive protrusions 100 are connected to the extended part of the extended conductor pattern 15B.

In the modification shown in FIG. 77, as in the case of the thirty-first embodiment (FIGS. 39 and 40), in plan view, the emitter electrode 32E surrounds the circular base electrode 32B of the power stage transistor 31, and the collector electrode 32C surrounds the emitter electrode 32E. The two first member conductive protrusions 100 are connected to the extended part of the extended conductor pattern 15B.

In the modifications shown in FIGS. 76 and 77 as well, as in the case of the forty-seventh embodiment, oscillation due to a positive feedback from the output-side circuit to the input-side circuit element 40 is suppressed, and heat dissipation from the second member 20 is improved.

### Forty-Eighth Embodiment

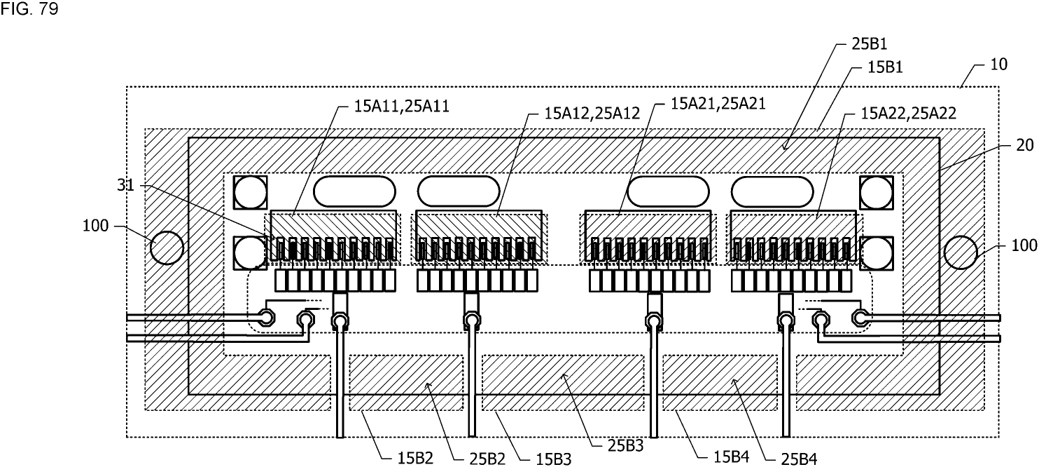

Next, a semiconductor device according to a forty-eighth embodiment will be described with reference to FIG. 78. Hereinafter, the description of components common to the semiconductor device (FIG. 41) according to the thirty-second embodiment will not be repeated.

FIG. 78 is a schematic plan view of the semiconductor device according to the forty-eighth embodiment. In the thirty-second embodiment (FIG. 41), the conductor patterns 25B1, 25B2, 25B3, 25B4 and the first member 10-side conductor patterns that respectively overlap these conductor patterns are covered with the second member 20 in plan view. In contrast, in the forty-eighth embodiment, the first member 10-side conductor patterns 15B1, 15B2, 15B3, 15B4 that respectively overlap the conductor patterns 25B1, 25B2, 25B3, 25B4 extend to outside from the inside of the second member 20 in plan view.

The two first member conductive protrusions 100 are connected to the extended part of the extended conductor pattern 15B1. The number of the first member conductive protrusions 100 may be one or may be three or more. The two first member conductive protrusions 100 may be connected to the extended parts of the conductor patterns 15B2, 15B3, 15B4, or the like.

Next, advantageous effects of the forty-eighth embodiment will be described. In the forty-eighth embodiment as well, as in the case of the thirty-second embodiment (FIG. 41), coupling between the input-side circuit element 40 and the plurality of power stage transistors 31 that make up a differential Doherty power amplifier is reduced. In addition, in the forty-eighth embodiment, as in the case of the thirty-sixth embodiment (FIGS. 45 and 46), heat dissipation from the second member 20 is improved.

Next, a semiconductor device according to a modification of the forty-eighth embodiment will be described with reference to FIG. 79. FIG. 79 is a schematic plan view of the semiconductor device according to the modification of the forty-eighth embodiment. In the forty-eighth embodiment (FIG. 78), as in the case of the thirty-second embodiment (FIG. 41), the conductor patterns 15A1, 25A1 are disposed in correspondence with the two blocks of the plurality of power stage transistors 31 that operate as the carrier amplifier of the differential Doherty power amplifier, and the conductor patterns 15A2, 25A2 are disposed in correspondence with the two blocks of the plurality of power stage transistors 31 that operate as the peak amplifier. In contrast, in the modification of the forty-eighth embodiment shown in FIG. 79, as in the case of the thirty-third embodiment (FIG. 42), conductor patterns 15A11, 25A11, conductor patterns 15A12, 25A12, conductor patterns 15A21, 25A21, and conductor patterns 15A22, 25A22 are respectively disposed in correspondence with four blocks of the plurality of power stage transistors 31. The two first member conductive protrusions 100 are connected to the extended part of the extended conductor pattern 15B1.

In the modification of the forty-eighth embodiment as well, as in the case of the forty-eighth embodiment, coupling between the input-side circuit element 40 and the plurality of power stage transistors 31 is reduced, and heat dissipation from the second member 20 is improved.

The following embodiments are disclosed in accordance with the embodiments described in the specification.

<1> A semiconductor device includes a first member having a first surface; a second member having a second surface opposite to the first surface and including a radio-frequency amplifier circuit; and an electrically conductive bonding member disposed between the first surface and the second surface and bonding the first member and the second member to each other. the radio-frequency amplifier circuit includes at least one power stage transistor, an input wire that is connected to the power stage transistor and that supplies an input signal to the power stage transistor, and an input-side circuit element connected to the input wire and including at least one of a passive element, an active element, and an external connection terminal. The bonding member includes a first conductor pattern covering the power stage transistor in plan view, and the input-side circuit element is disposed outside the first conductor pattern in plan view.

<2> In the semiconductor device according to <1>, the bonding member includes not only the first conductor pattern but also a second conductor pattern separated from the first conductor pattern, and the power stage transistor is disposed outside the second conductor pattern in plan view.

<3> In the semiconductor device according to <2>, the second conductor pattern includes a conductor pattern disposed along an edge of the second member in plan view.

<4> In the semiconductor device according to <3>, a plurality of the power stage transistors is arranged in one direction, in plan view, the input-side circuit element is disposed on one side of a straight line parallel to a direction in which the power stage transistors are arranged and passing through the power stage transistors, and a conductor pattern of the second conductor pattern, disposed along the edge of the second member, includes a conductor pattern having a U-shape that is open from the power stage transistors toward the input-side circuit element in plan view.

<5> In the semiconductor device according to <3>, a conductor pattern of the second conductor pattern, disposed along the edge of the second member, annularly surrounds the radio-frequency amplifier circuit in plan view.

<6> In the semiconductor device according to <5>, a plurality of the power stage transistors is arranged in one direction, in plan view, the input-side circuit element is disposed on one side of a straight line parallel to a direction in which the power stage transistors are arranged and passing through the power stage transistors, and a conductor pattern of the second conductor pattern, disposed along the edge of the second member, annularly surrounds the radio-frequency amplifier circuit in plan view and includes two conductor patterns separated in a direction to isolate the power stage transistors and the input-side circuit element from each other.

<7> In the semiconductor device according to <5>, a conductor pattern of the second conductor pattern, annularly surrounding the radio-frequency amplifier circuit in plan view, includes an inner peripheral-side conductor pattern and an outer peripheral-side conductor pattern that at least doubly surround the radio-frequency amplifier circuit.

<8> In the semiconductor device according to <7>, a plurality of the power stage transistors is arranged in one direction, in plan view, the input-side circuit element is disposed on one side of a straight line parallel to a direction in which the power stage transistors are arranged and passing through the power stage transistors, and an inner peripheral-side conductor pattern of the second conductor pattern includes two conductor patterns separated in a direction to isolate the power stage transistor and the input-side circuit element from each other.

<9> In the semiconductor device according to <2>, a shape of the second member is a square or a rectangle in plan view, and the second conductor pattern includes four conductor patterns respectively disposed at four corners of the second member.

<10> In the semiconductor device according to any one of <2> to <9>, the second conductor pattern includes a plurality of conductor patterns dotted so as to at least partially overlap the input-side circuit element.

<11> In the semiconductor device according to <2>, the first conductor pattern reaches a part of an edge of the second member in plan view, and the second conductor pattern partially overlaps the input-side circuit element and reaches another part of the edge of the second member in plan view.

<12> In the semiconductor device according to any one of <2> to <11>, the input-side circuit element includes a driver stage transistor, the driver stage transistor is electrically connected to the power stage transistor, and the second conductor pattern includes a conductor pattern covering the driver stage transistor in plan view.

<13> In the semiconductor device according to any one of <1> to <12>, the power stage transistor includes a transistor of a carrier amplifier and a transistor of a peak amplifier that make up a Doherty power amplifier, and in plan view, the first conductor pattern includes a conductor pattern covering the transistor of the carrier amplifier and a conductor pattern covering the transistor of the peak amplifier, the conductor patterns being separated from each other.

<14> In the semiconductor device according to any one of <1> to <13>, the second member is smaller than the first member in plan view, the semiconductor device further includes an inter-member connection wire disposed on a surface of the second member on an opposite side to the second surface and on the first surface, the inter-member connection wire extending from an inside of the second member, intersecting with an edge of the second surface, and reaching the first surface outside the second member in plan view, and the inter-member connection wire is connected to the input-side circuit element and disposed outside the first conductor pattern in plan view.

<15> In the semiconductor device according to <14>, the inter-member connection wire is disposed at a location that does not overlap the bonding member in plan view.

<16> In the semiconductor device according to any one of <1> to <13>, the input-side circuit element includes a terminal conductive protrusion that protrudes from a surface of the second member on an opposite side to the second surface as an external connection terminal, and the terminal conductive protrusion is disposed at a location that does not overlap the bonding member in plan view.

<17> In the semiconductor device according to any one of <1> to <16>, the first surface expands to outside the second member in plan view, and the semiconductor device further includes a first member conductive protrusion that protrudes from the first surface of the first member outside the second member.

<18> In the semiconductor device according to <17>, a shortest distance in plan view from the first member conductive protrusion to the second member is shorter than or equal to twice a minimum space between two parallel lines that are tangent to the first member conductive protrusion on both sides in plan view.

<19> In the semiconductor device according to <17> or <18>, a shape of the second member in plan view is a convex polygon, and at least part of the first member conductive protrusion overlaps a region inside a circle about a geometric center of a minimum bounding rectangle including the power stage transistors in plan view and passing through a corner of the second member nearest from the geometric center.

<20> In the semiconductor device according to any one of <17> to <19>, the bonding member includes an extended conductor pattern that extends to outside from an inside of the second member in plan view, and the first member conductive protrusion is connected to an extended part of the extended conductor pattern.

<21> In the semiconductor device according to <20>, within the extended part of the extended conductor pattern, a part located along one edge of the second member includes a part where an extended amount is relatively large and a part where an extended amount is relatively small, and the first member conductive protrusion is connected to the part where the extended amount is relatively large.

<22> In the semiconductor device according to <21>, the extended conductor pattern includes the first conductor pattern, and the first member conductive protrusion is connected to the extended part of the first conductor pattern.

<23> In the semiconductor device according to any one of <19> to <22>, the bonding member further includes a second conductor pattern separated from the first conductor pattern, a plurality of the power stage transistors is arranged in a first direction, in plan view, the input-side circuit element is disposed on one side of a straight line parallel to the first direction and passing through the power stage transistors, the second conductor pattern includes two conductor patterns separated in a direction to isolate the input-side circuit element and the power stage transistors from each other, and of the two conductor patterns of the second conductor pattern, the first member conductive protrusion is connected to the conductor pattern on a side on which the power stage transistors are disposed.

<24> In the semiconductor device according to any one of <17> to <22>, in plan view, the plurality o power stage transistors is disposed so as to be arranged in a first direction, and the first member conductive protrusions are respectively disposed at two portions that are line-symmetric with respect to a straight line passing through a geometric center of a minimum bounding rectangle having a side parallel to the first direction and covering a plurality of the power stage transistors, and orthogonal to the first direction.

<25> A semiconductor device includes a semiconductor member containing a compound semiconductor; a radio-frequency amplifier circuit formed on or in the semiconductor member; and a conductor member disposed on one surface of the semiconductor member. The radio-frequency amplifier circuit includes at least one power stage transistor, an input wire that supplies an input signal to the power stage transistor, and an input-side circuit element connected to the input wire and including at least one of a passive element, an active element, and an external connection terminal. The conductor member includes at least one conductor pattern, and when a surface on which the conductor member is disposed is viewed in plan, the power stage transistor is covered with at least one conductor pattern of the conductor member, and the input-side circuit element is disposed outside the conductor pattern covering the power stage transistor.

<26> The semiconductor device according to <25>, the input-side circuit element includes a terminal exposed on a surface on an opposite side to a surface on which the conductor member is disposed.

The above-described embodiments are illustrative, and, of course, partial replacements or combinations of components described in different embodiments are possible. Similar operation and advantageous effects with similar components of some of the embodiments will not be repeated one by one for each embodiment. The present disclosure is not limited to the above-described embodiments. It is obvious to persons skilled in the art that, for example, various modifications, improvements, combinations, and the like are possible.

Since the first conductor pattern of the bonding member covers the plurality of power stage transistors in plan view, heat dissipation of a heat dissipation path from the power stage transistors via the bonding member to the first member is not impaired. Since the input-side circuit element is disposed outside the first conductor pattern in plan view, coupling between the input-side circuit element and the plurality of power stage transistors with the first conductor pattern interposed therebetween is reduced. Thus, the characteristics deterioration and oscillation of the radio-frequency amplifier circuit are suppressed.

What is claimed is:

1. A semiconductor device comprising:
a first member having a first surface;
a second member having a second surface opposite to the first surface and including a radio-frequency amplifier circuit; and
an electrically conductive bonding member between the first surface and the second surface and bonding the first member and the second member to each other, wherein
the radio-frequency amplifier circuit includes
at least one power stage transistor,
an input wire that is connected to the power stage transistor and that is configured to supply an input signal to the power stage transistor, and
an input-side circuit element connected to the input wire and including at least one of a passive element, an active element, and an external connection terminal,
the bonding member includes a first conductor pattern covering the power stage transistor in plan view, and
the input-side circuit element is outside the first conductor pattern in plan view.

2. The semiconductor device according to claim 1, wherein
the bonding member includes the first conductor pattern and a second conductor pattern separated from the first conductor pattern, and
the power stage transistor is outside the second conductor pattern in plan view.

3. The semiconductor device according to claim 2, wherein
the second conductor pattern includes a conductor pattern along an edge of the second member in plan view.

4. The semiconductor device according to claim 3, wherein
the at least one power stage transistor includes a plurality of the power stage transistors arranged in one direction,
in plan view, the input-side circuit element is on one side of a straight line that is parallel to a direction in which the power stage transistors are arranged and passes through the power stage transistors, and
a conductor pattern of the second conductor pattern, extending along the edge of the second member, includes a conductor pattern having a U-shape that is open from the power stage transistors toward the input-side circuit element in plan view.

5. The semiconductor device according to claim 3, wherein
a conductor pattern of the second conductor pattern, extending along the edge of the second member, annularly surrounds the radio-frequency amplifier circuit in plan view.

6. The semiconductor device according to claim 5, wherein
the at least one power stage transistor includes a plurality of the power stage transistors arranged in one direction,
in plan view, the input-side circuit element is on one side of a straight line that is parallel to a direction in which the power stage transistors are arranged and passes through the power stage transistors, and
a conductor pattern of the second conductor pattern, extending along the edge of the second member, annularly surrounds the radio-frequency amplifier circuit in plan view and includes two conductor patterns separated in a direction to isolate the power stage transistors and the input-side circuit element from each other.

7. The semiconductor device according to claim 5, wherein
a conductor pattern of the second conductor pattern, annularly surrounding the radio-frequency amplifier circuit in plan view, includes an inner peripheral-side conductor pattern and an outer peripheral-side conductor pattern that at least doubly surround the radio-frequency amplifier circuit.

8. The semiconductor device according to claim 7, wherein
the at least one power stage transistor includes a plurality of the power stage transistors arranged in one direction,
in plan view, the input-side circuit element is on one side of a straight line that is parallel to a direction in which the power stage transistors are arranged and passes through the power stage transistors, and
an inner peripheral-side conductor pattern of the second conductor pattern includes two conductor patterns separated in a direction to isolate the power stage transistor and the input-side circuit element from each other.

9. The semiconductor device according to claim 2, wherein
a shape of the second member is a square or a rectangle in plan view, and
the second conductor pattern includes four conductor patterns respectively at four corners of the second member.

10. The semiconductor device according to claim 2, wherein
the second conductor pattern includes a plurality of conductor patterns dotted so as to at least partially overlap the input-side circuit element.

11. The semiconductor device according to claim 2, wherein
the first conductor pattern reaches a part of an edge of the second member in plan view, and
the second conductor pattern partially overlaps the input-side circuit element and reaches another part of the edge of the second member in plan view.

12. The semiconductor device according to claim 2, wherein
the input-side circuit element includes a driver stage transistor,
the driver stage transistor is electrically connected to the power stage transistor, and
the second conductor pattern includes a conductor pattern covering the driver stage transistor in plan view.

13. The semiconductor device according to claim 1, wherein
the power stage transistor includes a transistor of a carrier amplifier and a transistor of a peak amplifier that make up a Doherty power amplifier, and
in plan view, the first conductor pattern includes a conductor pattern covering the transistor of the carrier amplifier and a conductor pattern covering the transistor of the peak amplifier, the conductor patterns being separated from each other.

14. The semiconductor device according to claim 1, wherein
the second member is smaller than the first member in plan view,
the semiconductor device further comprises an inter-member connection wire on a surface of the second member on an opposite side to the second surface and on the first surface, the inter-member connection wire extending from an inside of the second member, intersecting with an edge of the second surface, and reaching the first surface outside the second member in plan view, and
the inter-member connection wire is connected to the input-side circuit element and outside the first conductor pattern in plan view.

15. The semiconductor device according to claim 14, wherein
the inter-member connection wire is at a location that does not overlap the bonding member in plan view.

16. The semiconductor device according to claim 1, wherein
the input-side circuit element includes a terminal conductive protrusion that protrudes from a surface of the second member on an opposite side to the second surface as an external connection terminal, and
the terminal conductive protrusion is at a location that does not overlap the bonding member in plan view.

17. The semiconductor device according to claim 1, wherein
the first surface expands to outside the second member in plan view, and
the semiconductor device further comprises a first member conductive protrusion that protrudes from the first surface of the first member outside the second member.

18. The semiconductor device according to claim 17, wherein
a shortest distance in plan view from the first member conductive protrusion to the second member is shorter than or equal to twice a minimum space between two parallel lines that are tangent to the first member conductive protrusion on both sides in plan view.

19. A semiconductor device comprising:
a semiconductor member containing a compound semiconductor;
a radio-frequency amplifier circuit on or in the semiconductor member; and
a conductor member on one surface of the semiconductor member, wherein
the radio-frequency amplifier circuit includes
at least one power stage transistor,
an input wire configured to supply an input signal to the power stage transistor, and
an input-side circuit element connected to the input wire and including at least one of a passive element, an active element, and an external connection terminal,
the conductor member includes at least one conductor pattern, and
when a surface on which the conductor member is disposed is viewed in plan, the power stage transistor is covered with at least one conductor pattern of the conductor member, and the input-side circuit element is outside the conductor pattern covering the power stage transistor.

20. The semiconductor device according to claim 19, wherein
the input-side circuit element includes a terminal exposed on a surface on an opposite side to a surface on which the conductor member is disposed.
